(19) United States
(12) Patent Application Publication
(10) Pub. No.: US 2024/0112996 A1
(43) Pub. Date: Apr. 4, 2024

(54) SEMICONDUCTOR DEVICE

(71) Applicant: ROHM CO., LTD., Kyoto-shi, Kyoto (JP)

(72) Inventors: Hiroshi OJI, Kyoto-shi, Kyoto (JP); Hiroyuki SHINKAI, Kyoto-shi, Kyoto (JP); Natsuki SAKAMOTO, Kyoto-shi, Kyoto (JP); Naoyuki SANO, Kyoto-shi, Kyoto (JP)

(21) Appl. No.: 17/768,374

(22) PCT Filed: Oct. 19, 2020
(86) PCT No.: PCT/JP2020/039258

§ 371 Date: Apr. 12, 2022

(30) Foreign Application Priority Data
Oct. 24, 2019 (JP) 2019-193436
Nov. 28, 2019 (JP) 2019-215616

(51) Int. Cl. H01L 23/498; H01L 23/31; H01L 25/16

(52) U.S. Cl. CPC H01L 23/49811; H01L 23/3121; H01L 25/165; H01L 24/05

(57) ABSTRACT

A semiconductor device includes: a substrate having an obverse and a reverse face; wirings on the obverse face such as a first and a second drive wiring; a semiconductor element connected to the first and second drive wirings; a first drive conductor on the same side as the semiconductor element with respect to the substrate outside of the semiconductor element as viewed in a thickness direction and connected to the first drive wiring; a second drive conductor on the same side as the semiconductor element with respect to the substrate outside of the semiconductor element as viewed in the thickness direction and connected to the second drive wiring; and a sealing resin covering the wirings and the semiconductor element, while also covering the first and second drive conductor such that their faces opposite to the substrate in the thickness direction are exposed. The first and the second drive conductor are separated in a direction parallel to the obverse face. The first drive conductor is smaller in volume than the second drive conductor.

### TECHNICAL FIELD

The present disclosure relates to a semiconductor device. The present disclosure also relates to a manufacturing method of the semiconductor device.

### BACKGROUND ART

A conventionally known semiconductor device may include a semiconductor element with a plurality of electrodes, an insulation layer covering the reverse face of the semiconductor element on which the plurality of electrodes are formed, and a plurality of wirings formed on the insulation layer and electrically connected to the respective electrodes (see, for example, Patent document 1).

In addition, micro electro mechanical systems (MEMS) have come to be widely utilized in recent years. In the manufacturing process of the MEMS, a silicon (Si) substrate is subjected to micro-fabrication, so that various types of semiconductor elements are formed on the Si substrate. For example, a semiconductor device disclosed in Patent document 2 includes a Si substrate (base material), a semiconductor element (light emitting element) and a wiring layer (wiring pattern), and the semiconductor element is mounted on the Si substrate. The wiring layer is formed on the Si substrate, and electrically connected to the semiconductor element. The wiring layer serves as a terminal, when the semiconductor device is mounted on a circuit board of an electronic device or the like. The wiring layer is formed on the upper face of the Si substrate.

The manufacturing method of the semiconductor device configured as above includes, for example, a step of forming a wiring layer on a Si wafer, a step of mounting a plurality of semiconductor elements on the Si wafer, and a step of dicing the Si wafer into individual pieces each having the semiconductor element mounted thereon.

### PRIOR ART DOCUMENT

### Patent Documents

Patent document 1: JP-A-2013-239740
Patent document 2: JP-A-2009-94409

### SUMMARY OF INVENTION

### Problem to be Solved by Invention

The above-noted semiconductor device (paragraph [0002]) may, for example, include a substrate formed of silicon (Si), a plurality of wirings formed on the substrate obverse face, which is one of the faces of the substrate in a thickness direction, a semiconductor element located at a central region of the substrate obverse face and formed on the plurality of wirings, a plurality of conductors located on an outer side of the semiconductor element, and formed on the plurality of wirings, and a sealing resin covering the semiconductor element and the plurality of conductors. The plurality of conductors are exposed from a face of the sealing resin on the opposite side of the substrate in the thickness direction.

The plurality of conductors include a plurality of drive conductors that drive the semiconductor element, and a plurality of control conductors that control the action of the semiconductor element. As viewed in the thickness direction, the plurality of drive conductors are located on both sides of the semiconductor element in a predetermined direction, and aligned in a direction orthogonal to the predetermined direction and the thickness direction. The plurality of control conductors are located on both sides of the semiconductor element in the direction in which the plurality of drive conductors are aligned, and aligned along the predetermined direction.

It is preferable that the plurality of drive conductors are capable of accepting a relatively large current. Accordingly, the volume of each of the drive conductors is made larger than that of the control conductors, to which only a small current is supplied. As result, the electrical resistance of the drive conductor can be reduced.

However, in the case where the drive conductors are made larger in volume, the base material may be warped, upon being heated during the formation process of the sealing resin, after the drive conductors are formed on the wirings formed on the obverse face of the base material, yet to be divided into individual pieces each constituting a plurality of substrates, in the manufacturing process of the semiconductor device. This impedes the base material from being properly transported, or from being accurately divided into individual pieces, thus making it difficult to efficiently manufacture the semiconductor devices.

In the case of the conventional manufacturing method (paragraph [0004]), the base material is diced into individual pieces each having the semiconductor element, after the wiring layer is formed, and therefore no wiring layer is formed on the side face of the Si substrate, obtained after the dicing process. Accordingly, when the semiconductor device is mounted with solder on the circuit board of an electronic device, X-ray inspection equipment has to be employed, to check the bonding condition of the solder.

The present disclosure has been accomplished in view of the aforementioned situation, to provide a semiconductor device that can be stably manufactured. In another aspect, the present disclosure provides a semiconductor device that enables the bonding condition of solder to be easily checked, when the semiconductor device is mounted on a circuit board. In still another aspect, the present disclosure provides a manufacturing method appropriate for manufacturing the mentioned semiconductor device.

### Means to Solve the Problem

As an embodiment of a first aspect, the present disclosure provides a semiconductor device including: a substrate having a substrate obverse face and a substrate reverse face that are oriented to opposite sides to each other in a thickness direction; wirings located on the substrate obverse face and including a first drive wiring and a second drive wiring; a semiconductor element electrically connected to the first drive wiring and the second drive wiring; a first drive conductor located on a same side as the semiconductor element with respect to the substrate in a region on an outer side of the semiconductor element as viewed in the thickness direction and electrically connected to the first drive wiring; a second drive conductor located on the same side as the semiconductor element with respect to the substrate in a region on an outer side of the semiconductor element as viewed in the thickness direction and electrically connected to the second drive wiring; and a sealing resin covering the wirings and the semiconductor element, and also covering the first drive conductor and the second drive conductor such that respective faces of the first drive conductor and the second drive conductor that are opposite to the substrate in the thickness direction are exposed from the sealing resin. The first drive conductor and the second drive conductor are aligned with a spacing between each other in a predetermined direction parallel to the substrate obverse face, where the first drive conductor is smaller in volume than the second drive conductor.

The inventor of the present disclosure possesses the knowledge that, with an increase in volume of the first drive conductor and the second drive conductor, a base material constituting a plurality of substrates becomes more likely to be warped upon being heated, for example during formation of the sealing resin, in the manufacturing process of the semiconductor device.

In this semiconductor device, therefore, the first drive conductor is made smaller in volume than the second drive conductor. Such a configuration can minimize the warp of the base material constituting a plurality of substrates, despite being heated, for example during the formation of the sealing resin, in the manufacturing process of the semiconductor device. Consequently, the semiconductor device can be stably manufactured.

As another embodiment of the first aspect, the present disclosure provides a semiconductor device including a substrate having a substrate obverse face and a substrate reverse face, oriented to opposite sides to each other in a thickness direction, wirings located on the substrate obverse face, and including a first drive wiring and a second drive wiring, a semiconductor element mounted on the substrate obverse face, and electrically connected to the first drive wiring and the second drive wiring, a first drive conductor penetrating through the substrate in the thickness direction, so as to be exposed on the substrate obverse face and the substrate reverse face, and electrically connected to the first drive wiring, a second drive conductor penetrating through the substrate in the thickness direction, so as to be exposed on the substrate obverse face and the substrate reverse face, and electrically connected to the second drive wiring, and a sealing resin covering the wirings and the semiconductor element. The first drive conductor and the second drive conductor are aligned, with a spacing between each other, in a predetermined direction as viewed from the substrate reverse face, and the first drive conductor is smaller in volume than the second drive conductor.

The inventor of the present disclosure possesses the knowledge that, with an increase in volume of the first drive conductor and the second drive conductor, a base material constituting a plurality of substrates becomes more likely to be warped, upon being heated, for example during formation of the sealing resin, in the manufacturing process of the semiconductor device.

In this semiconductor device, therefore, the first drive conductor is made smaller in volume than the second drive conductor. Such a configuration can minimize the warp of the base material constituting a plurality of substrates, despite being heated, for example during the formation of the sealing resin, in the manufacturing process of the semiconductor device. Consequently, the semiconductor device can be stably manufactured.

As an embodiment of a second aspect, the present disclosure provides a semiconductor device including a semiconductor element formed with an element electrode, a wiring layer located on one side of the semiconductor element, in a thickness direction of the semiconductor element, and electrically connected to the element electrode, a first columnar electrode protruding from the wiring layer to the other side in the thickness direction, and a resin member covering the semiconductor element. The resin member includes a resin obverse face and a resin reverse face spaced apart from each other in the thickness direction, a first resin side face connected to the resin obverse face, and a second resin side face connected to the resin reverse face. The first resin side face is located on an inner side of the second resin side face, as viewed in the thickness direction. The first columnar electrode includes a first exposed side face exposed from the resin member, a first covered side face covered with the resin member, and a first top face connected to the first exposed side face and flush with the resin obverse face. The first exposed side face is located on an inner side of the first covered side face as viewed in the thickness direction, and flush with the first resin side face. The first covered side face and the second resin side face are each oriented in a first direction orthogonal to the thickness direction, and the first covered side face overlaps with the second resin side face, as viewed in the first direction.

As another embodiment of the second aspect, the present disclosure provides a manufacturing method of a semiconductor device. The method includes a substrate preparation process including preparing a substrate having a substrate obverse face and a substrate reverse face spaced apart from each other in a thickness direction, a wiring layer formation process including forming a wiring layer on the substrate obverse face, a first columnar electrode formation process including forming a first columnar electrode on the wiring layer, an element mounting process including mounting a semiconductor element, a resin formation process including forming a resin member on the substrate so as to cover the semiconductor element, a first cutting process including cutting the first columnar electrode and the resin member, to a halfway position of the first columnar electrode and the resin member respectively, in the thickness direction, thereby forming a first cutaway portion, and a second cutting process including cutting away an entirety of the resin member in the first cutaway portion, in the thickness direction of the resin member. Through the first cutting process, the first exposed side face exposed from the resin member and the first covered side face covered with the resin member are formed on the first columnar electrode, and also the first resin side face is formed on the resin member. Through the second cutting process, the second resin side face is formed on the resin member. The first resin side face is located on the inner side of the second resin side face, as viewed in the thickness direction, and the first exposed side face is located on the inner side of the first covered side face, as viewed in the thickness direction, and flush with the first resin side face. The first covered side face and the second resin side face are each oriented in a first direction orthogonal to the thickness direction, and the first covered side face overlaps with the second resin side face, as viewed in the first direction.

### Advantages of Invention

With the mentioned manufacturing method, for example, the semiconductor device can be stably manufactured. In addition, when the semiconductor device is mounted on a circuit board, the bonding condition of the solder can be easily checked visually.

### BRIEF DESCRIPTION OF DRAWINGS

FIG. 1 is a perspective view showing a semiconductor device according to a first embodiment of a first aspect.

FIG. 2 is a perspective view showing the semiconductor device seen from a different direction from FIG. 1.

FIG. 3 is a bottom view of the semiconductor device shown in FIG. 1.

FIG. 4 is a bottom view of the semiconductor device shown in FIG. 3, with a sealing resin excluded.

FIG. 5 is a bottom view of the semiconductor device shown in FIG. 4, with semiconductor elements excluded.

FIG. 6 is a partially enlarged bottom view from FIG. 5.

FIG. 7 is another partially enlarged bottom view from FIG. 5.

FIG. 8 is a cross-sectional view taken along a line 8-8 in FIG. 4, the sealing resin and terminals inclusive.

FIG. 9 is a cross-sectional view taken along a line 9-9 in FIG. 4, the sealing resin and the terminals inclusive.

FIG. 10 is a cross-sectional view taken along a line 10-10 in FIG. 4, the sealing resin and the terminals inclusive.

FIG. 11 is an enlarged cross-sectional view showing a bonding structure between an element electrode and a wiring, and related parts, in the semiconductor element shown in FIG. 8.

FIG. 12 is an enlarged cross-sectional view showing a bonding structure between an element electrode and a wiring, and related parts, in the semiconductor element shown in FIG. 10.

FIG. 13 is a cross-sectional view for explaining an exemplary process in a manufacturing method of the semiconductor device according to the first embodiment.

FIG. 14 is a cross-sectional view for explaining another exemplary process in the manufacturing method of the semiconductor device according to the first embodiment.

FIG. 15 is a cross-sectional view for explaining another exemplary process in the manufacturing method of the semiconductor device according to the first embodiment.

FIG. 16 is a cross-sectional view for explaining another exemplary process in the manufacturing method of the semiconductor device according to the first embodiment.

FIG. 17 is a plan view including the portion shown in FIG. 16.

FIG. 18 is a cross-sectional view for explaining another exemplary process in the manufacturing method of the semiconductor device according to the first embodiment.

FIG. 19 is a cross-sectional view for explaining another exemplary process in the manufacturing method of the semiconductor device according to the first embodiment.

FIG. 20 is a cross-sectional view for explaining another exemplary process in the manufacturing method of the semiconductor device according to the first embodiment.

FIG. 21 is a cross-sectional view for explaining another exemplary process in the manufacturing method of the semiconductor device according to the first embodiment.

FIG. 22 is a plan view including the portion shown in FIG. 21.

FIG. 23 is a cross-sectional view for explaining another exemplary process in the manufacturing method of the semiconductor device according to the first embodiment.

FIG. 24 is a cross-sectional view for explaining another exemplary process in the manufacturing method of the semiconductor device according to the first embodiment.

FIG. 25 is a cross-sectional view for explaining another exemplary process in the manufacturing method of the semiconductor device according to the first embodiment.

FIG. 26 is a bottom view of a semiconductor device according to a second embodiment of the first aspect.

FIG. 27 is a bottom view of the semiconductor device shown in FIG. 26, with the sealing resin excluded.

FIG. 28 is a bottom view of the semiconductor device shown in FIG. 27, with the semiconductor elements excluded.

FIG. 29 is a bottom view of a semiconductor device according to a variation, with the sealing resin, the terminals, and the semiconductor elements excluded.

FIG. 30 is another bottom view of the semiconductor device according to the variation, with the sealing resin, the terminals, and the semiconductor elements excluded.

FIG. 31 is a partial bottom view of the semiconductor device according to the variation.

FIG. 32 is another partial bottom view of the semiconductor device according to the variation.

FIG. 33 is another partial bottom view of the semiconductor device according to the variation.

FIG. 34 is another partial bottom view of the semiconductor device according to the variation.

FIG. 35 is another partial bottom view of the semiconductor device according to the variation.

FIG. 36 is a cross-sectional view for explaining an exemplary process in a manufacturing method of the semiconductor device according to the variation.

FIG. 37 is a bottom view of the semiconductor device according to the variation.

FIG. 38 is a cross-sectional view taken along a line 38-38 in FIG. 37.

FIG. 39 is a cross-sectional view for explaining another exemplary process in the manufacturing method of the semiconductor device according to the variation.

FIG. 40 is a cross-sectional view for explaining another exemplary process in the manufacturing method of the semiconductor device according to the variation.

FIG. 41 is a cross-sectional view for explaining another exemplary process in the manufacturing method of the semiconductor device according to the variation.

FIG. 42 is a cross-sectional view for explaining another exemplary process in the manufacturing method of the semiconductor device according to the variation.

FIG. 43 is a cross-sectional view for explaining another exemplary process in the manufacturing method of the semiconductor device according to the variation.

FIG. 44 is a cross-sectional view for explaining another exemplary process in the manufacturing method of the semiconductor device according to the variation.

FIG. 45 is a cross-sectional view for explaining another exemplary process in the manufacturing method of the semiconductor device according to the variation.

FIG. 46 is a cross-sectional view for explaining another exemplary process in the manufacturing method of the semiconductor device according to the variation.

FIG. 47 is a partial bottom view of the semiconductor device according to the variation.

FIG. 48 is another partial bottom view of the semiconductor device according to the variation.

FIG. 49 is a perspective view showing a semiconductor device according to a first embodiment of a second aspect.

FIG. 50 is a plan view showing the semiconductor device (second aspect).

FIG. 51 is a plan view corresponding to FIG. 50, with external electrodes excluded, and the semiconductor element and resin member indicated by imaginary lines.

FIG. 52 is a front view showing the semiconductor device (second aspect).

FIG. 53 is a side view (left-side view) showing the semiconductor device (second aspect).

FIG. 54 is a cross-sectional view taken along a line 54-54 in FIG. 51.

FIG. 55 is a partially enlarged cross-sectional view from FIG. 54.

FIG. 56 is a cross-sectional view taken along a line 56-56 in FIG. 51.

FIG. 57 is a partially enlarged cross-sectional view from FIG. 56.

FIG. 58 is a cross-sectional view taken along a line 58-58 in FIG. 51.

FIG. 59 is a partially enlarged cross-sectional view from FIG. 58.

FIG. 60 is a cross-sectional view for explaining an exemplary process in a manufacturing method of the semiconductor device (second aspect).

FIG. 61 is a cross-sectional view for explaining another exemplary process in the manufacturing method of the semiconductor device (second aspect).

FIG. 62 is a cross-sectional view for explaining another exemplary process in the manufacturing method of the semiconductor device (second aspect).

FIG. 63 is a cross-sectional view for explaining another exemplary process in the manufacturing method of the semiconductor device (second aspect).

FIG. 64 is a cross-sectional view for explaining another exemplary process in the manufacturing method of the semiconductor device (second aspect).

FIG. 65 is a cross-sectional view for explaining another exemplary process in the manufacturing method of the semiconductor device (second aspect).

FIG. 66 is a cross-sectional view for explaining another exemplary process in the manufacturing method of the semiconductor device (second aspect).

FIG. 67 is a cross-sectional view for explaining another exemplary process in the manufacturing method of the semiconductor device (second aspect).

FIG. 68 is a cross-sectional view for explaining another exemplary process in the manufacturing method of the semiconductor device (second aspect).

FIG. 69 is a partially enlarged cross-sectional view from FIG. 68.

FIG. 70 is a cross-sectional view for explaining another exemplary process in the manufacturing method of the semiconductor device (second aspect).

FIG. 71 is a cross-sectional view for explaining another exemplary process in the manufacturing method of the semiconductor device (second aspect).

FIG. 72 is a cross-sectional view for explaining another exemplary process in the manufacturing method of the semiconductor device (second aspect).

FIG. 73 is a partially enlarged cross-sectional view from FIG. 72.

FIG. 74 is a cross-sectional view showing a semiconductor device according to a second embodiment of the second aspect.

FIG. 75 is a cross-sectional view showing a semiconductor device according to a third embodiment of the second aspect.

FIG. 76 is a partially enlarged cross-sectional view showing a bonding section according to a variation of the second aspect.

### MODE FOR CARRYING OUT INVENTION

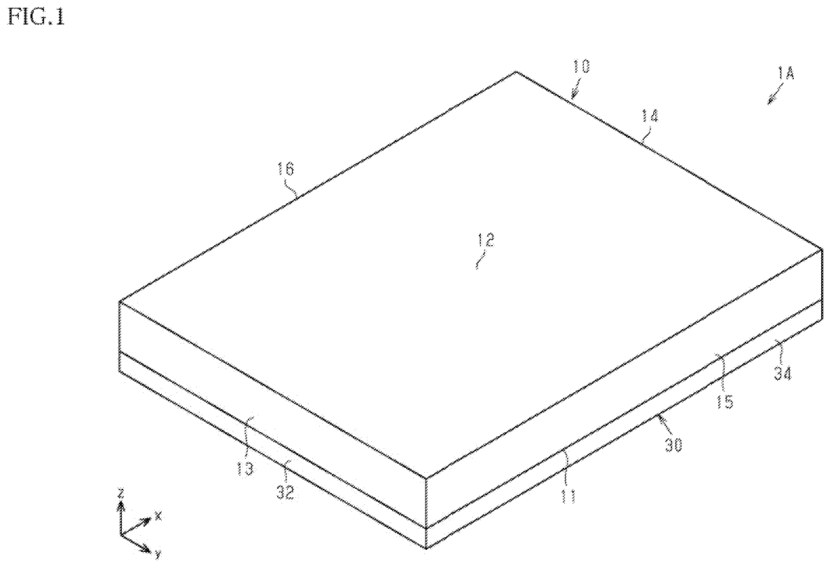

Hereafter, a semiconductor device (and a manufacturing method thereof) according to embodiments of a first aspect of the present disclosure, and variations thereof, will be described, with reference to FIG. 1 to FIG. 48. In addition, a semiconductor device (and a manufacturing method thereof) according to some embodiments of a second aspect of the present disclosure, and variations thereof, will be described, with reference to FIG. 49 to FIG. 76. Reference numerals in FIG. 1 to FIG. 48 (first aspect) and those in FIG. 49 to FIG. 76 (second aspect) are independently used, and therefore the same numeral may represent different elements, and different numerals may represent the same (or similar) element. As to the embodiments of the same aspect, the same or similar elements are given the same numeral, and the description thereof may be skipped, as the case may be. The embodiments of the first and second aspects, and the variations thereof described hereunder merely exemplify the configurations and methods for realizing technical ideas, and are in no way intended to limit the material, shape, structure, location, and size of the elements to those described below. Various modifications may be made to the following embodiments and variations.

### First Embodiment (First Aspect)

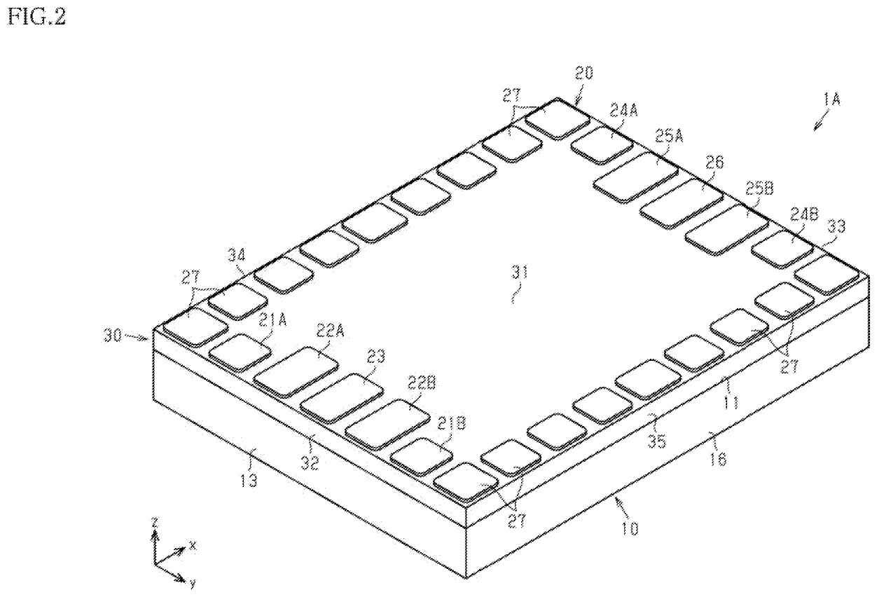

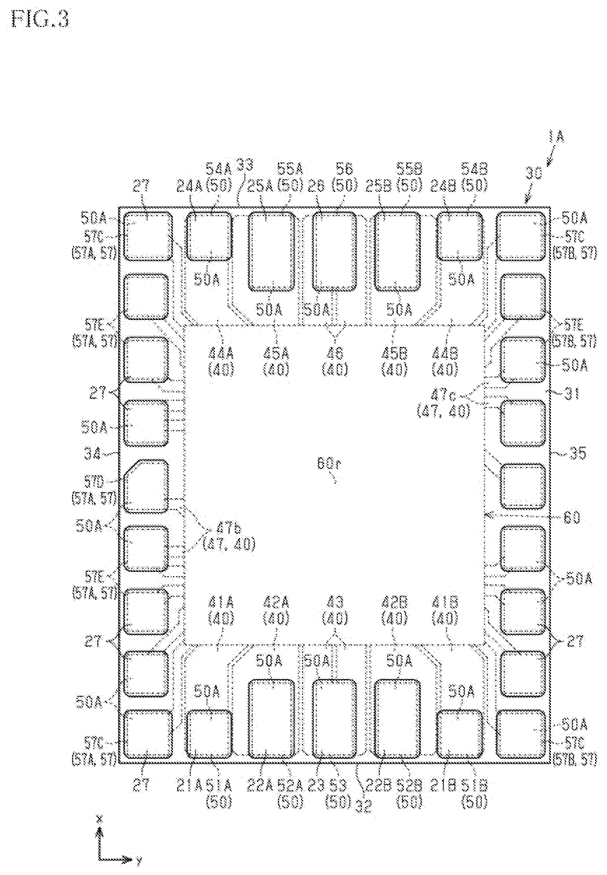

Referring to FIG. 1 to FIG. 11, a configuration of a semiconductor device 1A according to a first embodiment of the first aspect will be described hereunder. As shown in FIG. 1 and FIG. 2, the semiconductor device 1A is formed in a rectangular flat plate shape. The semiconductor device 1A includes a substrate 10 of a flat plate shape, a plurality of terminals 20, and a sealing resin 30. The plurality of terminals 20 are provided on a face of the sealing resin 30 opposite to another face on which the substrate 10 is located. As shown in FIG. 2 and FIG. 3, the plurality of terminals 20 are located on an inner side of the peripheral edge of the face of the sealing resin 30 on which the plurality of terminals 20 are provided. As is apparent from the above, the semiconductor device 1A according to this embodiment is of a surface-mounting type.

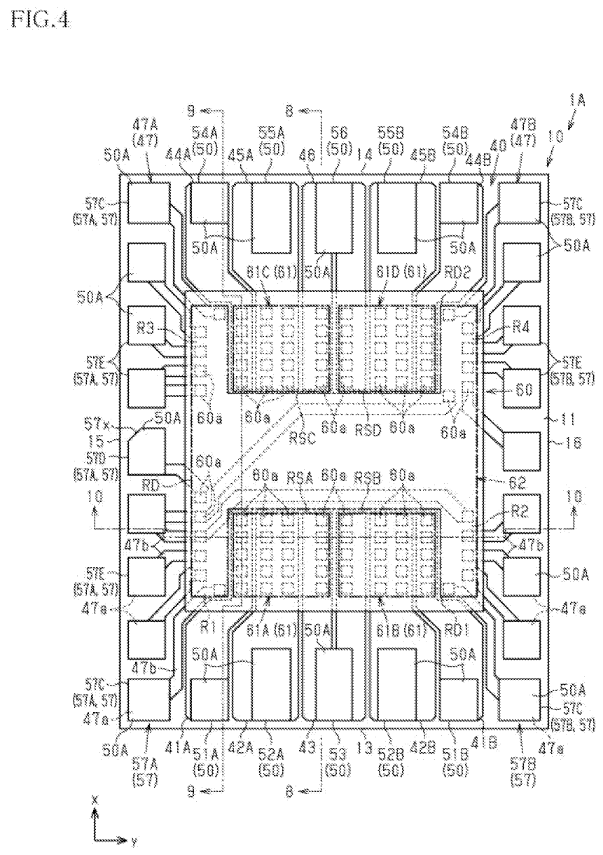

As shown in FIG. 3 and FIG. 4, the semiconductor device 1A also includes a plurality of wirings 40, a plurality of conductors 50, and a semiconductor element 60. The plurality of wirings 40 and the plurality of conductors 50 constitute conduction paths for electrically connecting the semiconductor element 60 and the plurality of terminals 20. The plurality of wirings 40 are each electrically connected to the semiconductor element 60, and the plurality of conductors 50 are electrically connected to the respective wirings 40 and the respective terminals 20. The plurality of wirings 40, the plurality of conductors 50, and the semiconductor element 60 are covered by the sealing resin 30.

As shown in FIG. 4, the semiconductor element 60 includes a first circuit 61 having a plurality of switching circuits that convert power, and a second circuit 62 having a control circuit that controls the switching circuits of the first circuit 61. The second circuit 62 controls the switching circuits of the first circuit 61, according to electrical signals inputted from outside of the semiconductor device 1A.

The semiconductor device 1A constitutes a part of a power conversion device such as a DC/DC converter. The semiconductor device 1A is configured as a resin package to be surface-mounted on a circuit board of the power conversion device. This package is known as a quad flat non-leaded (QFN) package.

In the subsequent description, the thickness direction of the substrate 10 will be defined as z-direction, and two directions orthogonal to the z-direction, and also orthogonal to each other, will be defined as x-direction and y-direction, respectively. In this embodiment, the semiconductor device 1A has a rectangular shape having long sides and short sides, as viewed in the z-direction. In this embodiment, the direction along the long sides of the semiconductor device 1A will be defined as the x-direction, and the direction along the short sides will be defined as the y-direction. In addition, for the sake of convenience, a direction from the substrate 10 toward the sealing resin 30 in the z-direction will be defined as “upward”, and a direction from the sealing resin 30 toward the substrate 10 will be defined as “downward”.

Referring to FIG. 1, the substrate 10 is formed of a monocrystalline intrinsic semiconductor material. In this embodiment, the substrate 10 is formed of silicon (Si). The substrate 10 includes a substrate obverse face 11 and a substrate reverse face 12 oriented to opposite sides in the z-direction. Between the substrate obverse face 11 and the substrate reverse face 12 in the z-direction, four substrate side faces 13, 14, 15, and 16 are provided. As shown in FIG. 4, the substrate side faces 13 and 14 are spaced apart from each other in the x-direction, and oriented to opposite sides to each other in the x-direction. The substrate side faces 13 and 14 each extend along the y-direction. The substrate side faces 15 and 16 are spaced apart from each other in the y-direction, and oriented to opposite sides to each other in the y-direction. The substrate side faces 15 and 16 each extend along the x-direction. As shown in FIG. 4, the substrate 10 has a rectangular shape with the long sides extending in the x-direction and the short sides extending in the y-direction, as viewed in the z-direction. Accordingly, the substrate side faces 13 and 14 constitute the short sides, and the substrate side faces 15 and 16 constitute the long sides of the substrate 10, as viewed in the z-direction. Thus, the x-direction may be referred to as a first direction representing the longitudinal direction of the substrate 10, and the y-direction may be referred to as a second direction representing the width direction of the substrate 10.

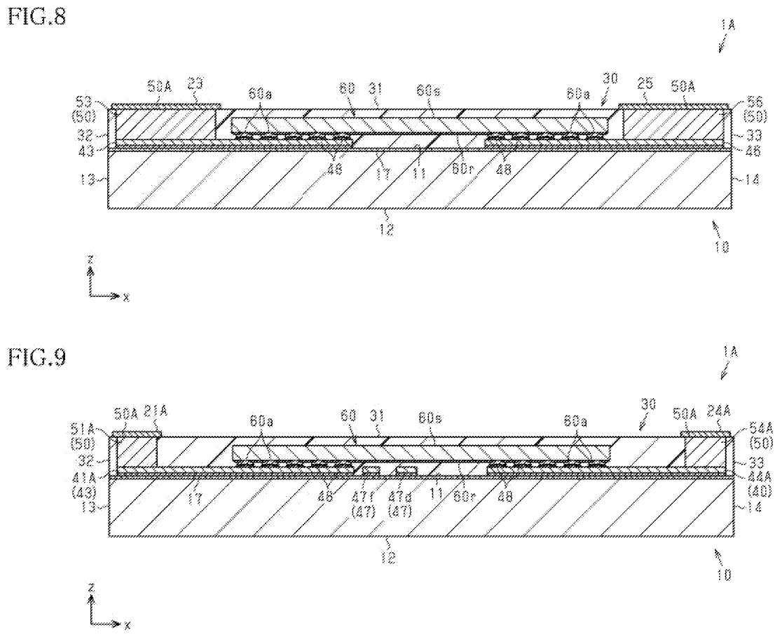

As shown in FIG. 4 and FIG. 8 to FIG. 10, the plurality of wirings 40, the plurality of conductors 50, and the semiconductor element 60 are arranged on the substrate obverse face 11. As shown in FIG. 8 to FIG. 10, the sealing resin 30 is provided on the substrate obverse face 11, so as to cover the plurality of wirings 40, the plurality of conductors 50, and the semiconductor element 60. In this embodiment, the sealing resin 30 is formed over the entirety of the substrate obverse face 11, as shown in FIG. 1 and FIG. 2. The substrate reverse face 12 is to constitute the upper face, when the semiconductor device 1A is mounted on a circuit board. As shown in FIG. 8, an insulation film 17 is formed on an end face of the substrate 10 in the z-direction, on the side of the sealing resin 30. The insulation film 17 includes an oxide layer (SiO2) and a nitride layer (Si3N4) stacked on the oxide layer. The substrate obverse face 11 corresponds to the surface of the insulation film 17. Therefore, the plurality of wirings 40 are formed on the surface of the insulation film 17.

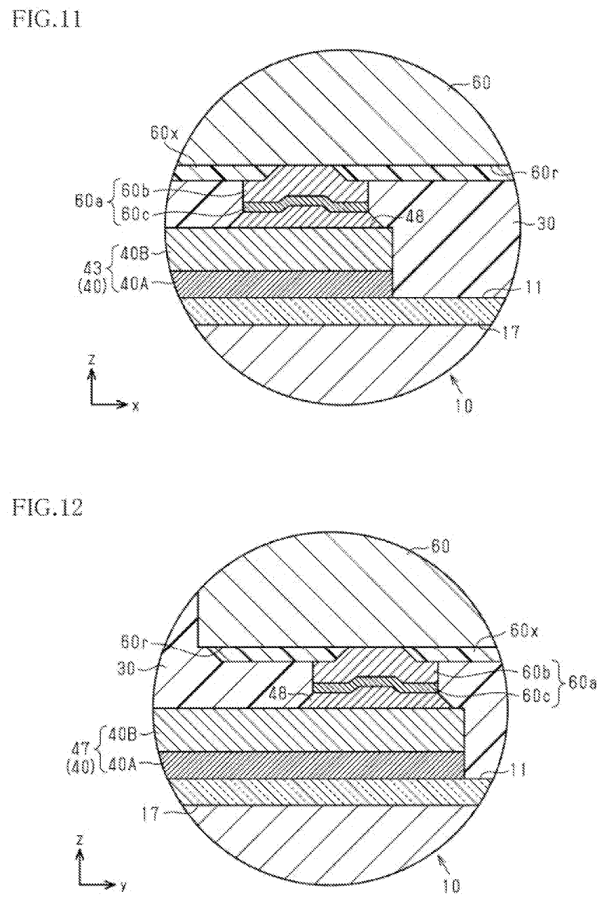

As shown in FIG. 11 and FIG. 12, the plurality of wirings 40 each include an underlying layer 40A and a plated layer 408. The underlying layer 40A is in contact with the insulation film 17 (substrate obverse face 11). The underlying layer 40A includes a barrier layer formed in contact with the substrate obverse face 11, and a seed layer stacked on the barrier layer. The barrier layer is, for example, formed of titanium (Ti). The seed layer is, for example, formed of copper (Cu). The plated layer 408 is stacked on the underlying layer 40A. The plated layer 40B is thicker than the underlying layer 40A. In each of the plurality of wirings 40, the plated layer 40B serves as the primary conduction path. The plated layer 40B is, for example, formed of Cu.

As shown in FIG. 5, the plurality of wirings 40 include first power wirings 41A and 41B, first output wirings 42A and 428, a first ground wiring 43, second power wirings 44A and 449, second output wirings 45A and 459, a second ground wiring 46, and a plurality of control wirings 47. In this embodiment, the first power wirings 41A and 41B, and the second power wirings 44A and 449 correspond to the first drive wiring, and the first output wirings 42A and 42B, the first ground wiring 43, the second output wirings 45A and 45B, and the second ground wiring 46 correspond to the second drive wiring.

The first power wirings 41A and 419, the first output wirings 42A and 42B, the first ground wiring 43, the second power wirings 44A and 44B, the second output wirings 45A and 45B, and the second ground wiring 46 are each electrically connected to the first circuit 61 (see FIG. 4). The first power wirings 41A and 41B and the second power wirings 44A and 44B each serve to supply a current to the first circuit 61 of the semiconductor element 60. The first output wirings 42A and 42B and the second output wirings 45A and 45B each serve to supply a current outputted from the first circuit 61 of the semiconductor element 60 to outside of the semiconductor device 1A. The first ground wiring 43 and the second ground wiring 46 each serve to provide the ground for the first circuit 61. The plurality of control wirings 47 are each electrically connected to the second circuit 62 (see FIG. 4) of the semiconductor element 60. The plurality of control wirings 47 each serve to input an electrical signal from outside of the semiconductor device 1A to the second circuit 62, or to output an electrical signal outputted from the second circuit 62 to outside of the semiconductor device 1A.

As shown in FIG. 5, the first power wirings 41A and 41B, the first output wirings 42A and 42B, and the first ground wiring 43 are located in the vicinity of the substrate side face 13, in the x-direction. The first power wirings 41A and 41B, the first output wirings 42A and 42B, and the first ground wiring 43 are located at the same position in the x-direction, and aligned in the y-direction with a spacing between each other. The first ground wiring 43 is located at the central position in the y-direction, among the first power wirings 41A and 41B, the first output wirings 42A and 428, and the first ground wiring 43. In this embodiment, the first ground wiring 43 is located in the central region of the substrate 10 in the y-direction. The first output wirings 42A and 42B are separately located on the respective sides of the first ground wiring 43 in the y-direction. In this embodiment, the first output wiring 42A is located on the side of the substrate side face 15 with respect to the first ground wiring 43, in the y-direction. The first output wiring 420 is located on the side of the substrate side face 16 with respect to the first ground wiring 43, in the y-direction. The first power wiring 41A is located on the opposite side of the first ground wiring 43 with respect to the first output wiring 42A, in the y-direction. The first power wiring 41B is located on the opposite side of the first ground wiring 43 with respect to the first output wiring 42B, in the y-direction. Thus, the first power wirings 41A and 41B are separately located on the respective outer sides of the first output wirings 42A and 42B and the first ground wiring 43 in the y-direction.

The first power wirings 41A and 41B, the first output wirings 42A and 428, and the first ground wiring 43 each extend in the x-direction. To be more detailed, the first power wirings 41A and 41B, the first output wirings 42A and 42B, and the first ground wiring 43 each extend along the x-direction, from one of the end portions of the substrate 10 in the x-direction on the side of the substrate side face 13, toward the center of the substrate 10 in the x-direction. As shown in FIG. 5, the first power wirings 41A and 41B, the first output wirings 42A and 42B, and the first ground wiring 43 each extend from the outer side of the semiconductor element 60 to the inner side thereof, in the x-direction. Therefore, the first power wirings 41A and 41B, the first output wirings 42A and 42B, and the first ground wiring 43 each include a portion overlapping with the semiconductor element 60, as viewed in the z-direction.

As shown in FIG. 5, the second power wirings 44A and 44B, the second output wirings 45A and 45B, and the second ground wiring 46 are located in the vicinity of the substrate side face 13, in the x-direction. The second power wirings 44A and 44B, the second output wirings 45A and 45B, and the second ground wiring 46 are located at the same position in the x-direction, and aligned in the y-direction with a spacing between each other. The second ground wiring 46 is located at the central position in the y-direction, among the second power wirings 44A and 44B, the second output wirings 45A and 45B, and the second ground wiring 46. In this embodiment, the second ground wiring 46 is located in the central region of the substrate 10 in the y-direction. The second output wirings 45A and 45B are separately located on the respective sides of the second ground wiring 46 in the y-direction. In this embodiment, the second output wiring 45A is located on the side of the substrate side face 15 with respect to the second ground wiring 46, in the y-direction. The second output wiring 45B is located on the side of the substrate side face 15 with respect to the second ground wiring 46, in the y-direction. The second power wiring 44A is located on the opposite side of the second ground wiring 46 with respect to the second output wiring 45A, in the y-direction. The second power wiring 44B is located on the opposite side of the second ground wiring 46 with respect to the second output wiring 45B, in the y-direction. Thus, the second power wirings 44A and 44B are separately located on the respective outer sides of the second output wirings 45A and 45B and the second ground wiring 46 in the y-direction.

The second power wirings 44A and 44B, the second output wirings 45A and 45B, and the second ground wiring 46 each extend in the x-direction. To be more detailed, the second power wirings 44A and 44B, the second output wirings 45A and 45B, and the second ground wiring 46 each extend along the x-direction, from the other end portion of the substrate 10 in the x-direction on the side of the substrate side face 14, toward the center of the substrate 10 in the x-direction. As shown in FIG. 5, the second power wirings 44A and 44B, the second output wirings 45A and 45B, and the second ground wiring 46 each extend from the outer side of the semiconductor element 60 to the inner side thereof, in the x-direction. Therefore, the second power wirings 44A and 440, the second output wirings 45A and 45B, and the second ground wiring 46 each include a portion overlapping with the semiconductor element 60, as viewed in the z-direction.

As shown in FIG. 5, the first power wirings 41A and 41B, the first output wirings 42A and 42B, and the first ground wiring 43 are spaced apart from the second power wirings 44A and 44B, the second output wirings 45A and 45B, and the second ground wiring 46, in the x-direction. The first power wiring 41A is located so as to overlap with the second power wiring 44A, and the first power wiring 41B is located so as to overlap with the second power wiring 44B, as viewed in the x-direction. The first power wiring 42A is located so as to overlap with the second power wiring 45A, and the first power wiring 42B is located so as to overlap with the second power wiring 45B, as viewed in the x-direction. The first ground wiring 43 is located so as to overlap with the second ground wiring 46, as viewed in the x-direction. As shown in FIG. 5, further, the first power wirings 41A and 41B, the first output wirings 42A and 42B, and the first ground wiring 43, and also the second power wirings 44A and 44B, the second output wirings 45A and 45B, and the second ground wiring 46 are each located so as to overlap with the semiconductor element 60, as viewed in the x-direction.

As shown in FIG. 5, the plurality of control wirings 47 are aligned along the end portions of the substrate 10 in the y-direction, with a spacing between each other in the x-direction. The plurality of control wirings 47 are separately located on both sides of the first power wirings 41A and 41B, the first output wirings 42A and 428, and the first ground wiring 43 in the y-direction. Further, the plurality of control wirings 47 are separately located on both sides of the second power wirings 44A and 44B, the second output wirings 45A and 45B, and the second ground wiring 46, in the y-direction. For the sake of convenience, the plurality of control wirings 47 aligned along one of the end portions of the substrate 10 in the y-direction on the side of the substrate side face 15 will be referred to as “control wirings 47A”, and the plurality of control wirings 47 aligned along the other end portion of the substrate 10 in the y-direction on the side of the substrate side face 16 will be referred to as “control wirings 47B”. The control wirings 47A each include a wiring end section 47a of a rectangular shape, located at the other end portion of the substrate 10 in the y-direction on the side of the substrate side face 16, a connecting wiring section 47b extending from the wiring end section 47a toward the inner region of the substrate 10, and a connecting end section 47c located at the distal end of the connecting wiring section 47b. The control wirings 478 each include a wiring end section 47a of a rectangular shape, located at the end portion of the substrate 10 in the y-direction on the side of the substrate side face 15, a connecting wiring section 47b extending from the wiring end section 47a toward the inner region of the substrate 10, and a connecting end section 47c located at the distal end of the connecting wiring section 47b. As shown in FIG. 5, the respective wiring end sections 47a of the control wirings 47A and 47B are located on the outer side of the semiconductor element 60, in the y-direction. The wiring end sections 47a of the control wirings 47A are located between the semiconductor element 60 and the substrate side face 15 in the y-direction, as viewed in the z-direction. The wiring end sections 47a of the control wirings 47B are located between the semiconductor element 60 and the substrate side face 16 in the y-direction, as viewed in the z-direction. The respective connecting wiring sections 47b of the control wirings 47A and 47B extend from outside of the semiconductor element 60 to the inner side thereof, as viewed in the z-direction. The respective connecting end sections 47c of the control wirings 47A and 47B are located so as to overlap with the semiconductor element 60, as viewed in the z-direction.

As described above, the semiconductor device 1A is what is known as a fan-out semiconductor device, in which the plurality of wirings 40 each extend from the position overlapping with the semiconductor element 60 in the z-direction, to outside thereof, and the plurality of conductors 50 are located on the outer side of the semiconductor element 60.

As shown in FIG. 4 and FIG. 8, the semiconductor element 60 is mounted on the plurality of wirings 40. As shown in FIG. 8, the semiconductor element 60 includes an element obverse face 60s and an element reverse face 60r, oriented to the opposite sides in the z-direction. The element obverse face 60s is oriented to the same side as is the substrate obverse face 11 in the z-direction, and the element reverse face 60r is oriented to the same side as is the substrate reverse face 12 in the z-direction. On the element reverse face 60r, an insulation film 60x and a plurality of element electrodes 60a are formed. As shown in FIG. 4 and FIG. 8, the semiconductor element 60 according to this embodiment is of a flip-chip mounting type.

As shown in FIG. 8, FIG. 11, and FIG. 12, a plurality of element electrodes 60a are bonded to the plurality of wirings 40, via a solder layer 48. The plurality of element electrodes 60a each include a conductive section 60b and a barrier layer 60c. The conductive section 60b is, for example, formed of Cu. The barrier layer 60c is formed of a nickel (Ni) layer. The barrier layer 60c is stacked on the conductive section 60b, so as to cover the end face of the conductive section 60b. The presence of the barrier layer 60c in the element electrode 60a suppresses the conductive section 60b, which is formed of Cu, from permeating into the solder layer 48. Here, the barrier layer 60c may include a Ni layer, a palladium (Pd) layer, and a gold (Au) layer stacked on each other.

The insulation film 60x covers the element reverse face 60r, and also the peripheral edge of the element electrode 60a. The insulation film 60x is, for example, formed of a polyimide resin. The insulation film 60x covers a part of the element electrode 60a, so as to expose a part of the surface of the element electrode 60a, as a connection terminal. Here, the insulation film 60x may be formed of silicon nitride (SiN).

As shown in FIG. 4 to FIG. 10, the plurality of conductors 50 are respectively located on the plurality of wirings 40. As shown in FIG. 4, the plurality of conductors 50 are located on the outer side of the semiconductor element 60, as viewed in the z-direction. In other words, the semiconductor element 60 is surrounded by the plurality of conductors 50. As shown in FIG. 8 to FIG. 10, the conductor 50 is stacked on the face of the wiring 40 on the opposite side of the substrate 10, in the z-direction. Accordingly, the conductor 50 may be described as protruding in the direction away from the substrate obverse face 11, in the z-direction. As shown in FIG. 4 and FIG. 5, the plurality of conductors 50 are located on the inner side of the substrate side faces 13 to 16, as viewed in the z-direction. In other words, the plurality of conductors 50 are located so as to overlap with the substrate obverse face 11, as viewed in the z-direction. Therefore, as shown in FIG. 3, the plurality of conductors 50 are located on the inner side of the peripheral edge of the sealing resin 30, as viewed in the z-direction. The plurality of conductors 50 are each formed of Cu. The plurality of conductors 50 each include a top face 50A, oriented to the same side as is the substrate obverse face 11, in the z-direction. The top face 50A of each of the plurality of conductors 50 is exposed from the sealing resin 30, in the z-direction.

As shown in FIG. 4, the plurality of conductors 50 include first power conductors 51A and 51B, first output conductors 52A and 52B, a first ground conductor 53, second power conductors 54A and 54B, second output conductors 55A and 55B, a second ground conductor 56, and a plurality of control conductors 57. The first power conductors 51A and 51B, the first output conductors 52A and 52B, the first ground conductor 53, the second power conductors 54A and 54B, the second output conductors 55A and 55B, and the second ground conductor 56 are each electrically connected to the first circuit 61 of the semiconductor element 60. The plurality of control conductors 57 are electrically connected to the second circuit 62 of the semiconductor element 60. In this embodiment, the first power conductors 51A and 51B and the second power conductors 54A and 54B correspond to the first drive conductor, and the first output conductors 52A and 52B, the first ground conductor 53, the second output conductors 55A and 55B, and the second ground conductor 56 correspond to the second drive conductor.

As shown in FIG. 4, the first power conductors 51A and 51B, the first output conductors 52A and 52B, the first ground conductor 53, the second power conductors 54A and 54B, the second output conductors 55A and 55B, and the second ground conductor 56 each have a top face 50A having a rectangular shape, with the long sides extending in the x-direction, and the short sides extending in the y-direction, as viewed in the z-direction. The control conductors 57 each have a rectangular shape, with the sides extending in the x-direction and the sides extending in the y-direction, as viewed in the z-direction.

Here, the shape of the top face 50A of the first power conductors 51A and 51B, the first output conductors 52A and 528, the first ground conductor 53, the second power conductors 54A and 54B, the second output conductors 55A and 55B, and the second ground conductor 56, viewed in the z-direction, may be modified as desired. For example, the first power conductors 51A and 51B, the first output conductors 52A and 52B, the first ground conductor 53, the second power conductors 54A and 54B, the second output conductors 55A and 55B, and the second ground conductor 56 may each have a top face 50A having an elliptical shape, with the major axis extending in the x-direction and the minor axis extending in the y-direction, as viewed in the z-direction. The control conductors 57 may each have a circular or elliptical shape, as viewed in the z-direction.

The first power conductor 51A is electrically connected to the first power wiring 41A of the wiring 40. Accordingly, the first power conductor 51A is electrically connected to the first circuit 61, via the first power wiring 41A. The first power conductor 51B is electrically connected to the first power wiring 41B of the wiring 40. Accordingly, the first power conductor 51B is electrically connected to the first circuit 61, via the first power wiring 41B.

The first output conductor 52A is electrically connected to the first output wiring 42A of the wiring 40. Accordingly, the first output conductor 52A is electrically connected to the first circuit 61, via the first output wiring 42A. The first output conductor 52B is electrically connected to the first output wiring 42B of the wiring 40. Accordingly, the first output conductor 52B is electrically connected to the first circuit 61, via the first output wiring 42B.

The first ground conductor 53 is electrically connected to the first ground wiring 43 of the wiring 40. Accordingly, the first ground conductor 53 is electrically connected to the first circuit 61, via the first ground wiring 43.

The second power conductor 54A is electrically connected to the second power wiring 44A of the wiring 40. Accordingly, the second power conductor 54A is electrically connected to the first circuit 61, via the second power wiring 44A. The second power conductor 54B is electrically connected to the second power wiring 44B of the wiring 40. Accordingly, the second power conductor 54B is electrically connected to the first circuit 61, via the second power wiring 44B.

The second output conductor 55A is electrically connected to the second output wiring 45A of the wiring 40. Accordingly, the second output conductor 55A is electrically connected to the first circuit 61, via the second output wiring 45A. The second output conductor 55B is electrically connected to the second output wiring 45B of the wiring 40. Accordingly, the second output conductor 55B is electrically connected to the first circuit 61, via the second output wiring 453.

The second ground conductor 56 is electrically connected to the second ground wiring 46 of the wiring 40. Accordingly, the second ground conductor 56 is electrically connected to the first circuit 61, via the second ground wiring 46.

The plurality of control conductors 57 are electrically connected to the respective control wirings 47 of the wiring 40. Accordingly, the plurality of control conductors 57 are electrically connected to the second circuit 62, via the plurality of control wirings 47.

The first power conductors 51A and 51B, the first output conductors 52A and 52B, and the first ground conductor 53 are located along one of the end portions of the substrate obverse face 11 in the x-direction, on the side of the substrate side face 13. The first power conductors 51A and 51B, the first output conductors 52A and 52B, and the first ground conductor 53 are located at the same position in the x-direction, and aligned in the y-direction with a spacing between each other. The second power conductors 54A and 54B, the second output conductors 55A and 55B, and the second ground conductor 56 are located along the other end portion of the substrate obverse face 11 in the x-direction, on the side of the substrate side face 14. The second power conductors 54A and 54B, the second output conductors 55A and 55B, and the second ground conductor 56 are located at the same position in the x-direction, and aligned in the y-direction with a spacing between each other.

As described above, the first power conductors 51A and 51B, the first output conductors 52A and 528, and the first ground conductor 53 are aligned in the y-direction, corresponding to the width direction of the substrate 10, and extend in the x-direction corresponding to the longitudinal direction of the substrate 10. The second power conductors 54A and 54B, the second output conductors 55A and 55B, and the second ground conductor 56 are aligned in the y-direction, corresponding to the width direction of the substrate 10, and extend in the x-direction corresponding to the longitudinal direction of the substrate 10.

As shown in FIG. 1 and FIG. 2, the sealing resin 30 is formed in a rectangular flat plate shape, and in contact with the substrate obverse face 11. The sealing resin 30 is thinner than the substrate 10. In other words, substrate 10 is thicker than the sealing resin 30. The sealing resin 30 is formed of an electrically insulative resin material. The sealing resin 30 is, for example, formed of a thermosetting resin. In this embodiment, the sealing resin 30 is formed of a black epoxy resin.

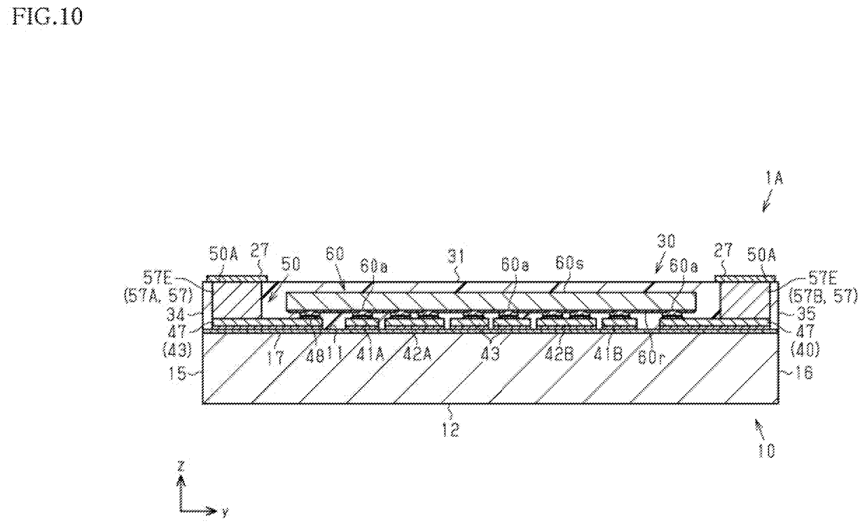

As shown in FIG. 2, FIG. 3, and FIG. 8 to FIG. 10, the sealing resin 30 includes a mounting surface 31 oriented to the same side as is the substrate obverse face 11 in the z-direction, and four resin side faces 32 to 35. As shown in FIG. 3, the resin side faces 32 and 33 are spaced apart from each other in the x-direction, and oriented to the opposite sides to each other in the x-direction. The resin side faces 32 and 33 each extend along the y-direction. The resin side faces 34 and 35 are spaced apart from each other in the y-direction, and oriented to the opposite sides to each other in the y-direction. The resin side faces 34 and 35 each extend along the x-direction. As shown in FIG. 3, the sealing resin 30 has a rectangular shape with the long sides extending in the x-direction, and the short sides extending in the y-direction, as viewed in the z-direction. Accordingly, the resin side faces 32 and 33 constitute the short sides, and the resin side faces 34 and 35 constitute the long sides, of the sealing resin 30 viewed in the z-direction. In this embodiment, as shown in FIG. 9, the substrate side face 13 and the resin side face 32 are flush with each other, and the substrate side face 14 and the resin side face 33 are flush with each other. Likewise, as shown in FIG. 10, the substrate side face 15 and the resin side face 34 are flush with each other, and the substrate side face 16 and the resin side face 35 are flush with each other.

As shown in FIG. 3 and FIG. 8 to FIG. 10, the mounting surface 31 is to oppose the circuit board, when the semiconductor device 1A is mounted thereon. The top face 50A of each of the plurality of conductors 50 is exposed from the mounting surface 31. On the top face 50A of the plurality of conductors 50, exposed from the mounting surface 31, the plurality of terminals 20 are respectively provided. Here, the top face 50A of each of the conductors 50 is oriented in the same direction as is the mounting surface 31 (substrate obverse face 11), in the z-direction.

As shown in FIG. 2 and FIG. 3, the plurality of terminals 20 are each exposed to outside of the semiconductor device 1A. In other words, although the respective top faces 50A of the plurality of conductors 50 are exposed from the mounting surface 31 as shown in FIG. 3 and FIG. 8 to FIG. 10, the top faces 50A are respectively covered with the plurality of terminals 20, and therefore the top faces 50A are not exposed to outside of the semiconductor device 1A. By bonding the plurality of terminals 20 to the circuit board, for example via solder, the semiconductor device 1A can be mounted on the circuit board. The plurality of terminals 20 are each formed of a plurality of metal layers, namely a Ni layer, a Pd layer, and an Au layer stacked in this order from the side of the top face 50A of the plurality of conductors 50.

Hereunder, a detailed configuration of the semiconductor element 60, and a detailed connection arrangement among the semiconductor element 60, the plurality of wirings 40, the plurality of conductors 50, and the plurality of terminals 20, will be described. In this embodiment, as shown in FIG. 4, the first circuit 61 includes a first switching unit 61A, a second switching unit 618, a third switching unit 61C, and a fourth switching unit 61D. The switching units 61A to 61D each include two switching elements connected in series to act as a plurality of switching circuit that convert power, and two driver circuits that drive the respective switching element. The second circuit 62 includes a control circuit that controls, for example, each of the switching units 61A to 61D. For example, a metal-oxide-semiconductor field-effect transistor (MOSFET) is employed as the switching element. In this case, in each of the switching units 61A to 61D, the source of the MOSFET constituting the upper arm and the drain of the MOSFET constituting the lower arm are connected. When the MOSFET is employed as the switching element, the driver circuits each provide electrical signals for controlling the action of the MOSFET, to the gate of the MOSFET. Here, the switching element may be constituted of a different transistor such as an insulated gate bipolar transistor (IGBT), without limitation to the MOSFET. In addition, the driver circuit of the first switching unit 61A may include a driver circuit that drives one of the two switching elements of the first switching unit 61A, and another driver circuit that drives the other switching element. The driver circuit of each of the switching units 61B to 61D may also be modified in the same way as that of the first switching unit 61A.

In this embodiment, as shown in FIG. 4, a circuit region RD, on which the second circuit 62 is formed, has an H-shape including two recesses RD1 and RD2 receding in the opposite directions to each other in the x-direction, as viewed in the z-direction. The circuit region RD is formed generally over the entirety of the semiconductor element 60, as viewed in the z-direction. The recess RD1 is a rectangular recess, receding from one of the edges of the circuit region RD in the x-direction on the side of the substrate side face 13, toward the center of the semiconductor element 60 in the x-direction. The recess RD2 is a rectangular recess, receding from the other edge of the circuit region RD in the x-direction on the side of the substrate side face 14, toward the center of the semiconductor element 60 in the x-direction.

Hereinafter, a circuit region where the first switching unit 61A is formed will be referred to as circuit region RSA, a circuit region where the second switching unit 61B is formed will be referred to as circuit region RSB, a circuit region where the third switching unit 61C is formed will be referred to as circuit region RSC, and a circuit region where the fourth switching unit 61D is formed will be referred to as circuit region RSD. In this embodiment, the circuit regions RSA to RSD each have a rectangular shape, as viewed in the z-direction. Further, the circuit regions RSA to RSD have the same size as one another, as viewed in the z-direction.

The circuit regions RSA and RSB are each located inside the recess RD1 of the circuit region RD. The circuit regions RSA and RSB are located at the same position in the x-direction, and aligned in the y-direction with a spacing between each other. The circuit region RSA is located closer to the substrate side face 15 in the y-direction, than is the circuit region RSB. In other words, circuit region RSB is located closer to the substrate side face 16 in the y-direction, than is the circuit region circuit region RSA.

The circuit regions RSC and RSD are each located inside the recess RD2 of the circuit region RD. The circuit regions RSC and RSD are located at the same position in the x-direction, and aligned in the y-direction with a spacing between each other. The circuit region RSC is located closer to the substrate side face 15 in the y-direction, than is the circuit region RSD. In other words, circuit region RSD is located closer to the substrate side face 16 in the y-direction, than is the circuit region circuit region RSC. As viewed in the x-direction, the circuit region RSC overlaps with the circuit region RSA, and the circuit region RSD overlaps with the circuit region RSB.

As shown in FIG. 4, the second circuit 62 is electrically connected to one of the control wirings 47, at each of the four corners of the semiconductor element 60, as viewed in the z-direction. Hereinafter, regarding the circuit region RD where the second circuit 62 is formed, a region close to each of the substrate side faces 13 and 15 will be referred to as first region R1, a region close to each of the substrate side faces 13 and 16 will be referred to as second region R2, a region close to each of the substrate side faces 14 and 15 will be referred to as third region R3, and a region close to each of the substrate side faces 14 and 16 will be referred to as fourth region R4.

The control wirings 47A are connected to the second circuit 62, in the first region R1 and the third region R3. One of the control wirings 47A located on the side of the substrate side face 13 is connected to the second circuit 62 in the first region R1, and the other control wiring 47A located on the side of the substrate side face 14 is connected to the second circuit 62 in the third region R3. The control wirings 47B are connected to the second circuit 62, in the second region R2 and the fourth region R4. One of the control wirings 47B located on the side of the substrate side face 13 is connected to the second circuit 62 in the second region R2, and the other control wiring 47B located on the side of the substrate side face 14 is connected to the second circuit 62 in the fourth region R4.

As shown in FIG. 4, the first switching unit 61A is electrically connected to the first power wiring 41A, the first output wiring 42A, and the first ground wiring 43. The second switching unit 618 is electrically connected to the first power wiring 41B, the first output wiring 42B, and the first ground wiring 43.

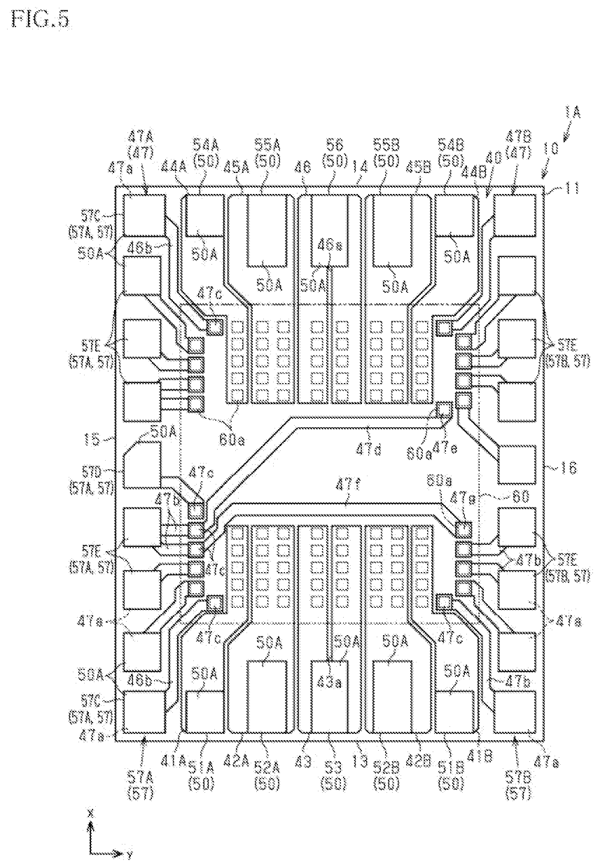

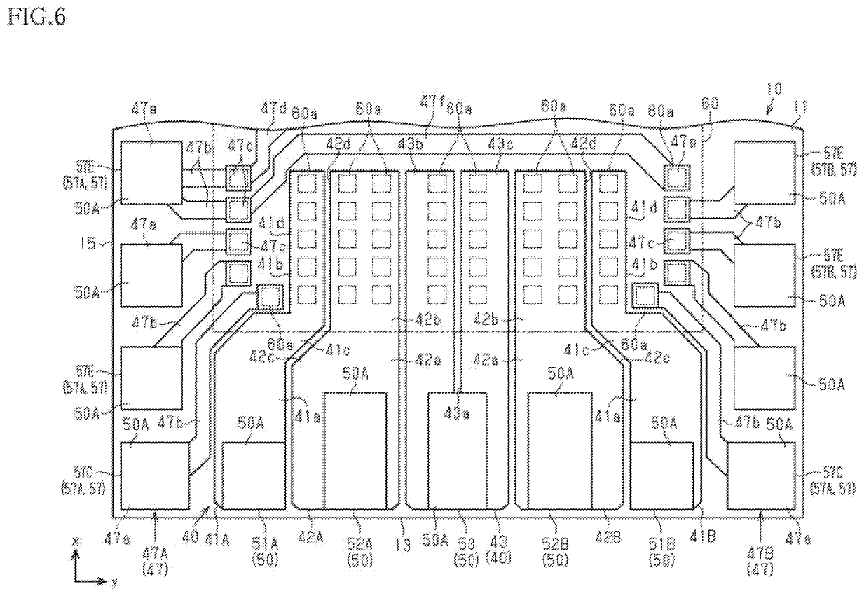

As shown in FIG. 6, the first ground wiring 43 extends along the x-direction. In this embodiment, the width of the first ground wiring 43 constant, along the x-direction. The first ground wiring 43 is wider than the connecting wiring section 47b of the control wiring 47. Here, the width of the first ground wiring 43 refers to the length of the portion thereof extending in the direction orthogonal to the direction in which the first ground wiring 43 extends, as viewed in the z-direction. In this embodiment, the width of the first ground wiring 43 corresponds to the length thereof in the y-direction. At the central portion of the first ground wiring 43 in the y-direction, a slit 43a is formed so as to extend in the x-direction. The slit 43a extends in the x-direction over the range between the edge of the first ground wiring 43 on the side of the center of the substrate 10 in the x-direction, and a position on the side of the substrate side face 13. The portions of the first ground wiring 43, divided by the slit 43a so as to be spaced apart from each other in the y-direction, will be respectively referred to as a first wiring section 43b and a second wiring section 43c. The first wiring section 43b is located closer to the first output wiring 42A, than is the second wiring section 43c. In other words, the second wiring section 43c is located closer to the first output wiring 42B than is the first wiring section 43b.

As viewed in the z-direction, on the portion of the first wiring section 43b overlapping with the semiconductor element 60, a plurality of (in this embodiment, five) element electrodes 60a are bonded. These element electrodes 60a are located at the same position in the y-direction, and aligned in the x-direction with a spacing between each other.

As viewed in the z-direction, on the portion of the first wiring section 43c overlapping with the semiconductor element 60, a plurality of (in this embodiment, five) element electrodes 60a are bonded. These element electrodes 60a are located at the same position in the y-direction, and aligned in the x-direction with a spacing between each other.

The first output wiring 42A includes a wide wiring section 42a which is relatively wider, and a narrow wiring section 42b which is relatively narrower. The first output wiring 42A is wider than the connecting wiring section 47b of the control wiring 47. The width of the first output wiring 42A refers to the length of the portion thereof extending in the direction orthogonal to the direction in which the first output wiring 42A extends, as viewed in the z-direction.

The wide wiring section 42a is located closer to the substrate side face 13 than is the narrow wiring section 42b, in the x-direction. In other words, the narrow wiring section 42b is located closer to the semiconductor element 60 than is the wide wiring section 42a in the x-direction. The wide wiring section 42a is located closer to the substrate side face 13 than is the semiconductor element 60, as viewed in the z-direction. The narrow wiring section 42b overlaps with the semiconductor element 60, as viewed in the z-direction.

The narrow wiring section 42b extends along the x-direction. To the narrow wiring section 42b, a plurality of (in this embodiment, ten) element electrodes 60a are bonded. As shown in FIG. 5, two rows of the element electrodes 60a, each including five of the ten element electrodes 60a located at the same position in the y-direction and aligned in the x-direction with a spacing between each other, are aligned in the y-direction with a spacing between each other.

The wide wiring section 42a includes a sloped section 42c, formed adjacent to the narrow wiring section 42b, so as to be narrower in the direction toward the narrow wiring section 42b in the x-direction. The sloped section 42c is formed along the edge of the wide wiring section 42a on the side of the first power wiring 41A, in the y-direction. Accordingly, the first output wiring 42A includes a recessed region 42d defined by the sloped section 42c and the narrow wiring section 42b, so as to recede in the y-direction.

The first power wiring 41A includes a wide wiring section 41a which is relatively wider, a narrow wiring section 41b which is relatively narrower, and a connecting wiring section 41c connecting between the wide wiring section 41a and the narrow wiring section 41b. The first power wiring 41A is wider than the connecting wiring section 47b of the control wiring 47. Here, the width of the first power wiring 41A refers to the length of the portion thereof extending in the direction orthogonal to the direction in which the first power wiring 41A extends, as viewed in the z-direction. The width of the connecting wiring section 47b refers to the length of the portion thereof extending in the direction orthogonal to the direction in which the connecting wiring section 47b extends, as viewed in the z-direction.

The wide wiring section 41a is located closer to the substrate side face 13 than is the narrow wiring section 41b, in the x-direction. In other words, the narrow wiring section 41b is located closer to the semiconductor element 60 than is the wide wiring section 41a, in the x-direction. The wide wiring section 41a is located closer to the substrate side face 13, than is the semiconductor element 60. The wide wiring section 41a extends along the x-direction, from the end portion of the substrate obverse face 11 on the side of the substrate side face 13. The wide wiring section 41a is narrower than the wide wiring section 42a of the first output wiring 42A. In other words, the wide wiring section 42a is wider than the wide wiring section 41a of the first power wiring 41A. The width of the wide wiring section 41a refers to the length of the portion thereof extending in the direction orthogonal to the direction in which the wide wiring section 41a extends, as viewed in the z-direction. In this embodiment, the width of the wide wiring section 41a corresponds to the length thereof in the y-direction. The width of the wide wiring section 42a refers to the length of the portion thereof extending in the direction orthogonal to the direction in which the wide wiring section 42a extends, as viewed in the z-direction. In this embodiment, the width of the wide wiring section 42a corresponds to the length thereof in the y-direction.

The narrow wiring section 41b is located closer to the first output wiring 42A than is the wide wiring section 41a, in the y-direction. The narrow wiring section 41b overlaps with the semiconductor element 60, as viewed in the z-direction. The narrow wiring section 41b extends along the x-direction. The narrow wiring section 41b is narrower than the narrow wiring section 42b of the first output wiring 42A. In other words, the narrow wiring section 42b is wider than the narrow wiring section 41b of the first power wiring 41A. The width of the narrow wiring section 41b refers to the length of the portion thereof extending in the direction orthogonal to the direction in which the narrow wiring section 41b extends, as viewed in the z-direction. In this embodiment, the width of the narrow wiring section 41b corresponds to the length thereof in the y-direction. The width of the narrow wiring section 42b refers to the length of the portion thereof extending in the direction orthogonal to the direction in which the narrow wiring section 42b extends, as viewed in the z-direction. In this embodiment, the width of the narrow wiring section 42b corresponds to the length thereof in the y-direction.

To the narrow wiring section 41b, a plurality of (in this embodiment, five) element electrodes 60a are bonded. These element electrodes 60a are located at the same position in the y-direction, and aligned in the x-direction with a spacing between each other.

The connecting wiring section 41c obliquely extends, so as to be closer to the first output wiring 42A in the y-direction, in the direction from the wide wiring section 41a toward the narrow wiring section 41b in the x-direction. A part of the connecting wiring section 41c overlaps with the semiconductor element 60, as viewed in the z-direction. As viewed in the y-direction, the connecting wiring section 41c overlaps with the sloped section 42c of the first output wiring 42A. The width of the connecting wiring section 41c (length thereof in the y-direction) is wider than that of the narrow wiring section 41b.

The first power wiring 41A includes a recessed region 41d defined by the narrow wiring section 41b and the connecting wiring section 41c, so as to recede in the y-direction. The recessed region 41d overlaps with the semiconductor element 60, as viewed in the z-direction. In the recessed region 41d, the respective connecting end sections 47c of five of the control wirings 47A, located on the side of the substrate side face 13, are located. By forming thus the recessed region 41d to secure the space for locating the connecting end sections 47c of the control wirings 47A, the portion of the first power wiring 41A on the side of the center of the substrate 10 in the x-direction becomes narrower. For such reason, the narrow wiring section 41b of the first power wiring 41A is formed.

The narrow wiring section 41b and the connecting wiring section 41c are located inside the recessed region 42d of the first output wiring 42A. This allows the narrow wiring section 41b to be located closer to the center of the substrate 10 in the y-direction, than is the wide wiring section 41a, thereby enabling the connecting end sections 47c of the five control wirings 47A close to the substrate side face 13, to be located so as to overlap with the first region R1 (see FIG. 4) of the semiconductor element 60, as viewed in the z-direction.

The first output wiring 42B is symmetrical to the first output wiring 42A, with respect to an imaginary center line of the substrate obverse face 11, passing the center thereof in the y-direction and extending in the x-direction. Accordingly, the first output wiring 42B includes, like the first output wiring 42A, the wide wiring section 42a, the narrow wiring section 42b, and the sloped section 42c. The first output wiring 42B also includes the recessed region 42d. To the narrow wiring section 42b, ten element electrodes 60a are bonded. The arrangement pattern of these ten element electrodes 60a is the same as that of the ten element electrodes 60a on the narrow wiring section 42b of the first output wiring 42A.

The first power wiring 41B is symmetrical to the first power wiring 41A, with respect to the imaginary center line of the substrate obverse face 11, passing the center thereof in the y-direction and extending in the x-direction. Accordingly, the first power wiring 41B includes, like the first power wiring 41A, the wide wiring section 41a, the narrow wiring section 41b, and the connecting wiring section 41c. To the narrow wiring section 41b, five element electrodes 60a are bonded. The arrangement pattern of these five element electrodes 60a is the same as that of the five element electrodes 60a on the narrow wiring section 41b of the first power wiring 41A. The narrow wiring section 41b and the connecting wiring section 41c are, like the narrow wiring section 41b and the connecting wiring section 41c of the first power wiring 41A, each located inside the recessed region 42d of the first output wiring 42B. Therefore, the connecting end sections 47c of the four control wirings 47B close to the substrate side face 13 can be located so as to overlap with the second region R2 (see FIG. 4) of the semiconductor element 60, as viewed in the z-direction.

As shown in FIG. 6, the area of the first output wiring 42A viewed in the z-direction, and the area of the first ground wiring 43 viewed in the z-direction are larger than the area of the first power wiring 41A viewed in the z-direction. The area of the first output wiring 42B viewed in the z-direction, and the area of the first ground wiring 43 viewed in the z-direction are larger than the area of the first power wiring 413 viewed in the z-direction.

As shown in FIG. 4, the third switching unit 61C is electrically connected to the second power wiring 44A, the second output wiring 45A, and the second ground wiring 46. The fourth switching unit 61D is electrically connected to the second power wiring 44B, the second output wiring 45B, and the second ground wiring 46.

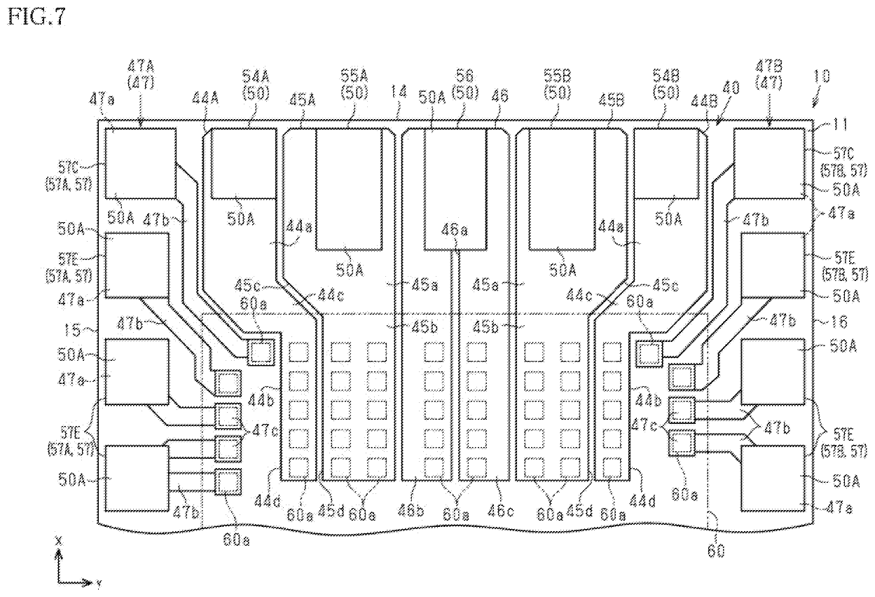

As shown in FIG. 7, the second ground wiring 46 extends along the x-direction. To be more detailed, the shape of the second ground wiring 46 viewed in the z-direction is symmetrical to that of the first ground wiring 43 viewed in the z-direction, with respect to an imaginary line, passing the center of the substrate 10 in the x-direction and extending in the y-direction. Accordingly, the second ground wiring 46 includes a slit 46a corresponding to the slit 43a of the first ground wiring 43, and a first wiring section 46b and a second wiring section 46c, respectively corresponding to the first wiring section 43b and the second wiring section 43c. The first wiring section 46b is located closer to the second output wiring 45A, than is the second wiring section 46c. In other words, the second wiring section 46c is located closer to the second output wiring 45B, than is the first wiring section 46b.

As viewed in the z-direction, on the portion of the first wiring section 46b overlapping with the semiconductor element 60, a plurality of (in this embodiment, five) element electrodes 60a are bonded. These element electrodes 60a are located at the same position in the y-direction, and aligned in the x-direction with a spacing between each other.

As viewed in the z-direction, on the portion of the second wiring section 46c overlapping with the semiconductor element 60, a plurality of (in this embodiment, five) element electrodes 60a are bonded. These element electrodes 60a are located at the same position in the y-direction, and aligned in the x-direction with a spacing between each other.

The second output wiring 45A extends along the x-direction. To be more detailed, the shape of the second output wiring 45A viewed in the z-direction is symmetrical to that of the first output wiring 42A viewed in the z-direction, with respect to the imaginary line, passing the center of the substrate 10 in the x-direction and extending in the y-direction. Accordingly, the second output wiring 45A includes a wide wiring section 45a, a narrow wiring section 45b, and a sloped section 45c, respectively corresponding to the wide wiring section 42a, the narrow wiring section 42b, and the sloped section 42c of the first output wiring 42A. Further, the second output wiring 45A includes a recessed region 45d corresponding to the recessed region 42d of the first output wiring 42A.

The wide wiring section 45a is located closer to the substrate side face 14 than is the narrow wiring section 45b, in the x-direction. In other words, the narrow wiring section 45b is located closer to the semiconductor element 60 (see FIG. 4), than is the wide wiring section 45a, in the x-direction. The wide wiring section 45a is located closer to the substrate side face 14, than is the semiconductor element 60, as viewed in the z-direction. The narrow wiring section 45b overlaps with the semiconductor element 60, as viewed in the z-direction.

To the narrow wiring section 45b, a plurality of (in this embodiment, ten) element electrodes 60a are bonded. The arrangement pattern of these element electrodes 60a is the same as that of the ten element electrodes 60a on the first output wiring 42A.

The second power wiring 44A extends along the x-direction. To be more detailed, the shape of the second power wiring 44A viewed in the z-direction is symmetrical to that of the first power wiring 41A viewed in the z-direction, with respect to the imaginary line, passing the center of the substrate 10 in the x-direction and extending in the y-direction. Accordingly, the second power wiring 44A includes a wide wiring section 44a, a narrow wiring section 44b, and a connecting wiring section 44c, respectively corresponding to the wide wiring section 41a, the narrow wiring section 41b, and the connecting wiring section 41c of the first power wiring 41A. Further, the second power wiring 44A includes a recessed region 44d corresponding to the recessed region 41d of the first power wiring 41A.

The wide wiring section 44a is located closer to the substrate side face 14 than is the narrow wiring section 44b, in the x-direction. In other words, the narrow wiring section 44b is located closer to the semiconductor element 60 than is the wide wiring section 44a, in the x-direction. The wide wiring section 44a includes a portion located closer to the substrate side face 14, than is the semiconductor element 60.

The narrow wiring section 44b is located closer to the second output wiring 45A than is the wide wiring section 44a, in the y-direction. To the narrow wiring section 44b, a plurality of (in this embodiment, five) element electrodes 60a are bonded. These element electrodes 60a are located at the same position in the y-direction, and aligned in the x-direction with a spacing between each other.

The connecting wiring section 44c obliquely extends, so as to be closer to the second output wiring 45A in the y-direction, in the direction from the wide wiring section 44a toward the narrow wiring section 44b in the x-direction. In the recessed region 44d, the respective connecting end sections 47c of four of the control wirings 47A, located on the side of the substrate side face 14, are located. By forming thus the recessed region 44d to secure the space for locating the connecting end sections 47c of the control wirings 47A, the portion of the second power wiring 44A on the side of the center of the substrate 10 in the x-direction becomes narrower. For such reason, the narrow wiring section 44b of the second power wiring 44A is formed.

The narrow wiring section 44b and the connecting wiring section 44c are located in the recessed region 44d of the second output wiring 45A. This allows the narrow wiring section 44b to be located closer to the center of the substrate 10 in the y-direction, than is the wide wiring section 44a, thereby enabling the connecting end sections 47c of the four control wirings 47A close to the substrate side face 14, to be located so as to overlap with the third region R3 (see FIG. 4) of the semiconductor element 60, as viewed in the s-direction.

The second output wiring 45B is symmetrical to the second output wiring 45A, with respect to the imaginary center line of the substrate obverse face 11, passing the center thereof in the y-direction and extending in the x-direction. Accordingly, the second output wiring 45B includes, like the second output wiring 45A, the wide wiring section 45a, the narrow wiring section 45b, and the sloped section 45c. The second output wiring 45B also includes the recessed region 45d. To the narrow wiring section 45b, ten element electrodes 60a are bonded. The arrangement pattern of these ten element electrodes 60a is the same as that of the ten element electrodes 60a on the narrow wiring section 45b of the second output wiring 45A.

The second power wiring 44B is symmetrical to the second power wiring 44A, with respect to the imaginary center line of the substrate obverse face 11, passing the center thereof in the y-direction and extending in the x-direction. Accordingly, the second power wiring 440 includes, like the second power wiring 44A, the wide wiring section 44a, the narrow wiring section 44b, and the connecting wiring section 44c. The wide wiring section 44a is located closer to the substrate side face 14 than is the semiconductor element 60, as viewed in the z-direction. The narrow wiring section 44b overlaps with the semiconductor element 60, as viewed in the z-direction.

To the narrow wiring section 44b, five element electrodes 60a are bonded. The arrangement pattern of these five element electrodes 60a is the same as that of the five element electrodes 60a on the narrow wiring section 44b of the second power wiring 44A. The narrow wiring section 44b and the connecting wiring section 44c are, like the narrow wiring section 44b and the connecting wiring section 44c of the second power wiring 44A, each located inside the recessed region 45d of the second output wiring 45B. Therefore, the connecting end sections 47c of the four control wirings 47B close to the substrate side face 14 can be located so as to overlap with the fourth region R4 (see FIG. 4) of the semiconductor element 60, as viewed in the z-direction.

As shown in FIG. 7, the second output wiring 45A and the second ground wiring 46 are larger in area viewed in the z-direction, than the second power wiring 44A. The second output wiring 45B and the second ground wiring 46 are larger in area viewed in the z-direction, than the second power wiring 44B.

As shown in FIG. 5, the respective wiring end sections 47a of two of the control wirings 47A located at the respective end portions in the x-direction, are larger in area viewed in the z-direction, than the wiring end sections 47a of the remaining control wirings 47A. The wiring end section 47a of the control wiring 47A located at the center in the x-direction, among the control wirings 47A, is larger in area viewed in the z-direction than the respective wiring and sections 47a of the control wirings 47A other than the two control wirings 47A located at the respective end portions in the y-direction. The wiring end section 47a of the control wiring 47A located at the center in the x-direction, among the control wirings 47A, has a rectangular shape with the long sides extending in the x-direction and the short sides extending in the y-direction, as viewed in the z-direction.

Among the control wirings 47A, the control wiring 47A located adjacent to the control wiring 47A located at the center in the x-direction, on the side of the substrate side face 13 in the x-direction, includes two connecting wiring sections 47b and two connecting end sections 47c. This control wiring 47A includes an extended wiring section 47d extending from one of the connecting end sections 47c toward the second power wiring 44B, a connecting end section 47e provided at the distal end of the extended wiring section 47d, an extended wiring section 47f extending from the other connecting end section 47c toward the first power wiring 41B, and a connecting end section 47g provided at the distal end of the extended wiring section 47f. To the connecting end section 47e, the element electrode 60a in the fourth region R4 (see FIG. 4) of the semiconductor element 60 is bonded, via the solder layer 48. To the connecting end section 47g, the element electrode 60a in the second region R2 (see FIG. 4) of the semiconductor element 60 is bonded, via the solder layer 48.

As shown in FIG. 6, the first power conductor 51A is located on the wide wiring section 41a of the first power wiring 41A. In this embodiment, the first power conductor 51A is located on the end portion of the wide wiring section 41a of the first power wiring 41A on the side of the substrate side face 13 in the x-direction. To be more detailed, as viewed in the z-direction, one of the edges of the first power conductor 51A in the x-direction on the side of the substrate side face 13, is aligned with the edge of the wide wiring section 41a of the first power wiring 41A on the side of the substrate side face 13, in the x-direction.

The top face 50A of the first power conductor 51A is shorter in the y-direction, than the width of the wide wiring section 41a of the first power wiring 41A. The first power conductor 51A is located close to one of the edges of the wide wiring section 41a of the first power wiring 41A in the y-direction on the side of the substrate side face 16 (first output wiring 42A). Accordingly, the distance between the first power conductor 51A and the edge of the wide wiring section 41a of the first power wiring 41A in the y-direction on the side of the substrate side face 16 (first output wiring 42A), is shorter than the distance between the first power conductor 51A and another edge of the wide wiring section 41a of the first power wiring 41A in the y-direction on the side of the substrate side face 15. In this embodiment, as viewed in the z-direction, one of the edges of the first power conductor 51A in the y-direction on the side of the substrate side face 16 is aligned with the edge of the wide wiring section 41a of the first power wiring 41A in the y-direction on the side of the substrate side face 16.

The top face 50A of the first power conductor 51A is shorter in the x-direction, than the wide wiring section 41a of the first power wiring 41A. In this embodiment, the length of the top face 50A of the first power conductor 51A in the x-direction is equal to or shorter than a half of the length of the wide wiring section 41a of the first power wiring 41A in the x-direction.

The first power conductor 51B is located on the wide wiring section 41a of the first power wiring 419. In this embodiment, the first power conductor 51B is located on the end portion of the wide wiring section 41a of the first power wiring 41B on the side of the substrate side face 13 in the x-direction. To be more detailed, as viewed in the z-direction, one of the edges of the first power conductor 51B in the x-direction on the side of the substrate side face 13, is aligned with the edge of the wide wiring section 41a of the first power wiring 41B on the side of the substrate side face 13, in the x-direction.

The top face 50A of the first power conductor 51B is shorter in the y-direction, than the width of the wide wiring section 41a of the first power wiring 41B. The first power conductor 51B is located close to one of the edges of the wide wiring section 41a of the first power wiring 41B in the y-direction on the side of the substrate side face 15. Accordingly, the distance between the first power conductor 51B and the edge of the wide wiring section 41a of the first power wiring 41B in the y-direction on the side of the substrate side face 15, is shorter than the distance between the first power conductor 51B and another edge of the wide wiring section 41a of the first power wiring 41B in the y-direction on the side of the substrate side face 16. In this embodiment, as viewed in the z-direction, one of the edges of the first power conductor 51B in the y-direction on the side of the substrate side face 15 is aligned with the edge of the wide wiring section 41a of the first power wiring 41B in the y-direction on the side of the substrate side face 15.

The top face 50A of the first power conductor 51B is shorter in the x-direction, than the wide wiring section 41a of the first power wiring 41B. In this embodiment, the length of the top face 50A of the first power conductor 51B in the x-direction is equal to or shorter than a half of the length of the wide wiring section 41a of the first power wiring 41B in the x-direction.

The top face 50A of the first power conductor 51B has the same length in the x-direction, as the top face 50A of the first power conductor 51A, and the top face 50A of the first power conductor 51B has the same length in the y-direction as the top face 50A of the first power conductor 51A. Accordingly, the top face 50A of the first power conductor 51B has the same area as the top face 50A of the first power conductor 51A. Here, when the difference in area between the top face 50A of the first power conductor 51B and the top face 50A of the first power conductor 51A is, for example, within 5% of the area of the top face 50A of the first power conductor 51A, the area of the top face 50A of the first power conductor 51B may be regarded as being equal to that of the top face 50A of the first power conductor 51A. Since the first power conductors 51A and 510 are both rectangular parallelepipeds, the length in the x-direction or y-direction, of the portion of the first power conductor 51A closer to the substrate 10 than is the top face 50A, is equal to that of the top face 50A of the first power conductor 51A, and the length in the x-direction or y-direction, of the portion of the first power conductor 51B closer to the substrate 10 than is the top face 50A, is equal to that of the top face 50A of the first power conductor 51B.

Though not shown, the first power conductor 51B has the same thickness as the first power conductor 51A. Accordingly, the first power conductor 51B has the same volume as the first power conductor 51A. Here, when the difference in volume between the first power conductor 51B and the first power conductor 51A is, for example, within 5% of the volume of the first power conductor 51A, the volume of the first power conductor 51B may be regarded as being equal to that of the first power conductor 51A.

As shown in FIG. 6, the first output conductor 52A is located on the wide wiring section 42a of the first output wiring 42A. In this embodiment, the first output conductor 52A is located on the end portion of the wide wiring section 42a of the first output wiring 42A on the side of the substrate side face 13 in the x-direction. To be more detailed, as viewed in the z-direction, one of the edges of the first output conductor 52A in the x-direction on the side of the substrate side face 13, is aligned with the edge of the wide wiring section 42a of the first output wiring 42A on the side of the substrate side face 13, in the x-direction.

The top face 50A of the first output conductor 52A is shorter in the y-direction, than the width of the wide wiring section 42a of the first output wiring 42A. The length of the top face 50A of the first output conductor 52A in the y-direction is between ½ and ⅔, both ends inclusive, of the width of the wide wiring section 42a of the first output wiring 42A. The first output conductor 52A is located on the side of one of the edges of the wide wiring section 42a of the first output wiring 42A in the y-direction, on the side of the substrate side face 16 (first ground wiring 43). Accordingly, the distance between the first output conductor 52A and the edge of the wide wiring section 42a of the first output wiring 42A in the y-direction, on the side of the substrate side face 16 (first ground wiring 43), is shorter than the distance between the first output conductor 52A and the other edge of the wide wiring section 42a of the first output wiring 42A in the y-direction, on the side of the substrate side face 15 (first power wiring 41A).

The first output conductor 52A is shorter in the x-direction, than the wide wiring section 42a of the first output wiring 42A. The first output conductor 52A is located on the side of the substrate side face 13 in the x-direction, than is the sloped section 42c of the first output wiring 42A.

The top face 50A of the first output conductor 52A is longer in the x-direction, than the top face 50A of the first power conductor 51A. In other words, the top face 50A of the first power conductor 51A is shorter in the x-direction, than the top face 50A of the first output conductor 52A. In this embodiment, the length of the top face 50A of the first power conductor 51A in the x-direction is between ½ and ⅔, both ends inclusive, of the top face 50A of the first output conductor 52A. The top face 50A of the first output conductor 52A has the same length in the y-direction, as the top face 50A of the first power conductor 51A. Accordingly, the top face 50A of the first power conductor 51A is smaller in area than the top face 50A of the first output conductor 52A. Since the area of the top face 50A of the first power conductor 51A is equal to that of the top face 50A of the first power conductor 51B, the top face 50A of the first power conductor 51B is smaller in area than the top face 50A of the first output conductor 52A. In other words, the top face 50A of the first output conductor 52A is larger in area than the top face 50A of the first power conductor 51A, and also than the top face 50A of the first power conductor 51B. Here, since the first output conductor 52A is a rectangular parallelepiped, the length in the x-direction or y-direction, of the portion of the first output conductor 52A closer to the substrate 10 than is the top face 50A, is equal to that of the top face 50A of the first power conductor 51A.

Though not shown, the first output conductor 52A has the same thickness as the first power conductor 51A. Accordingly, the first output conductor 52A is larger in volume than the first power conductor 51A. In other words, the first power conductor 51A is smaller in volume than the first output conductor 52A. Here, when the difference in volume between the first output conductor 52A and the first power conductor 51A is, for example, within 5% of the volume of the first power conductor 51A, the volume of the first output conductor 52A may be regarded as being equal to that of the first power conductor 51A. Since the first power conductor 51A has the same volume as the first power conductor 51B, the volume of the first power conductor 51B may be regarded as being smaller than that of the first output conductor 52A.

As shown in FIG. 6, the first output conductor 52B is located on the wide wiring section 42a of the first output wiring 42B. In this embodiment, the first output conductor 52B is located on the end portion of the wide wiring section 42a of the first output wiring 42B on the side of the substrate side face 13 in the x-direction. To be more detailed, as viewed in the z-direction, one of the edges of the first output conductor 52B in the x-direction on the side of the substrate side face 13, is aligned with the edge of the wide wiring section 42a of the first output wiring 42B on the side of the substrate side face 13, in the x-direction.

The top face 50A of the first output conductor 52B is shorter in the y-direction, than the width of the wide wiring section 42a of the first output wiring 42B. The length of the top face 50A of the first output conductor 52B in the y-direction is between ½ and ⅔, both ends inclusive, of the width of the wide wiring section 42a of the first output wiring 42B. The first output conductor 52B is located closer to one of the edges of the wide wiring section 42a of the first output wiring 420 in the y-direction, on the side of the substrate side face 15 (first ground wiring 43). Accordingly, the distance between the first output conductor 52B and the edge of the wide wiring section 42a of the first output wiring 42B in the y-direction, on the side of the substrate side face 15 (first ground wiring 43), is shorter than the distance between the first output conductor 52B and the other edge of the wide wiring section 42a of the first output wiring 420 in the y-direction, on the side of the substrate side face 16 (first power wiring 41B).

The first output conductor 52B is shorter in the x-direction, than the wide wiring section 42a of the first output wiring 42B. The first output conductor 52B is located closer to the substrate side face 13 in the x-direction, than is the sloped section 42c of the first output wiring 42B.

The top face 50A of the first output conductor 52B has the same length in the x-direction, as the top face 50A of the first output conductor 52A, and the top face 50A of the first output conductor 52B has the same length in the y-direction as the top face 50A of the first output conductor 52A. Accordingly, the top face 50A of the first output conductor 52B has the same area as the top face 50A of the first output conductor 52A. Here, when the difference in area between the top face 50A of the first output conductor 52B and the top face 50A of the first output conductor 52A is, for example, within 5% of the area of the top face 50A of the first output conductor 52A, the area of the top face 50A of the first output conductor 52B may be regarded as being equal to that of the top face 50A of the first output conductor 52A. Since the top face 50A of the first output conductor 52B has the same area as the top face 50A of the first output conductor 52A, the top face 50A of the first output conductor 52B is larger in area than the top face 50A of the first power conductor 51A, and the top face 50A of the first power conductor 51B. In other words, the top face 50A of the first power conductor 51A and the top face 50A of the first power conductor 51B are each smaller in area than the top face 50A of the first output conductor 520. Here, since the first output conductor 52B is a rectangular parallelepiped, the length in the x-direction or y-direction, of the portion of the first output conductor 52B closer to the substrate 10 than is the top face 50A, is equal to that of the top face 50A of the first output conductor 52B.

Though not shown, the first output conductor 52B has the same thickness as the first output conductor 52A. Accordingly, the first output conductor 52B has the same volume as the first output conductor 52A. Here, when the difference in volume between the first output conductor 52B and the first output conductor 52A is, for example, within 5% of the volume of the first output conductor 52A, the volume of the first output conductor 52B may be regarded as being equal to that of the first output conductor 52A. Since the first output conductor 52B has the same volume as the first output conductor 52A, the first output conductor 528 is larger in volume than the first power conductor 51A and the first power conductor 51B. In other words, the first power conductor 51A and the first power conductor 51B are each smaller in volume than the first output conductor 52B.

As shown in FIG. 6, the first ground conductor 53 is located on one of the end portions of the first ground wiring 43 in the x-direction, on the side of the substrate side face 13. To be more detailed, as viewed in the z-direction, one of the edges of the first ground conductor 53 in the x-direction on the side of the substrate side face 13 is aligned with the edge of the first ground wiring 43 on the side of the substrate side face 13, in the x-direction.

The top face 50A of the first ground conductor 53 is shorter in the y-direction, than the width of the first ground wiring 43. The length of the top face 50A of the first ground conductor 53 in the y-direction is between ½ and ⅔, both ends inclusive, of the width of the first ground wiring 43. The first ground conductor 53 is located on the central portion of the first ground wiring 43, in the y-direction.

The top face 50A of the first ground conductor 53 has the same length in the x-direction, as the top face 50A of the first output conductor 52A. The top face 50A of the first ground conductor 53 has the same length in the y-direction as the top face 50A of the first output conductor 52A. Accordingly, the top face 50A of the first ground conductor 53 has the same area as the top face 50A of the first output conductor 52A. Here, when the difference in area between the top face 50A of the first ground conductor 53 and the top face 50A of the first output conductor 52A is, for example, within 5% of the area of the top face 50A of the first output conductor 52A, the area of the top face 50A of the first ground conductor 53 may be regarded as being equal to that of the top face 50A of the first output conductor 52A. Since the top face 50A of the first ground conductor 53 has the same area as the top face 50A of the first output conductor 52A as above, the top face 50A of the first ground conductor 53 is larger in area than the top face 50A of the first power conductor 51A, and the top face 50A of the first power conductor 51B. In other words, the top face 50A of the first power conductor 51A and the top face 50A of the first power conductor 51B are each smaller in area than the top face 50A of the first ground conductor 53. Here, since the first ground conductor 53 is a rectangular parallelepiped, the length in the x-direction or y-direction, of the portion of the first ground conductor 53 closer to the substrate 10 than is the top face 50A, is equal to that of the top face 50A of the first ground conductor 53.

Though not shown, the first ground conductor 53 has the same thickness as the first output conductor 52A. Accordingly, the first ground conductor 53 has the same volume as the first output conductor 52A. Here, when the difference in volume between the first ground conductor 53 and the first output conductor 52A is, for example, within 5% of the volume of the first output conductor 52A, the volume of the first ground conductor 53 may be regarded as being equal to that of the first output conductor 52A. Since the first ground conductor 53 has the same volume as the first output conductor 52A as above, the first ground conductor 53 is larger in volume than the first power conductor 51A and the first power conductor 519. In other words, the first power conductor 51A and the first power conductor 519 are each smaller in volume than the first ground conductor 53.

As shown in FIG. 7, the second power conductor 54A is located on the wide wiring section 44a of the second power wiring 44A. In this embodiment, the second power conductor 54A is located on the end portion of the wide wiring section 44a of the second power wiring 44A on the side of the substrate side face 14 in the x-direction. To be more detailed, as viewed in the z-direction, one of the edges of the second power conductor 54A in the x-direction on the side of the substrate side face 14, is aligned with the edge of the wide wiring section 44a of the second power wiring 44A on the side of the substrate side face 14, in the x-direction.

The top face 50A of the second power conductor 54A is shorter in the y-direction, than the width of the wide wiring section 44a of the second power wiring 44A. The width of the wide wiring section 44a of the second power wiring 44A refers to the size of the portion thereof extending in the direction orthogonal to the direction in which the wide wiring section 44a of the second power wiring 44A extends, as viewed in the s-direction. In this embodiment, the width of the wide wiring section 44a of the second power wiring 44A corresponds to the length thereof in the y-direction. The second power conductor 54A is located close to one of the edges of the wide wiring section 44a of the second power wiring 44A in the y-direction on the side of the substrate side face 16 (second output wiring 45A). Accordingly, the distance between the second power conductor 54A and one of the edges of the wide wiring section 44a of the second power wiring 44A in the y-direction on the side of the substrate side face 16 (second output wiring 45A), is shorter than the distance between the second power conductor 54A and another edge of the wide wiring section 44a of the second power wiring 44A in the y-direction on the side of the substrate side face 15. In this embodiment, as viewed in the z-direction, one of the edges of the second power conductor 54A in the y-direction on the side of the substrate side face 16 is aligned with the edge of the wide wiring section 44a of the second power wiring 44A in the y-direction on the side of the substrate side face 16 (second output wiring 45A).

The second power conductor 54A is shorter than the wide wiring section 44a of the second power wiring 44A, in the x-direction. In this embodiment, the length of the second power conductor 54A in the x-direction is equal to or shorter than ½ of that of the wide wiring section 44a of the second power wiring 44A.

As shown in FIG. 5, the top face 50A of the second power conductor 54A has the same length in the x-direction, as the top face 50A of the first power conductor 51A, and the top face 50A of the second power conductor 54A has the same length in the y-direction as the top face 50A of the first power conductor 51A. Accordingly, the top face 50A of the second power conductor 54A has the same area as the top face 50A of the first power conductor 51A. Here, when the difference in area between the top face 50A of the second power conductor 54A and the top face 50A of the first power conductor 51A is, for example, within 5% of the area of the top face 50A of the first power conductor 51A, the area of the top face 50A of the second power conductor 54A may be regarded as being equal to that of the top face 50A of the first power conductor 51A. Accordingly, the top face 50A of the second power conductor 54A is smaller in area than the top face 50A of the first output conductor 52A, the top face 50A of the first output conductor 52B, and the top face 50A of the first ground conductor 53. Since the second power conductor 54A is a rectangular parallelepiped, the length in the x-direction or y-direction, of the portion of the second power conductor 54A closer to the substrate 10 than is the top face 50A, is equal to that of the top face 50A of the second power conductor 54A.

Though not shown, the second power conductor 54A has the same thickness as the first power conductor 51A. Accordingly, the second power conductor 54A has the same volume as the first power conductor 51A. Here, when the difference in volume between the second power conductor 54A and the first power conductor 51A is, for example, within 5% of the volume of the first power conductor 51A, the volume of the second power conductor 54A may be regarded as being equal to that of the first power conductor 51A. Accordingly, the second power conductor 54A is smaller in volume than the first output conductor 52A, the first output conductor 528, and the first ground conductor 53.

As shown in FIG. 7, the second power conductor 54B is located on the wide wiring section 44a of the second power wiring 44B. In this embodiment, the second power conductor 54B is located on the end portion of the wide wiring section 44a of the second power wiring 44B on the side of the substrate side face 14 in the x-direction. To be more detailed, as viewed in the z-direction, one of the edges of the second power conductor 54B in the x-direction on the side of the substrate side face 14, is aligned with the edge of the wide wiring section 44a of the second power wiring 44B on the side of the substrate side face 14, in the x-direction.

The top face 50A of the second power conductor 54B is shorter in the y-direction, than the width of the wide wiring section 44a of the second power wiring 44B. The width of the wide wiring section 44a of the second power wiring 44B refers to the size of the portion thereof extending in the direction orthogonal to the direction in which the wide wiring section 44a of the second power wiring 44B extends, as viewed in the z-direction. In this embodiment, the width of the wide wiring section 44a of the second power wiring 44B corresponds to the length thereof in the y-direction. The second power conductor 54B is located close to one of the edges of the wide wiring section 44a of the second power wiring 44B in the y-direction on the side of the substrate side face 15 (second output wiring 45B). Accordingly, the distance between the second power conductor 54B and one of the edges of the wide wiring section 44a of the second power wiring 44B in the y-direction on the side of the substrate side face 15 (second output wiring 45B), is shorter than the distance between the second power conductor 54B and another edge of the wide wiring section 44a of the second power wiring 44B in the y-direction on the side of the substrate side face 16. In this embodiment, as viewed in the z-direction, one of the edges of the second power conductor 54B in the y-direction on the side of the substrate side face 15 (second output wiring 45B) is aligned with the edge of the wide wiring section 44a of the second power wiring 44B in the y-direction on the side of the substrate side face 15 (second output wiring 45B).

The second power conductor 54B is shorter than the wide wiring section 44a of the second power wiring 44B, in the x-direction. In this embodiment, the length of the second power conductor 54B in the x-direction is equal to or shorter than ½ of that of the wide wiring section 44a of the second power wiring 44B.

As shown in FIG. 5, the top face 50A of the second power conductor 54B has the same length in the x-direction, as the top face 50A of the second power conductor 54A, and the top face 50A of the second power conductor 54B has the same length in the y-direction as the top face 50A of the second power conductor 54A. Accordingly, the top face 50A of the second power conductor 54B has the same area as the top face 50A of the second power conductor 54A. Here, when the difference in area between the top face 50A of the second power conductor 54B and the top face 50A of the second power conductor 54A is, for example, within 5% of the area of the top face 50A of the second power conductor 54A, the area of the top face 50A of the second power conductor 54B may be regarded as being equal to that of the top face 50A of the second power conductor 54A. Since the top face 50A of the second power conductor 54A has the same area as the top face 50A of the first power conductor 51A, the top face 50A of the second power conductor 54A is smaller in area than the top face 50A of the first output conductor 52A, the top face 50A of the first output conductor 52B, and the top face 50A of the first ground conductor 53. Here, since the second power conductor 54B is a rectangular parallelepiped, the length in the x-direction or y-direction, of the portion of the second power conductor 54B closer to the substrate 10 than is the top face 50A, is equal to that of the top face 50A of the second power conductor 54B.

Though not shown, the second power conductor 54B has the same thickness as the second power conductor 54A. Accordingly, the second power conductor 54B has the same volume as the second power conductor 54A. Here, when the difference in volume between the second power conductor 54B and the second power conductor 54A is, for example, within 5% of the volume of the second power conductor 54A, the volume of the second power conductor 54B may be regarded as being equal to that of the second power conductor 54A. Since the second power conductor 54A has the same volume as the first power conductor 51A, the second power conductor 54B is smaller in volume than the first output conductor 52A, the first output conductor 52B, and the first ground conductor 53.

The second output conductor 55A is located on the wide wiring section 45a of the second output wiring 45A. In this embodiment, the second output conductor 55A is located on the end portion of the wide wiring section 45a of the second output wiring 45A on the side of the substrate side face 14 in the x-direction. To be more detailed, as viewed in the z-direction, one of the edges of the second output conductor 55A in the x-direction on the side of the substrate side face 14, is aligned with the edge of the wide wiring section 45a of the second output wiring 45A on the side of the substrate side face 14, in the x-direction.

The top face 50A of the second output conductor 55A is shorter in the y-direction, than the width of the wide wiring section 45a of the second output wiring 45A. The length of the top face 50A of the second output conductor 55A in the y-direction is between ½ and ⅔, both ends inclusive, of the width of the wide wiring section 45a of the second output wiring 45A. The width of the wide wiring section 45a of the second output wiring 45A refers to the size of the portion thereof extending in the direction orthogonal to the direction in which the wide wiring section 45a of the second output wiring 45A extends, as viewed in the z-direction. In this embodiment, the width of the wide wiring section 45a of the second output wiring 45A corresponds to the length thereof in the y-direction. The second output conductor 55A is located closer to one of the edges of the wide wiring section 45a of the second output wiring 45A in the y-direction, on the side of the substrate side face 16. Accordingly, the distance between the second output conductor 55A and the edge of the wide wiring section 45a of the second output wiring 45A in the y-direction, on the side of the substrate side face 16, is shorter than the distance between the second output conductor 55A and the other edge of the wide wiring section 45a of the second output wiring 45A in the y-direction, on the side of the substrate side face 15.

The second output conductor 55A is shorter in the x-direction, than the wide wiring section 45a of the second output wiring 45A. The second output conductor 55A is located closer to the substrate side face 14 in the x-direction, than is the sloped section 45c of the second output wiring 45A.

The top face 50A of the second output conductor 55A is longer in the x-direction, than the top face 50A of the second power conductor 54A. In other words, the top face 50A of the second power conductor 54A is shorter in the x-direction, than the top face 50A of the second output conductor 55A. The length of the top face 50A of the second power conductor 54A in the x-direction is between ½ and ⅔, both ends inclusive, of the top face 50A of the second output conductor 55A. The top face 50A of the second output conductor 55A has the same length in the y-direction, as the top face 50A of the second power conductor 54A. Accordingly, the top face 50A of the second power conductor 54A is smaller in area than the top face 50A of the second output conductor 55A. Since the area of the top face 50A of the second power conductor 54A is equal to that of the top face 50A of the second power conductor 54B, the top face 50A of the second power conductor 54B is smaller in area than the top face 50A of the second output conductor 55A. In other words, the top face 50A of the second output conductor 55A is larger in area than the top face 50A of the second power conductor 54A, and also than the top face 50A of the second power conductor 54B. Here, since the second output conductor 55A is a rectangular parallelepiped, the length in the x-direction or y-direction, of the portion of the second output conductor 55A closer to the substrate 10 than is the top face 50A, is equal to that of the top face 50A of the second output conductor 55A.

Though not shown, the second output conductor 55A has the same thickness as the second power conductor 54A. Accordingly, the second output conductor 55A is larger in volume than the second power conductor 54A. In other words, the second power conductor 54A is smaller in volume than the second output conductor 55A. Here, when the difference in volume between the second output conductor 55A and the second power conductor 54A is, for example, within 5% of the volume of the second power conductor 54A, the volume of the second output conductor 55A may be regarded as being equal to that of the second power conductor 54A. Since the second power conductor 54A has the same volume as the second power conductor 54B, the volume of the second power conductor 54B may be regarded as being smaller than that of the second output conductor 55A.

As shown in FIG. 5, the top face 50A of the second output conductor 55A has the same length in the x-direction, as the top face 50A of the first output conductor 52A, and the top face 50A of the second output conductor 55A has the same length in the y-direction as the top face 50A of the first output conductor 52A. Accordingly, the top face 50A of the second output conductor 55A has the same area as the top face 50A of the first output conductor 52A. Here, when the difference in area between the top face 50A of the second output conductor 55A and the top face 50A of the first output conductor 52A is, for example, within 5% of the area of the top face 50A of the first output conductor 52A, the area of the top face 50A of the second output conductor 55A may be regarded as being equal to that of the top face 50A of the first output conductor 52A. Accordingly, the top face 50A of the second output conductor 55A is larger in area than the top face 50A of the first power conductor 51A, and the top face 50A of the first power conductor 51B. In other words, the top face 50A of the first power conductor 51A and the top face 50A of the first power conductor 51B are each smaller in area than the top face 50A of the second output conductor 55A.

Though not shown, the second output conductor 55A has the same thickness as the first output conductor 52A. Accordingly, the second output conductor 55A has the same volume as the first output conductor 52A. Here, when the difference in volume between the second output conductor 55A and the first output conductor 52A is, for example, within 5% of the volume of the first output conductor 52A, the volume of the second output conductor 55A may be regarded as being equal to that of the first output conductor 52A. Since the second output conductor 55A has the same volume as the first output conductor 52A, the second output conductor 55A is larger in volume than the first power conductor 51A and the first power conductor 51B. In other words, the first power conductor 51A and the first power conductor 51B are each smaller in volume than the second output conductor 55A.

The second output conductor 55B is located on the wide wiring section 45a of the second output wiring 45B. In this embodiment, the second output conductor 55B is located on the end portion of the wide wiring section 45a of the second output wiring 45B on the side of the substrate side face 14 in the x-direction. To be more detailed, as viewed in the z-direction, one of the edges of the second output conductor 55B in the x-direction on the side of the substrate side face 14, is aligned with the edge of the wide wiring section 45a of the second output wiring 45B on the side of the substrate side face 14, in the x-direction.

The top face 50A of the second output conductor 55B is shorter in the y-direction, than the width of the wide wiring section 45a of the second output wiring 45B. The length of the top face 50A of the second output conductor 55B in the y-direction is between ½ and ⅔, both ends inclusive, of the width of the wide wiring section 45a of the second output wiring 45B. The width of the wide wiring section 45a of the second output wiring 45B refers to the size of the portion thereof extending in the direction orthogonal to the direction in which the wide wiring section 45a of the second output wiring 45B extends, as viewed in the z-direction. In this embodiment, the width of the wide wiring section 45a of the second output wiring 45B corresponds to the length thereof in the y-direction. The second output conductor 55B is located closer to one of the edges of the wide wiring section 45a of the second output wiring 45B in the y-direction, on the side of the substrate side face 15. Accordingly, the distance between the second output conductor 55B and the edge of the wide wiring section 45a of the second output wiring 45B in the y-direction, on the side of the substrate side face 15, is shorter than the distance between the second output conductor 55B and the other edge of the wide wiring section 45a of the second output wiring 45B in the y-direction, on the side of the substrate side face 16.

The second output conductor 55B is shorter in the x-direction, than the wide wiring section 45a of the second output wiring 45B. The second output conductor 55B is located closer to the substrate side face 14 in the x-direction, than is the sloped section 45c of the second output wiring 45B.

The top face 50A of the second output conductor 55B has the same length in the x-direction, as the top face 50A of the second output conductor 55A, and the top face 50A of the second output conductor 55B has the same length in the y-direction as the top face 50A of the second output conductor 55A. Accordingly, the top face 50A of the second output conductor 55B has the same area as the top face 50A of the second output conductor 55A. Here, when the difference in area between the top face 50A of the second output conductor 55B and the top face 50A of the second output conductor 55A is, for example, within 5% of the area of the top face 50A of the second output conductor 55A, the area of the top face 50A of the second output conductor 55B may be regarded as being equal to that of the top face 50A of the second output conductor 55A. Since the top face 50A of the second output conductor 55B has the same area as the top face 50A of the second output conductor 55A, the top face 50A of the second output conductor 55B is larger in area than the top face 50A of the second power conductor 54A, and the top face 50A of the second power conductor 54B. In other words, the top face 50A of the second power conductor 54A and the top face 50A of the second power conductor 54B are each smaller in area than the top face 50A of the second output conductor 55B. Here, since the second output conductor 55B is a rectangular parallelepiped, the length in the x-direction or y-direction, of the portion of the second output conductor 55B closer to the substrate 10 than is the top face 50A, is equal to that of the top face 50A of the second output conductor 55B.

Though not shown, the second output conductor 55B has the same thickness as the second output conductor 55A. Accordingly, the second output conductor 55B has the same volume as the second output conductor 55A. Here, when the difference in volume between the second output conductor 553 and the second output conductor 55A is, for example, within 5% of the volume of the second output conductor 55A, the volume of the second output conductor 55B may be regarded as being equal to that of the second output conductor 55A. Since the second output conductor 55B has the same volume as the second output conductor 55A, the second output conductor 55B is larger in volume than the second power conductor 54A and the second power conductor 54B. In other words, the second power conductor 54A and the second power conductor 54B are each smaller in volume than the second output conductor 55B.

As shown in FIG. 5, the top face 50A of the second output conductor 55B has the same length in the x-direction, as the top face 50A of the first output conductor 52B, and the top face 50A of the second output conductor 55B has the same length in the y-direction as the top face 50A of the first output conductor 52B. Accordingly, the top face 50A of the second output conductor 55B has the same area as the top face 50A of the first output conductor 529. Here, when the difference in area between the top face 50A of the second output conductor 55B and the top face 50A of the first output conductor 52B is, for example, within 5% of the area of the top face 50A of the first output conductor 52B, the area of the top face 50A of the second output conductor 559 may be regarded as being equal to that of the top face 50A of the first output conductor 52B. Accordingly, the top face 50A of the second output conductor 559 is larger in area than the top face 50A of the first power conductor 51A, and the top face 50A of the first power conductor 51B. In other words, the top face 50A of the first power conductor 51A and the top face 50A of the first power conductor 51B are each smaller in area than the top face 50A of the second output conductor 55B.

Though not shown, the second output conductor 55B has the same thickness as the first output conductor 528. Accordingly, the second output conductor 55B has the same volume as the first output conductor 52B. Here, when the difference in volume between the second output conductor 55B and the first output conductor 52B is, for example, within 5% of the volume of the first output conductor 52B, the volume of the second output conductor 55B may be regarded as being equal to that of the first output conductor 52B. Accordingly, the second output conductor 55B is larger in volume than the first power conductor 51A and the first power conductor 51B. In other words, the first power conductor 51A and the first power conductor 51B are each smaller in volume than the second output conductor 55B.

As shown in FIG. 7, the second ground conductor 56 is located on one of the edges of the second ground wiring 46 in the x-direction, on the side of the substrate side face 14. To be more detailed, as viewed in the z-direction, one of the edges of the second ground conductor 56 in the x-direction on the side of the substrate side face 14 is aligned with the edge of the second ground wiring 46 on the side of the substrate side face 14, in the x-direction.

The top face 50A of the second ground conductor 56 is shorter in the y-direction, than the width of the second ground wiring 46. The length of the top face 50A of the second ground conductor 56 in the y-direction is between ½ and ⅔, both ends inclusive, of the width of the second ground wiring 46. The width of the second ground wiring 46 refers to the size of the portion thereof extending in the direction orthogonal to the direction in which the second ground wiring 46 extends, as viewed in the z-direction. In this embodiment, the width of the second ground wiring 46 corresponds to the length thereof in the y-direction. The second ground conductor 56 is located on the central portion of the second ground wiring 46, in the y-direction.

The top face 50A of the second ground conductor 56 has the same length in the x-direction, as the top face 50A of the second output conductor 55A. The top face 50A of the second ground conductor 56 has the same length in the y-direction as the top face 50A of the second output conductor 55A. Accordingly, the top face 50A of the second ground conductor 56 has the same area as the top face 50A of the second output conductor 55A. Here, when the difference in area between the top face 50A of the second ground conductor 56 and the top face 50A of the second output conductor 55A is, for example, within 5% of the area of the top face 50A of the second output conductor 55A, the area of the top face 50A of the second ground conductor 56 may be regarded as being equal to that of the top face 50A of the second output conductor 55A. Since the top face 50A of the second ground conductor 56 has the same area as the top face 50A of the second output conductor 55A as above, the top face 50A of the second ground conductor 56 is larger in area than the top face 50A of the second power conductor 54A, and the top face 50A of the second power conductor 54B. In other words, the top face 50A of the second power conductor 54A and the top face 50A of the second power conductor 54B are each smaller in area than the top face 50A of the second ground conductor 56. Here, since the second ground conductor 56 is a rectangular parallelepiped, the length in the x-direction or y-direction, of the portion of the second ground conductor 56 closer to the substrate 10 than is the top face 50A, is equal to that of the top face 50A of the second ground conductor 56.

Though not shown, the second ground conductor 56 has the same thickness as the second output conductor 55A. Accordingly, the second ground conductor 56 has the same volume as the second output conductor 55A. Here, when the difference in volume between the second ground conductor 56 and the second output conductor 55A is, for example, within 5% of the volume of the second output conductor 55A, the volume of the second ground conductor 56 may be regarded as being equal to that of the second output conductor 55A. Since the second ground conductor 56 has the same volume as the second output conductor 55A as above, the second ground conductor 56 is larger in volume than the second power conductor 54A and the second power conductor 54B. In other words, the second power conductor 54A and the second power conductor 54B are each smaller in volume than the second ground conductor 56.

As shown in FIG. 5, the top face 50A of the second ground conductor 56 has the same length in the x-direction, as the top face 50A of the first ground conductor 53, and the top face 50A of the second ground conductor 56 has the same length in the y-direction as the top face 50A of the first ground conductor 53. Accordingly, the top face 50A of the second ground conductor 56 has the same area as the top face 50A of the first ground conductor 53. Here, when the difference in area between the top face 50A of the second ground conductor 56 and the top face 50A of the first ground conductor 53 is, for example, within 5% of the area of the top face 50A of the first ground conductor 53, the area of the top face 50A of the second ground conductor 56 may be regarded as being equal to that of the top face 50A of the first ground conductor 53. Accordingly, the top face 50A of the second ground conductor 56 is larger in area than the top face 50A of the first power conductor 51A, and the top face 50A of the first power conductor 51B. In other words, the top face 50A of the first power conductor 51A and the top face 50A of the first power conductor 51B are each smaller in area than the top face 50A of the second ground conductor 56.

Though not shown, the second ground conductor 56 has the same thickness as the first ground conductor 53. Accordingly, the second ground conductor 56 has the same volume as the first ground conductor 53. Here, when the difference in volume between the second ground conductor 56 and the first ground conductor 53 is, for example, within 5% of the volume of the first ground conductor 53, the volume of the second ground conductor 56 may be regarded as being equal to that of the first ground conductor 53. Accordingly, the second ground conductor 56 is larger in volume than the first power conductor 51A and the first power conductor 51B. In other words, the first power conductor 51A and the first power conductor 51B are each smaller in volume than the second ground conductor 56.

As shown in FIG. 5, the plurality of control conductors 57 include a plurality of (in this embodiment, nine) control conductors 57A respectively located on the wiring end section 47a of the plurality of control wirings 47A, and a plurality of (in this embodiment, nine) control conductors 573 respectively located on the wiring end section 47a of the plurality of control wirings 47B. However, the number of pieces of the control conductors 57A and 57B may be changed as desired. In an example, the number of pieces of the control conductors 57A and that of the control conductors 57B may be different from each other.

The plurality of control conductors 57A include two distal control conductors 57C, a central control conductor 57D, and six intermediate control conductors 57E. The distal control conductors 57C, the central control conductor 57D, and the intermediate control conductors 57E are each formed in a rectangular parallelepiped shape. As viewed in the z-direction, the top face 50A of the distal control conductor 57C has a rectangular shape having the sides extending along the x-direction and the sides extending along the y-direction and, in this embodiment, a square shape. As viewed in the z-direction, the top face 50A of the central control conductor 57D has a generally rectangular shape having the sides extending along the x-direction and the sides extending along the y-direction. In this embodiment, the sides along the x-direction correspond to the long sides, and the sides along the y-direction correspond to the short sides. As viewed in the z-direction, the top face 50A of the intermediate control conductor 57E has a rectangular shape having the sides extending along the x-direction and the sides extending along the y-direction and, in this embodiment, a square shape.

Here, the shape viewed in the z-direction of the top face 50A of the distal control conductor 57C, the top face 50A of the central control conductor 57D, and the top face 50A of the intermediate control conductor 57B may be modified as desired. In an example, the shape viewed in the z-direction of the top face 50A of the distal control conductor 57C, the top face 50A of the central control conductor 57D, and the top face 50A of the intermediate control conductor 57E may each be circular, or elliptical.

The two distal control conductors 57C are located at the respective ends of the plurality of control conductors 57A, in the x-direction. The distal control conductor 57C on the side of the substrate side face 13 in the x-direction is aligned with the first power conductor 51A in the x-direction, and spaced therefrom in the y-direction. The top face 50A of the distal control conductor 57C has the same length in the x-direction, as the top face 50A of the first power conductor 51A, and the top face 50A of the distal control conductor 57C is longer in the y-direction, than the top face 50A of the first power conductor 51A. Accordingly, the top face 50A of the distal control conductor 57C is larger in area than the top face 50A of the first power conductor 51A. In other words, the top face 50A of the first power conductor 51A is smaller in area than the top face 50A of the distal control conductor 57C. In addition, the top face 50A of the distal control conductor 57C is smaller in area than the top face 50A of the first output conductor 52A, the top face 50A of the first output conductor 52B, and the top face 50A of the first ground conductor 53. Since each of the distal control conductors 57C is a rectangular parallelepiped, the length in the x-direction or y-direction, of the portion of the distal control conductor 57C closer to the substrate 10 than is the top face 50A, is equal to that of the top face 50A of the distal control conductor 57C.

Though not shown, the distal control conductor 57C has the same thickness as the first power conductor 51A. Accordingly, the distal control conductor 57C is larger in volume than the first power conductor 51A. In other words, the first power conductor 51A is smaller in volume than the distal control conductor 57C. In addition, the distal control conductor 57C located close to the substrate side face 13 in the x-direction is smaller in volume than the first output conductor 52A, the first output conductor 52B, and the first ground conductor 53.

The distal control conductor 57C on the side of the substrate side face 14 in the x-direction is aligned with the second power conductor 54A in the x-direction, and spaced therefrom in the y-direction. The top face 50A of the distal control conductor 57C has the same length in the x-direction, as the top face 50A of the second power conductor 54A, and the top face 50A of the distal control conductor 57C is longer in the y-direction, than the top face 50A of the second power conductor 54A. Accordingly, the top face 50A of the distal control conductor 57C is larger in area than the top face 50A of the second power conductor 54A. In addition, the top face 50A of the distal control conductor 57C is smaller in area than the top face 50A of the second output conductor 55A, the top face 50A of the second output conductor 55B, and the top face 50A of the second ground conductor 56.

Though not shown, the distal control conductor 57C has the same thickness as the second power conductor 54A. Accordingly, the distal control conductor 57C is larger in volume than the first power conductor 51B. In other words, first power conductor 51B is smaller in volume than the distal control conductor 57C. In addition, the distal control conductor 57C located close to the substrate side face 14 in the x-direction is smaller in volume than the second output conductor 55A, the second output conductor 55B, and the second ground conductor 56.

The central control conductor 57D is located between the power conductors 51A and 51B, the output conductors 52A and 52B and the first ground conductor 53, and the power conductors 54A and 54B, the output conductors 55A and 55B and the second ground conductor 56, in the x-direction. The central control conductor 57D includes a cutaway portion 57x for indicating the orientation of the semiconductor device 1A. The top face 50A of the central control conductor 57D is longer in the x-direction, than the top face 50A of the first power conductor 51A, and the top face 50A of the central control conductor 57D has the same length in the y-direction, as the top face 50A of the first power conductor 51A. Accordingly, the top face 50A of the central control conductor 57D is larger in area than the top face 50A of the first power conductor 51A. In other words, the top face 50A of the first power conductor 51A is smaller in area than the top face 50A of the central control conductor 57D. In addition, the top face 50A of the central control conductor 57D is smaller in area than the top face 50A of the first output conductor 52A, the top face 50A of the first output conductor 52B, and the top face 50A of the first ground conductor 53. Since the central control conductor 57D is a rectangular parallelepiped, the length in the x-direction or y-direction, of the portion of the central control conductor 57D closer to the substrate 10 than is the top face 50A, is equal to that of the top face 50A of the central control conductor 57D.

Though not shown, the central control conductor 57D has the same thickness as the first power conductor 51A. Accordingly, the central control conductor 57D is larger in volume than the first power conductor 51A. In other words, the first power conductor 51A is smaller in volume than the central control conductor 57D. In addition, the central control conductor 57D is smaller in volume than the first output conductor 52A, the first output conductor 52B, and the first ground conductor 53.

Three out of the six intermediate control conductors 57B are located between the distal control conductor 57C on the side of the substrate side face 13 and the central control conductor 57D in the x-direction, in alignment with one another in the y-direction and with a spacing between each other in the x-direction.

The remaining three intermediate control conductors 57E are located between the distal control conductor 57C on the side of the substrate side face 14 and the central control conductor 57D in the x-direction, in alignment with one another in the y-direction and with a spacing between each other in the x-direction.

The top face 50A of each of the intermediate control conductors 57B is shorter in the x-direction, than the top face 50A of the first power conductor 51A, and the top face 50A of each of the intermediate control conductors 57E has the same length in the y-direction, as the top face 50A of the first power conductor 51A. Accordingly, the top face 50A of each of the intermediate control conductors 57B is smaller in area than the top face 50A of the first power conductor 51A. In other words, the top face 50A of the first power conductor 51A is larger in area than the top face 50A of each of the intermediate control conductors 579. Since the intermediate control conductor 57E is a rectangular parallelepiped, the length in the x-direction or y-direction, of the portion of the intermediate control conductor 57E closer to the substrate 10 than is the top face 50A, is equal to that of the top face 50A of the intermediate control conductor 57E.

Though not shown, the intermediate control conductors 57B each have the same thickness as the first power conductor 51A. Accordingly, each of the intermediate control conductors 57E is smaller in volume than the first power conductor 51A. In other words, the first power conductor 51A is greater in volume than each intermediate control conductor 57E.

The plurality of control conductors 57B include two distal control conductors 57C and seven intermediate control conductors 57E. The distal control conductors 57C and the intermediate control conductor 579 each have a rectangular parallelepiped shape. The two distal control conductors 57C are located at the respective end portions of the plurality of control conductors 57A in the x-direction. The seven intermediate control conductors 57E are located between the two distal control conductors 57C, in the x-direction. The seven intermediate control conductors 57E are aligned with each other in the y-direction, and spaced apart from each other in the x-direction.

The top face 50A of the distal control conductor 57C in the control conductors 57B has the same area as the top face 50A of the distal control conductor 57C in the control conductors 57A. Accordingly, the top face 50A of the distal control conductor 57C in the control conductors 57B, located close to the substrate side face 13, is larger in area than the top face 50A of the first power conductor 51B. Likewise, the top face 50A of the distal control conductor 57C in the control conductors 57B, located close to the substrate side face 14, is larger in area than the top face 50A of the second power conductor 54B. In addition, the top face 50A of the distal control conductor 57C close to the substrate side face 13 is smaller in area than the top face 50A of the first output conductor 52A, the top face 50A of the first output conductor 52B, and the top face 50A of the first ground conductor 53. Likewise, the top face 50A of the distal control conductor 57C close to the substrate side face 14 is smaller in area than the top face 50A of the second output conductor 55A, the top face 50A of the second output conductor 55B, and the top face 50A of the second ground conductor 56.

Though not shown, the distal control conductors 57C each have the same thickness as the first power conductor 51B and the second power conductor 54B. Accordingly, the distal control conductors 57C are each larger in volume than the first power conductor 51B and the second power conductor 54B. In other words, the first power conductor 51B and the second power conductor 54B are each smaller in volume, than each of the distal control conductors 57C. In addition, the distal control conductor 57C close to the substrate side face 13 is smaller in volume than the first output conductor 52A, the first output conductor 52B, and the first ground conductor 53. Likewise, the distal control conductor 57C close to the substrate side face 14 is smaller in volume than the second output conductor 55A, the second output conductor 55B, and the second ground conductor 56.

The top face 50A of each of the intermediate control conductors 57E in the control conductors 57B has the same area as the top face 50A of the intermediate control conductors 579 in the control conductors 57A. Accordingly, the top face 50A of each of the intermediate control conductors 57B in the control conductors 579 is smaller in area than the top face 50A of the first power conductor 51A.

Though not shown, the intermediate control conductors 57B in the control conductors 57B each have the same thickness as the intermediate control conductors 57E in the control conductors 57A. Accordingly, each of the intermediate control conductors 57E in the control conductors 57B has the same volume as the intermediate control conductors 57B in the control conductors 57A. Therefore, each of the intermediate control conductors 57E in the control conductors 57B is smaller in volume than the first power conductor 51A.

As shown in FIG. 3, the plurality of terminals 20 include first power terminals 21A and 21B, first output terminals 22A and 22B, a first ground terminal 23, second power terminals 24A and 24B, second output terminals 25A and 25B, a second ground terminal 26, and a plurality of control terminals 27. In this embodiment, the first power terminals 21A and 21B and the second power terminals 24A and 24B correspond to the first drive terminal, and the first output terminals 22A and 22B, the first ground terminal 23, the second output terminals 25A and 25B, and the second ground terminal 26 correspond to the second drive terminal.

The first power terminal 21A covers the top face 50A of the first power conductor 51A in the plurality of conductors 50. The first power terminal 21B covers the top face 50A of the first power conductor 51B. The first output terminal 22A covers the top face 50A of the first output conductor 52A in the plurality of conductors 50. The first output terminal 22B covers the top face 50A of the first output conductor 52B in the plurality of conductors 50. The first ground terminal 23 covers the top face 50A of the first ground conductor 53 in the plurality of conductors 50. The second ground terminal 26 covers the top face 50A of the second ground conductor 56 in the plurality of conductors 50. The plurality of control terminals 27 respectively covers the top face 50A of the plurality of control conductors 57.

The relation in size viewed in the z-direction, among the first power terminals 21A and 21B, the first output terminals 22A and 22B, the first ground terminal 23, the second power terminals 24A and 24B, the second output terminals 25A and 25B, the second ground terminal 26, and the plurality of control terminal 27 is the same as the relation in size of the top face 50A viewed in the z-direction, among the first power conductors 51A and 51B, the first output conductors 52A and 52B, the first ground conductor 53, the second power conductors 54A and 54B, the second output conductors 55A and 55B, the second ground conductor 56, and the plurality of control conductors 57.

Referring to FIG. 13 to FIG. 25, an exemplary manufacturing method of the semiconductor device 1A will now be described hereunder. Referring to FIG. 13, the manufacturing method of the semiconductor device 1A includes a process of forming an insulation film 817 on a base material 810. To be more detailed, first the base material 810 of a flat plate-shape is prepared. In this embodiment, a silicon wafer is employed as the base material 810. Then the insulation film 817 is formed on one of the surfaces of the base material 810 in the thickness direction. The insulation film 817 can be formed through depositing an oxide layer on the one surface of the base material 810 in the thickness direction by thermal oxidation, and then depositing a nitride layer on the oxide layer by plasma chemical vapor deposition (CVD). The surface of the insulation film 817 formed as above, oriented in the thickness direction, will hereinafter be referred to as base material obverse face 811. The face of the base material 810 oriented in the opposite direction to the base material obverse face 811 in the thickness direction, will hereinafter be referred to as base material reverse face 812.

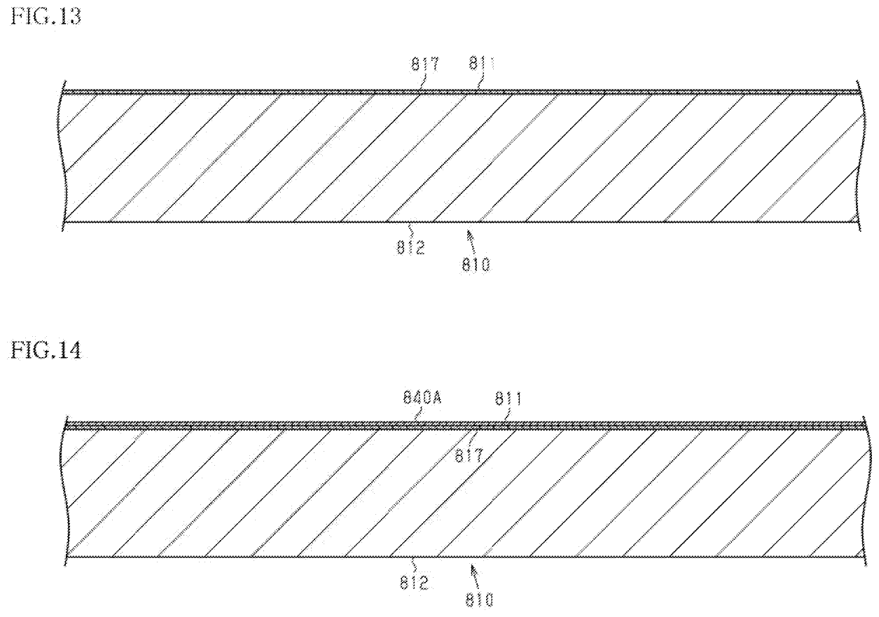

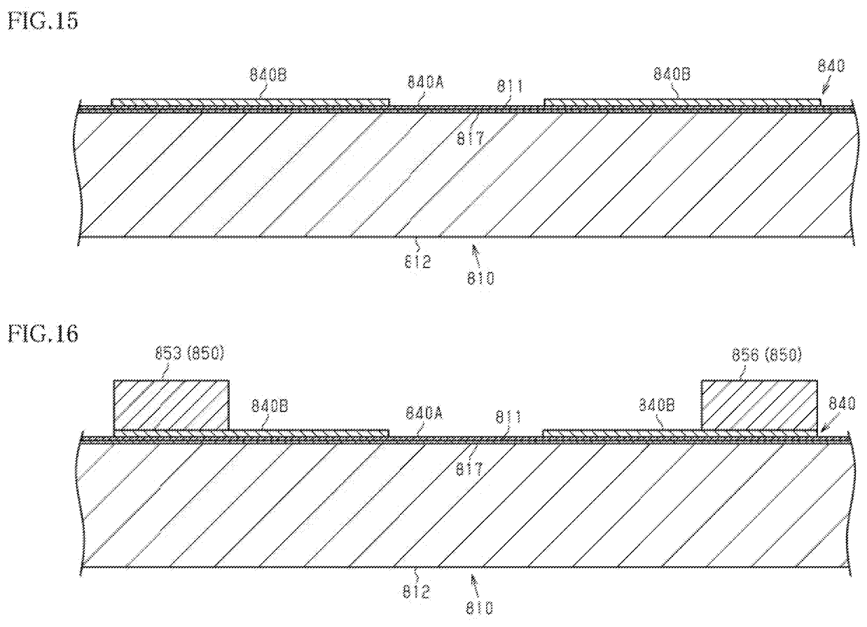

Referring to FIG. 14 and FIG. 15, the manufacturing method of the semiconductor device 1A includes a process of forming a plurality of wirings 840. To be more detailed, first an underlying layer 840A is formed so as to cover the base material obverse face 811, as shown in FIG. 14. The underlying layer 840A can be formed through depositing a barrier layer all over the base material obverse face 811 by a sputtering method, and then depositing a seed layer on the barrier layer, by a sputtering method. The barrier layer is formed of Ti, in a thickness between 100 nm and 300 nm, both ends inclusive. The seed layer is formed of Cu, in a thickness between 200 nm and 600 nm, both ends inclusive. Turning to FIG. 15, a plurality of plated layers 840B are formed on the underlying layer 840A. The plurality of plated layers 840B can be formed through applying a lithographic patterning on the underlying layer 840A, and performing an electrolytic plating process using the underlying layer 840A as the conduction path. The plurality of plated layers 8409 are each formed of Cu, in a thickness between 5 μm and 25 μm, both ends inclusive.

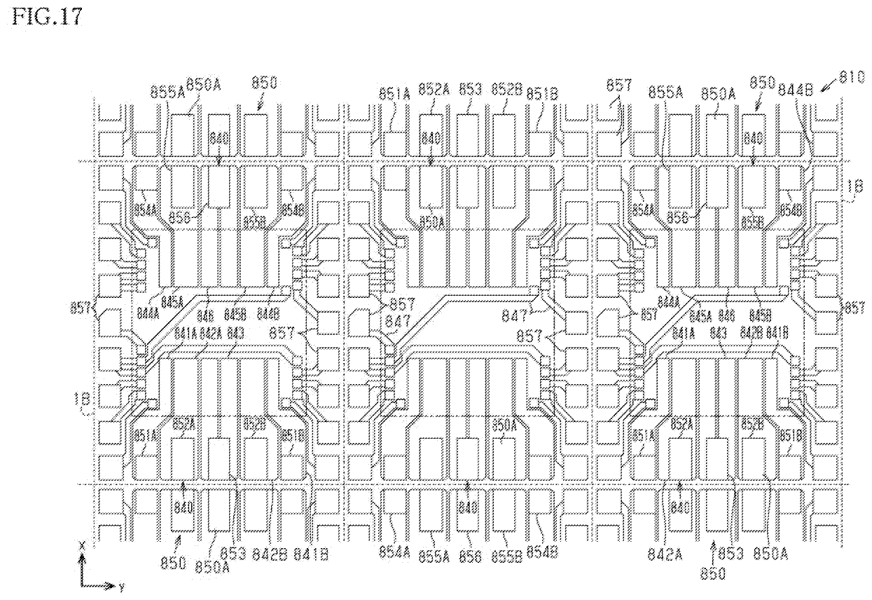

Turning to FIG. 16, the manufacturing method of the semiconductor device 1A includes a process of forming a plurality of conductors 850. To be more detailed, the plurality of conductors 850 are formed on the respective plated layers 840B. The conductors 850 are, for example, formed of Cu. The plurality of conductors 850 can be formed through applying a lithographic patterning on the plurality of plated layers 840B, and performing an electrolytic plating process using the underlying layer 840A and the plated layer 840B as the conduction path.

The plurality of conductors 850 have the same size as each other, in the thickness direction. Further, as shown in FIG. 17, the plurality of conductors 850 each have a rectangular shape having the long sides and short sides, as viewed in the thickness direction. Some of the plurality of conductors 850 are longer in the longitudinal direction, than the remaining conductors 850. Thus, the plurality of conductors 850 are each formed in a rectangular parallelepiped shape.

To be more detailed, as shown in FIG. 17, the plurality of conductors 850 include first power conductors 851A and 851B, first output conductors 852A and 852B, a first ground conductor 853, second power conductors 854A and 854B, second output conductors 855A and 855B, a second ground conductor 856 and a plurality of control conductors 857. The plurality of wirings 840 include first power wirings 841A and 841B, first output wirings 842A and 842B, a first ground wiring 843, second power wirings 844A and 844B, second output wirings 845A and 845B, a second ground wiring 846, and a plurality of control wirings 847. The first power conductor 851A is connected to the first power wiring 841A, and the first power conductor 851B is connected to the first power wiring 841B. The first output conductor 852A is connected to the first output wiring 842A, and the first output conductor 852B is connected to the first output wiring 842B. The first ground conductor 853 is connected to the first ground wiring 843. The second power conductor 854A is connected to the second power wiring 844A, and the second power conductor 854B is connected to the second power wiring 844B. The second output conductor 855A is connected to the second output wiring 845A, and the second output conductor 855B is connected to the second output wiring 845B. The second ground conductor 856 is connected to the second ground wiring 846. The plurality of control conductors 857 are respectively connected to the plurality of control wirings 847. Accordingly, the arrangement pattern of the first power conductors 851A and 851B, the first output conductors 852A and 852B, and the first ground conductor 853 is the same as that of the first power conductors 51A and 51B, the first output conductors 52A and 52B, and the first ground conductor 53 shown in FIG. 3. The arrangement pattern of the second power conductors 854A and 854B, the second output conductors 855A and 855B, and the second ground conductor 856 is the same as that of the second power conductors 54A and 54B, the second output conductors 55A and 55B, and the second ground conductor 56 shown in FIG. 3.

As shown in FIG. 17, the first power conductors 851A and 851B, the first output conductors 852A and 852B, the first ground conductor 853, the second power conductors 854A and 854B, the second output conductors 855A and 855B, and the second ground conductor 856 each have a rectangular shape having the long sides extending in the x-direction and the short sides extending in the y-direction, as viewed in the z-direction.

The respective top faces 850A of the first power conductors 851A and 851B are shorter in the x-direction, than the respective top faces 850A of the first output conductors 852A and 852B and the first ground conductor 853. The respective top faces 850A of the first power conductors 851A and 851B have the same length in the x-direction, as the respective top faces 850A of the first output conductors 852A and 852B and the first ground conductor 853. Though not shown, the plurality of conductors 850 all have the same thickness as one another. Accordingly, the first power conductors 851A and 851B are each smaller in volume than the first output conductors 852A and 852B and the first ground conductor 853.

The respective top faces 850A of the second power conductors 854A and 854B are shorter in the x-direction, than the respective top faces 850A of the second output conductors 855A and 855B and the second ground conductor 856. The respective top faces 850A of the second power conductors 854A and 854B have the same length in the x-direction, as the respective top faces 850A of the second output conductors 855A and 855B and the second ground conductor 856. Since the plurality of conductors 850 have the same thickness as one another as mentioned above, the second power conductors 854A and 854B are each smaller in volume than the second output conductors 855A and 855B and the second ground conductor 856.

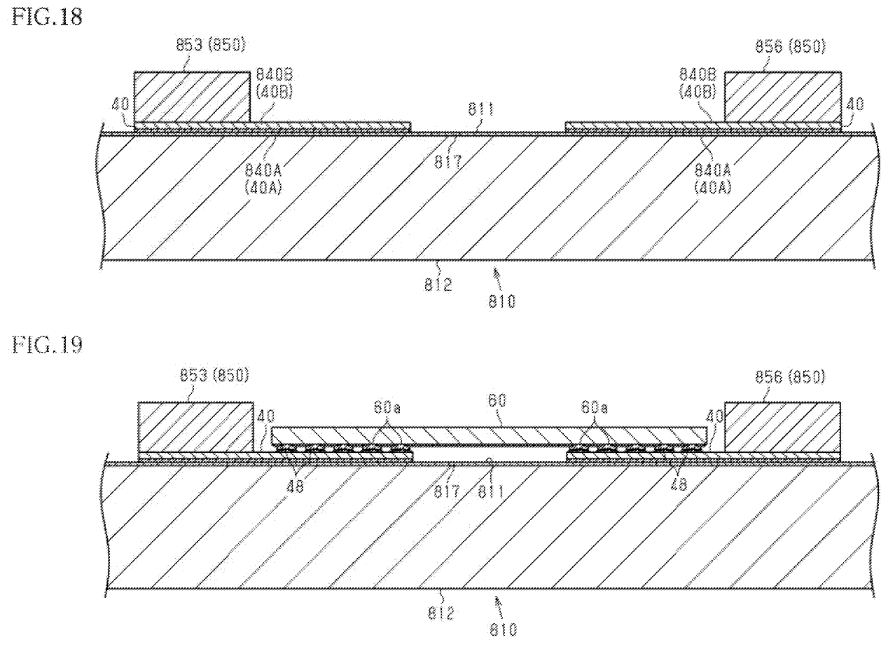

Referring to FIG. 18, the manufacturing method of the semiconductor device 1A includes a process of removing a part of the underlying layer 840A. To be more detailed, the portion of the underlying layer 840A uncovered with the plated layer 840B is removed. The portion of the underlying layer 840A uncovered with the plated layer 840B can be removed by a wet etching method using mixed solution of sulfuric acid (H₂SO₄) and hydrogen peroxide (H₂O₂). As result, the residual portion of the underlying layer 840A and the plurality of plated layers 840B stacked on the underlying layer 840A constitute the plurality of wirings 40 of the semiconductor device 1A.

Referring to FIG. 19, the manufacturing method of the semiconductor device 1A includes a process of mounting the semiconductor element 60. To be more detailed, the semiconductor element 60 is bonded onto the plurality of wirings 40, via the solder layer 48. In this embodiment, the semiconductor element 60 is flip-chip bonded onto the plurality of wirings 40. More specifically, first the solder layer 48 (see FIG. 12) is applied to each of the element electrodes 60a of the semiconductor element 60. Then the plurality of element electrodes 60a of the semiconductor element 60 are tentatively attached to the respective wirings 40 via the solder layer 48, using a collet (not shown), and the plurality of solder layers 48 are molten through a reflow process. Finally, the plurality of solder layers 48 are solidified by cooling, so that the semiconductor element 60 is fixed to the plurality of wirings 40.

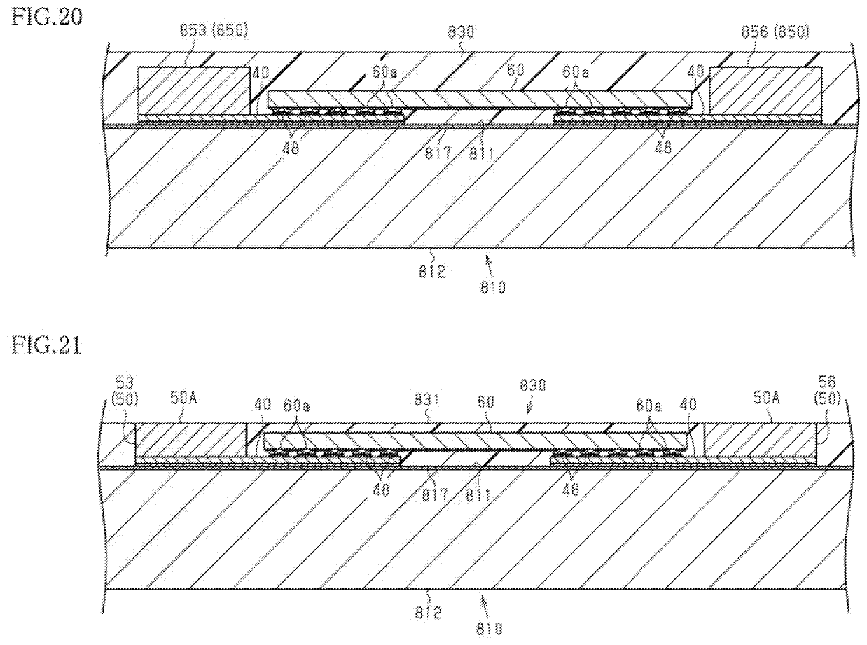

Referring to FIG. 20, the manufacturing method of the semiconductor device 1A includes a process of forming a resin layer 830. To be more detailed, the resin layer 830 is formed in contact with the base material obverse face 811, and so as to cover the plurality of wirings 40, the semiconductor element 60, and the plurality of conductors 850. For example, a thermosetting resin is employed as the resin layer 830. In this embodiment, a black epoxy resin is employed. The resin layer 830 is formed through a compression molding process.

Referring to FIG. 21, the manufacturing method of the semiconductor device 1A includes a process of removing the resin layer 830 in the thickness direction. To be more detailed, the portion of the resin layer 830 located on the opposite side of the substrate obverse face 11 in the thickness direction is removed by mechanical grinding. By the mechanical grinding, the portion of the plurality of conductors 850 located on the opposite side of the base material obverse face 811 in the thickness direction is also removed at the same time. As result, the thickness of the resin layer 830 is reduced, and the plurality of conductors 50 are formed.

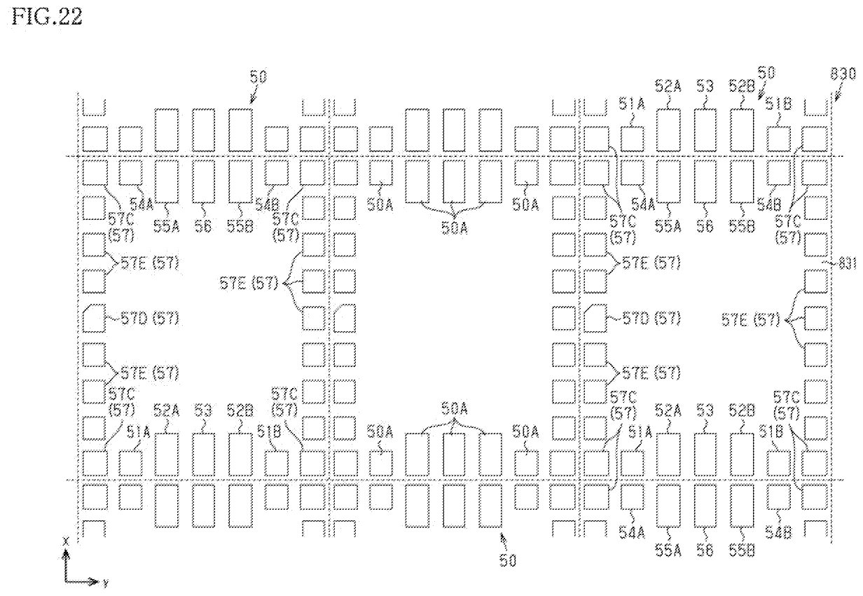

As shown in FIG. 22, the plurality of conductors 50 are exposed from a mounting surface 831 of the resin layer 830. In other words, the respective top faces 50A of the plurality of first power conductors 51A and 51B, the plurality of first output conductors 52A and 52B, the plurality of first ground conductors 53, the plurality of second power conductors 54A and 54B, the plurality of second output conductors 55A and 55B, the plurality of second ground conductors 56, and the plurality of control conductors 57 are exposed from the mounting surface 831. Here, the mounting surface 831 is formed when the resin layer 830 is removed by the mechanical grinding, and oriented to the same side as the base material obverse face 811 (see FIG. 21).

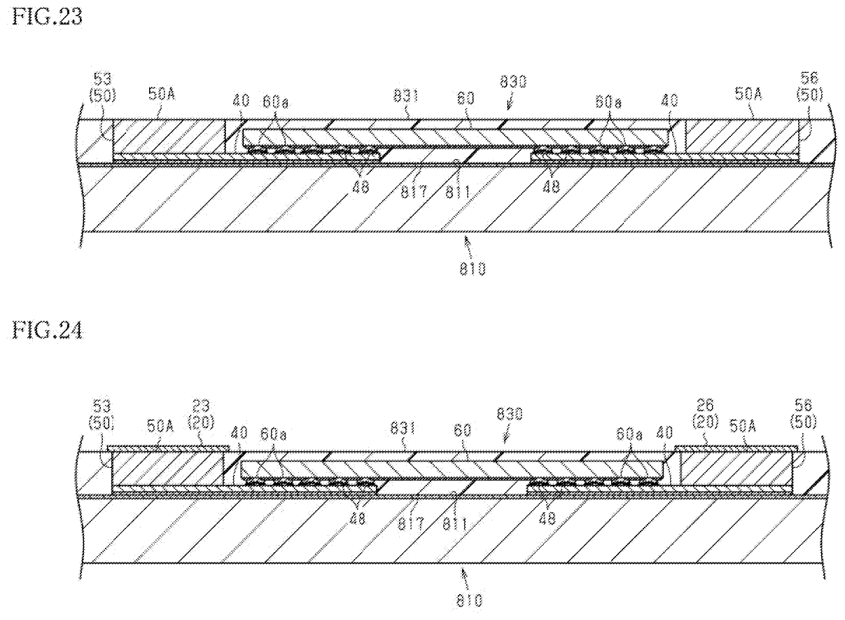

Referring to FIG. 23, the manufacturing method of the semiconductor device 1A includes a process of removing the base material 810 in the thickness direction. To be more detailed, the portion of the base material 810 including the base material reverse face 812 is removed, by the mechanical grinding. As result, the thickness of the base material 810 is reduced.

Referring to FIG. 24, the manufacturing method of the semiconductor device 1A includes a process of forming the plurality of terminals 20. To be more detailed, the plurality of terminals 20 are formed in contact with the respective top faces 50A of the plurality of conductors 50, exposed from the mounting surface 831 of the resin layer 830. The plurality of terminals 20 are each formed through a non-electrolytic plating process.

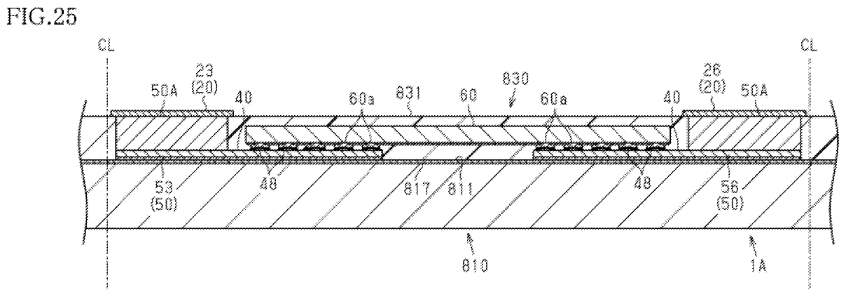

Referring to FIG. 25, the manufacturing method of the semiconductor device 1A includes a process of individuating the semiconductor device 1A. To be more detailed, a dicing blade is used to cut the base material 810 and the resin layer 830 along cutting lines CL, to thereby divide into a plurality of individual pieces. Each of the individual pieces includes one semiconductor element 60, and constitutes the semiconductor device 1A. Through the foregoing process, the semiconductor device 1A can be obtained.

In the manufacturing method of the semiconductor device 1A, the plurality of conductors 850 are each formed of Cu. In the mentioned manufacturing method, the resin layer 830 is formed by molding, after the plurality of conductors 850 are respectively formed on the plurality of wirings 840. The resin layer 830 is formed from a black epoxy resin, through the compression molding process.

During the formation process of the resin layer 830, the assembled body, composed of the base material 810 and the resin layer 830 stacked on each other in the z-direction, may be warped. The warp of the assembled body herein refers to such a deformation that the periphery of the assembled body is elevated in the z-direction with respect to the central portion of the assembled body. Whereas the assembled body is adsorbed to a suction device for transportation in a subsequent process, the assembled body may fail to be properly adsorbed, because of the warp. In addition, the warp of the assembled body may impede the assembled body from being accurately cut by the dicing blade, in the individuation process. Thus, the warp may make it difficult to stably manufacture the semiconductor device 1A.

In the case of the semiconductor device 1A according to this embodiment, the assembled body is warped more largely in the x-direction, in which a first group including the first power conductors 51A and 51B, the first output conductors 52A and 52B, and the first ground conductor 53, and a second group including the second power conductors 54A and 54B, the second output conductors 55A and 55B, and the second ground conductor 56 are aligned, than in the y-direction in which the control conductors 57A and 57B are aligned. On the basis of such a phenomenon, the inventor of the present disclosure has found out that the assembled body is warped more largely, with an increase in total volume of the first power conductors 51A and 51B, the first output conductors 52A and 52B, the first ground conductor 53, the second power conductors 54A and 54B, the second output conductors 55A and 55B, and the second ground conductor 56, for the following reasons.

In the compression molding process, the temperature in the cavity of the tooling increases, during the loading of the epoxy resin to be formed into the resin layer 830, or during the solidification of the epoxy resin. Accordingly, the Cu constituting the plurality of conductors 850 is recrystallized. The Cu is condensed, in other words the plurality of conductors 50 are condensed because of the recrystallization, and therefore a stress is applied to the base material 810 and the resin layer 830, which leads to the warp of the assembled body. Here, although the plurality of wirings 40 are also formed of Cu, the volume thereof is smaller than that of the plurality of conductors 50, and therefore it can be assumed that the impact of the plurality of wirings 40 to the warp of the assembled body is smaller, than the impact of the plurality of conductors 50.

Accordingly, in the plurality of conductors 850, the total volume of the first power conductors 851A and 851B, the first output conductors 852A and 852B, the first ground conductor 853, the second power conductors 854A and 854B, the second output conductors 855A and 855B, and the second ground conductor 856, which are the cause of the large warp of the assembled body, is to be reduced. To be more detailed, the first power conductors 851A and 851B and the second power conductors 854A and 854B are each formed in a smaller volume than the first output conductors 852A and 852B, the first ground conductor 853, the second output conductors 855A and 855B, and the second ground conductor 856. Such a configuration reduces the stress originating from the condensation of the plurality of conductors 850 in the formation process of the resin layer 830, thereby suppressing the warp of the assembled body.

The semiconductor device 1A according to this embodiment provides the following advantageous effects.

(1-1) A larger current flows through the first circuit 61 than through the second circuit 62, in the semiconductor element 60. Accordingly, among the plurality of conductors 50, the first power conductors 51A and 51B, the first output conductors 52A and 520, the first ground conductor 53, the second power conductors 54A and 54B, the second output conductors 55A and 55B, and the second ground conductor 56, which are electrically connected to the first circuit 61, are each formed in a larger volume than the control conductors 57, to reduce the electrical resistance in the conduction path between the first circuit 61 and the terminals 20 connected thereto. On the other hand, as described above, increasing the volume of the first power conductors 51A and 51A, the first output conductors 52A and 52B, the first ground conductor 53, the second power conductors 54A and 54B, the second output conductors 55A and 55B, and the second ground conductor 56 leads to a larger warp of the assembled body composed of the base material 810 and the resin layer 830, during the formation process of the resin layer 830 in the manufacturing process of the semiconductor device 1A.

In this embodiment, therefore, the first power conductors 51A and 51B are each formed in a smaller volume, than the first output conductors 52A and 52B and the first ground conductor 53. Likewise, the second power conductors 54A and 54B are each formed in a smaller volume, than the second output conductors 55A and 55B and the second ground conductor 56. In this case, during the formation of the plurality of conductors 850 in the manufacturing process of the semiconductor device 1A, the first power conductors 851A and 851B are each formed in a smaller volume than the first output conductors 852A and 852B and the first ground conductor 853, and the second power conductors 854A and 854B are each formed in a smaller volume than the second output conductors 855A and 855B and the second ground conductor 856. Therefore, the warp of the assembled body composed of the base material 810 and the resin layer 830 can be suppressed, during the formation process of the resin layer 830. Such an arrangement facilitates the assembled body to be transported, and to be properly diced, in the subsequent process. Consequently, the electrical resistance in the conduction path between the first circuit 61 and the terminals 20 connected thereto can be reduced, and the semiconductor device 1A can be stably manufactured.

(1-2) The respective top faces 50A of the first power conductors 51A and 51B, exposed from the sealing resin 30 in the z-direction, are smaller in area than the respective top faces 50A of the first output conductors 52A and 52B and the first ground conductor 53, exposed from the sealing resin 30 in the z-direction. The respective top faces 50A of the second power conductors 54A and 54B, exposed from the sealing resin 30 in the z-direction, are smaller in area than the respective top faces 50A of the second output conductors 55A and 55B and the second ground conductor 56, exposed from the sealing resin 30 in the z-direction. To attain such a configuration, the first power conductors 851A and 851B are each formed in a smaller volume than the first output conductors 852A and 852B and the first ground conductor 853, and the second power conductors 854A and 854B are each formed in a smaller volume than the second output conductors 855A and 855B and the second ground conductor 856, during the formation of the plurality of conductors 850 in the manufacturing process of the semiconductor device 1A. Then by removing the resin layer 830 thereby reducing the thickness thereof, the respective top faces 50A of the first power conductors 51A and 51B, exposed from the sealing resin 30 in the z-direction, are made smaller in area than the respective top faces 50A of the first output conductors 52A and 52B and the first ground conductor 53, exposed from the sealing resin 30 in the z-direction, and the respective top faces 50A of the second power conductors 54A and 54B, exposed from the sealing resin 30 in the z-direction, are made smaller in area than the respective top faces 50A of the second output conductors 55A and 55B and the second ground conductor 56, exposed from the sealing resin 30 in the z-direction. Thus, the warp of the assembled body is suppressed owing to the relation in area among the top faces of the conductors 850, exposed from the resin layer 830 in the z-direction as result of the grinding of the resin layer 830. Therefore, the shape of the conductors 850 can be simplified, which facilitates the formation of the conductors 850.

(1-3) The first output conductors 52A and 52B, the first ground conductor 53, the second output conductors 55A and 55B, and the second ground conductor 56 are each larger in volume than the control conductors 57. Such a configuration reduces the electrical resistance in the conduction path between the first circuit 61, where a relatively large current flows, and the terminals 20 electrically connected to the first circuit 61, thereby improving the heat dissipation performance of the semiconductor device 1A.

(1-4) The respective top faces 50A of the first output conductors 52A and 52B, the first ground conductor 53, the second output conductors 55A and 55B, and the second ground conductor 56 are each larger in area, than the respective top faces 50A of the control conductors 57. Such a configuration enables the first output conductors 52A and 52B, the first ground conductor 53, the second output conductors 55A and 55B, and the second ground conductor 56 to accept a larger current, than a current applied to the control conductors 57.

In addition, the first output terminals 22A and 22B, the first ground terminal 23, the second output terminals 25A and 25B, and the second ground terminal 26 are larger in area than the control terminals 27, as viewed in the z-direction. Accordingly, when the semiconductor device 1A is mounted on a circuit board (not shown), the bonding area between the wiring pattern of the circuit board, and the first output terminals 22A and 22B, the first ground terminal 23, the second output terminals 25A and 25B, and the second ground terminal 26 becomes larger than the bonding area between the wiring pattern of the circuit board and the control terminals 27. As result, the electrical resistance between the circuit board and the first output terminals 22A and 22B, the first ground terminal 23, the second output terminals 25A and 25B, and the second ground terminal 26 becomes lower than the electrical resistance between the circuit board and the control terminals 27. Consequently, the first output terminals 22A and 22B, the first ground terminal 23, the second output terminals 25A and 25B, and the second ground terminal 26 can each accept a larger current than a current applied to the control terminals 27.

(1-5) The plurality of control conductors 57 are located on the outer side in the y-direction, with respect to the first power conductors 51A and 51B, the first output conductors 52A and 52B, the first ground conductor 53, the second power conductors 54A and 54B, the second output conductors 55A and 55B, and the second ground conductor 56. Such a configuration enables the volume of the first output conductors 52A and 52B, the first ground conductor 53, the second output conductors 55A and 55B, and the second ground conductor 56 to be increased, by increasing the length in the x-direction of the first output conductors 52A and 52B, the first ground conductor 53, the second output conductors 55A and 55B, and the second ground conductor 56. Therefore, the volume of the first output conductors 52A and 52B, the first ground conductor 53, the second output conductors 55A and 55B, and the second ground conductor 56 can be increased, while suppressing an increase in size of the semiconductor device 1A in the y-direction.

In addition, the plurality of control conductors 57 can be located so as to overlap with the first power conductors 51A and 51B, the first output conductors 52A and 52B, or the first ground conductor 53 as viewed in the y-direction, and so as to overlap with the second power conductors 54A and 54B, the second output conductors 55A and 55B, and the second ground conductor 56 as viewed in the y-direction. Therefore, the space for locating the plurality of control conductors 57 can be secured in the x-direction.

(1-6) The control conductors 57 include four distal control conductors 57C respectively located at the four corners of the substrate 10, and the intermediate control conductors 57E located between two of the distal control conductors 57C spaced apart from each other in the x-direction. The top face 50A of the distal control conductor 57C is larger in area than the top face 50A of the intermediate control conductor 579. With such a configuration, since the distal control conductors 57C are larger in area, a higher bonding strength between the control conductor 57 and the circuit board can be attained at the four corners of the substrate 10, when the semiconductor device 1A is mounted on the circuit board, for example via solder. Therefore, concentration of thermal stress at the four corners of the substrate 10, originating from the heat generated during the use of the semiconductor device 1A, can be mitigated. As result, the solder between the semiconductor device 1A and the circuit board can be exempted from suffering a crack.

(1-7) The respective top faces 50A of the first output conductors 52A and 52B, the first ground conductor 53, the second output conductors 55A and 55B, and the second ground conductor 56 are longer in the x-direction, than the respective top faces 50A of the control conductors 57. In other words, the respective top faces 50A of the first output conductors 52A and 52B and the first ground conductor 53 are made longer in the x-direction, orthogonal to the y-direction in which the first power conductors 51A and 51B, the first output conductors 52A and 528, and the first ground conductor 53 are aligned. Likewise, the respective top faces 50A of the second output conductors 55A and 55B and the second ground conductor 56 are made longer in the x-direction, orthogonal to the y-direction in which the first power conductors 51A and 51B, the first output conductors 52A and 52B, and the first ground conductor 53 are aligned. Such a configuration reduces the electrical resistance in the first output conductors 52A and 52B, the first ground conductor 53, the second output conductors 55A and 55B, and the second ground conductor 56, while suppressing an increase in size of the semiconductor device 1A in the y-direction.

Further, increasing the length in the x-direction of the first output conductors 52A and 528 and the first ground conductor 53, opposed to the first circuit 61 in the x-direction, allows the first output conductors 52A and 52B and the first ground conductor 53 to be located closer to the first circuit 61. In this case, the conduction path between the first output terminals 22A and 22B and the first ground terminal 23, and the first circuit 61, is shortened, and therefore the electrical resistance between the first output terminals 22A and 220 and the first ground terminal 23, and the first circuit 61, can be reduced.

Likewise, increasing the length in the x-direction of the second output conductors 55A and 55B and the second ground conductor 56, opposed to the first circuit 61 in the x-direction, allows the second output conductors 55A and 55B and the second ground conductor 56 to be located closer to the first circuit 61. In this case, the conduction path between the second output terminals 25A and 25B and the second ground terminal 26, and the first circuit 61, is shortened, and therefore the electrical resistance between the second output terminals 25A and 25B and the second ground terminal 26, and the first circuit 61, can be reduced.

(1-8) Among the plurality of wirings 40, the first power wirings 41A and 41B, the first output wirings 42A and 42B, the first ground wiring 43, the second power wirings 44A and 44B, the second output wirings 45A and 45B, and the second ground wiring 46 are wider than the connecting wiring section 47b of the control wiring 47. Such a configuration reduces the electrical resistance of the wirings 40 connected to the first circuit 61, where a larger current flows than in the second circuit 62.

(1-9) The wiring 40 connected to one of the plurality of conductors 50 aligned in the y-direction along the end portions of the substrate 10 in the x-direction, having a larger volume, is wider than the wiring 40 connected to the conductor 50 having a smaller volume. In this embodiment, the first output wirings 42A and 42B and the first ground wiring 43 are each wider than the first power wirings 41A and 41B. The second output wirings 45A and 45B and the second ground wiring 46 are each wider than the second power wirings 44A and 44B. Increasing thus the width of the wirings 40 close to the first circuit 61 reduces the electrical resistance of the conduction path between the first circuit 61 and the terminal 20.

(1-10) The plurality of control conductors 57 are each located on the outer side in the y-direction, with respect to the semiconductor element 60. Such a configuration enables the space for locating the plurality of control conductors 57 to be secured in the x-direction. Therefore, a space between the control conductors 57 located adjacent to each other in the x-direction can be secured, which prevents the occurrence of a short circuit between the control conductors 57, after the semiconductor device 1A is mounted on the circuit board.

(1-11) The first output wirings 42A and 42B each include the sloped section 42c, and the second output wirings 45A and 45B each include the sloped section 45c. Such a configuration reduces the area of one of the end portions of the wide wiring section 42a of the first output wirings 42A and 42B in the x-direction, closer to the narrow wiring section 42b, and also reduces the area of one of the end portions of the wide wiring section 45a of the second output wirings 45A and 45B in the x-direction, closer to the narrow wiring section 45b. Therefore, the electrical resistance of the first output wirings 42A and 42B and the second output wirings 45A and 45B can be reduced.

(1-12) The respective narrow wiring sections 41b of the first power wirings 41A and 41B are located closer to the center of the substrate 10 in the y-direction, than is the wide wiring section 41a, and the respective narrow wiring sections 44b of the second power wirings 44A and 44B are located closer to the center of the substrate 10 in the y-direction, than is the wide wiring section 44a. Such a configuration allows the respective wide wiring sections 42a of the first output wirings 42A and 42B to be made wider, and the respective wide wiring sections 45a of the second output wirings 45A and 45B to be made wider. Therefore, the electrical resistance of each of the first output wirings 42A and 420, and the electrical resistance of each of the second output wirings 45A and 45B can be reduced.

(1-13) The semiconductor element 60 is flip-chip bonded onto the plurality of wirings 40. Such a structure allows the sealing resin 30 to be thinner, compared with, for example, the case where the element obverse face 60s of the semiconductor element 60 and the plurality of wirings 40 are connected via wires. Therefore, the semiconductor device 1A can be formed in a lower height.

(1-14) The first ground wiring 43 includes the slit 43a. The element electrodes 60a of the semiconductor element 60 are bonded to the first ground wiring 43, on both sides of the slit 43a. In other words, the element electrodes 60a on the first switching unit 61A of the semiconductor element 60 are bonded to the first ground wiring 43 on the side of the substrate side face 15 with respect to the slit 43a, and the element electrodes 60a on the second switching unit 61B are bonded to the first ground wiring 43 on the side of the substrate side face 16 with respect to the slit 43a. Such a configuration prevents the noise generated from the first switching unit 61A or the second switching unit 61B from interfering with the other switching unit, when the semiconductor device 1A is in use.

The second ground wiring 46 includes the slit 46a. The element electrodes 60a of the semiconductor element 60 are bonded to the second ground wiring 46, on both sides of the slit 46a. In other words, the element electrodes 60a on the third switching unit 61C of the semiconductor element 60 are bonded to the second ground wiring 46 on the side of the substrate side face 15 with respect to the slit 46a, and the element electrodes 60a on the fourth switching unit 61D are bonded to the second ground wiring 46 on the side of the substrate side face 16 with respect to the slit 46a. Such a configuration prevents the noise generated from the third switching unit 61C or the fourth switching unit 61D from interfering with the other switching unit, when the semiconductor device 1A is in use.

(1-15) The plurality of conductors 50 are located on the inner side of the peripheral edge of the sealing resin 30, as viewed in the z-direction. Accordingly, the plurality of conductors 50 are exempted from being cut by the dicing blade, when the resin layer 830 and the base material 810 are cut into individual pieces, in the manufacturing process of the semiconductor device 1A. Therefore, the plurality of conductors 50 can be prevented from suffering a damage.

### Second Embodiment (First Aspect)

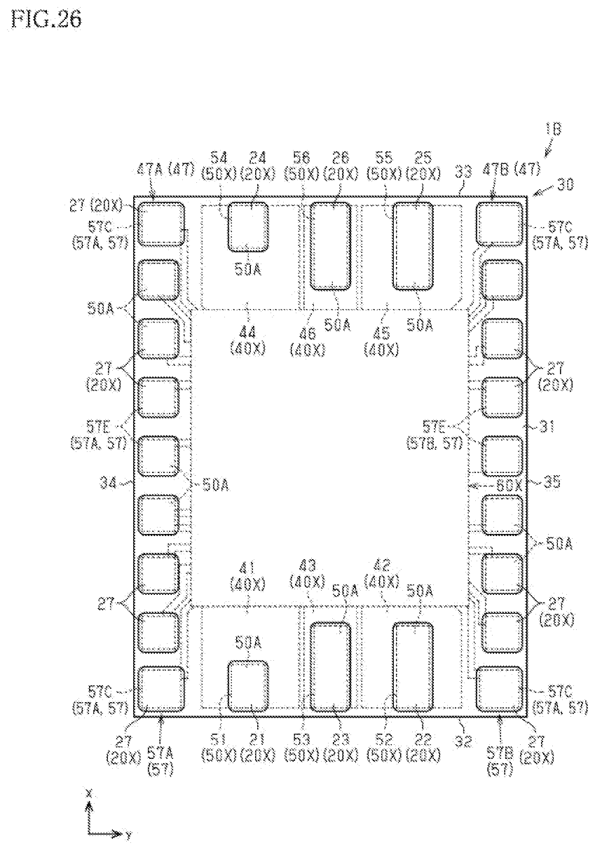

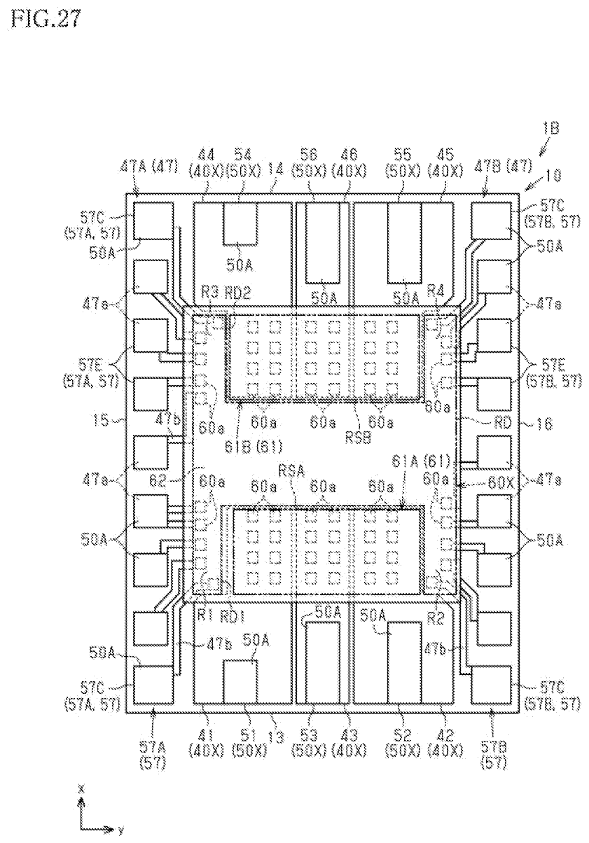

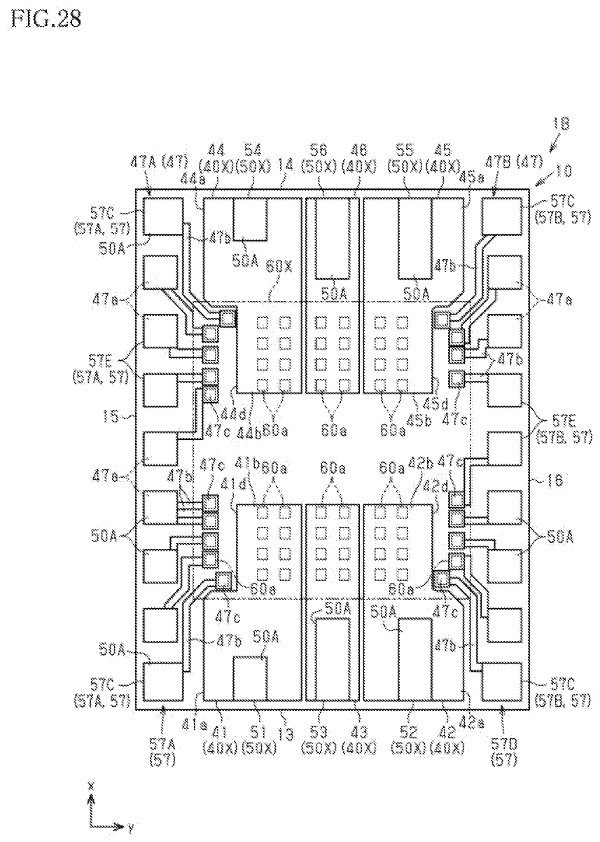

Referring now to FIG. 26 to FIG. 28, a semiconductor device 1B according to a second embodiment of the first aspect will be described hereunder. The semiconductor device 1B according to this embodiment is different from the semiconductor device 1A according to the first embodiment, in the configuration of the plurality of terminals, the plurality of wirings, the plurality of conductors, and the semiconductor element. In the following description, the elements employed in common with the semiconductor device 1A according to the first embodiment are given the same numeral, and the description thereof may be skipped.

As shown in FIG. 27 and FIG. 28, the semiconductor device 1B includes a plurality of wirings 40X, a plurality of conductors 50X, and a semiconductor element 60X. The semiconductor element 60X includes the first circuit 61 and the second circuit 62. The first circuit 61 includes a fewer number of switching units, than the first circuit 61 (see FIG. 4) of the first embodiment. The first circuit 61 includes the first switching unit 61A and the second switching unit 61B. In other words, the first circuit 61 according to this embodiment is without the third switching unit 61C and the fourth switching unit 61D. The switching units 61A and 61B have the same configuration as the switching units 61A and 61B of the first embodiment. The second circuit 62 includes a control circuit that controls the switching units 61A and 61B.

In this embodiment, as shown in FIG. 27, the circuit region RD where the second circuit 62 is formed has the same size and shape, as the circuit region RD of the first embodiment. In other words, the circuit region RD according to this embodiment includes two recesses RD1 and RD, and the regions R1 to R4.

The circuit region RSA, where the first switching unit 61A according to this embodiment is formed, is larger than the circuit region RSA of the first embodiment. The circuit region RSA according to this embodiment is approximately twice as large in area, as the circuit region RSA of the first embodiment. The circuit region RSA according to this embodiment has a rectangular shape having the long sides extending in the y-direction and the short sides extending in the x-direction, as viewed in the z-direction.

The circuit region RSB, where the second switching unit 61B according to this embodiment is formed, is larger than the circuit region RSB of the first embodiment. The circuit region RSB according to this embodiment is approximately twice as large in area, as the circuit region RSB of the first embodiment. The circuit region RSB according to this embodiment has a rectangular shape having the long sides extending in the y-direction and the short sides extending in the x-direction, as viewed in the z-direction. The circuit region RSB has the same size as the circuit region RSA.

The circuit region RSA is located inside the recess RD1 of the circuit region RD, and the circuit region RSB is located inside the recess RD2 of the circuit region RD. The circuit region RSA is aligned with the circuit region RSB in the y-direction, and spaced therefrom in the x-direction.

The plurality of wirings 40X include a first power wiring 41, a first output wiring 42, the first ground wiring 43, a second power wiring 44, a second output wiring 45, and the second ground wiring 46. In other words, the plurality of wirings 40X according to this embodiment are different from the plurality of wirings 40 of the first embodiment, in only including one each of the first power wiring, the first output wiring, the second power wiring, and the second output wiring. The plurality of wirings 40X include the plurality of control wirings 47. The number of the plurality of control wirings 47 is equal to that of the plurality of control wirings 47 in the plurality of wirings 40 of the first embodiment. In this embodiment, the first power wiring 41 and the second power wiring 44 correspond to the first drive wiring, and the first output wiring 42, the first ground wiring 43, the second output wiring 45, and the second ground wiring 46 correspond to the second drive wiring.

The first power wiring 41, the first output wiring 42, and the first ground wiring 43 are electrically connected to the first switching unit 61A. In other words, the first power wiring 41 serves to supply a current from an external power source (not shown) to the first switching unit 61A, the first output wiring 42 serves to output the current from the first switching unit 61A to outside of the semiconductor device 18, and the first ground wiring 43 serves to provide the ground for the first switching unit 61A.

The first power wiring 41, the first output wiring 42, and the first ground wiring 43 are located close to the substrate side face 13, in the x-direction. The first power wiring 41, the first output wiring 42, and the first ground wiring 43 are aligned with each other in the x-direction, and spaced apart from each other in the y-direction. The first ground wiring 43 is located at the central position of the substrate obverse face 11, in the y-direction. The first power wiring 41 and the first output wiring 42 are separately located on the respective sides of the first ground wiring 43, in the y-direction. The first power wiring 41 is located on the side of the substrate side face 15 in the y-direction, with respect to the first ground wiring 43. The first output wiring 42 is located on the side of the substrate side face 16 in the y-direction, with respect to the first ground wiring 43.

The second power wiring 44, the second output wiring 45, and the second ground wiring 46 are electrically connected to the second switching unit 618. In other words, the second power wiring 44 serves to supply a current from an external power source (not shown) to the second switching unit 618, the second output wiring 45 serves to output the current from the second switching unit 61B to outside of the semiconductor device 1B, and the second ground wiring 46 serves to provide the ground for the second switching unit 618.

The second power wiring 44, the second output wiring 45, and the second ground wiring 46 are located close to the substrate side face 14, in the x-direction. The second power wiring 44, the second output wiring 45, and the second ground wiring 46 are aligned with each other in the x-direction, and spaced apart from each other in the y-direction. The second ground wiring 46 is located at the central position of the substrate obverse face 11, in the y-direction. The second power wiring 44 and the second output wiring 45 are separately located on the respective sides of the second ground wiring 46, in the y-direction. The second power wiring 44 is located on the side of the substrate side face 15 in the y-direction, with respect to the second ground wiring 46. The second output wiring 45 is located on the side of the substrate side face 16 in the y-direction, with respect to the second ground wiring 46.

The second power wiring 44, the second output wiring 45, and the second ground wiring 46 are spaced apart from the first power wiring 41, the first output wiring 42, and the first ground wiring 43, in the x-direction. As viewed in the x-direction, the second power wiring 44 overlaps with the first power wiring 41, the second output wiring 45 overlaps with the first output wiring 4, and the second ground wiring 46 overlaps with the first ground wiring 43.

Further, the first power wiring 41, the first output wiring 42, the first ground wiring 43, the second power wiring 44, the second output wiring 45, and the second ground wiring 46 are different in shape, compared with the plurality of wirings 40 of the first embodiment.

As shown in FIG. 28, the first power wiring 41 includes the wide wiring section 41a and the narrow wiring section 41b. In other words, the first power wiring 41 is without the connecting wiring section 41c, unlike the first power wirings 41A and 41B of the first embodiment. The wide wiring section 41a is wider than the wide wiring section 41a of the first power wirings 41A and 41B of the first embodiment. The narrow wiring section 41b is wider than the narrow wiring section 41b of the first power wirings 41A and 41B of the first embodiment. To the narrow wiring section 41b, eight element electrodes 60a of the semiconductor element 60X are bonded. The eight element electrodes 60a are arranged in two rows, each including four element electrodes 60a aligned with each other in the y-direction and spaced apart from each other in the x-direction. The two rows of the element electrodes 60a are aligned with each other in the x-direction, and spaced apart from each other in the y-direction.

The narrow wiring section 41b is located on the side of the first ground wiring 43 (substrate side face 16) in the y-direction, with respect to the wide wiring section 41a. Accordingly, the first power wiring 41 includes the recessed region 41d. In the recessed region 41d, the connecting end section 47c of the control wiring 47, electrically connected to the first region R1 (see FIG. 27) of the second circuit 62, is located.

The shape of the first output wiring 42 viewed in the z-direction is generally symmetrical to that of the first power wiring 41, with respect to an imaginary center line of the substrate 10, passing the center thereof in the y-direction and extending in the x-direction. Accordingly, the first output wiring 42 includes, like the wide wiring section 41a and the narrow wiring section 41b of the first power wiring 41, the wide wiring section 42a and the narrow wiring section 42b. To the narrow wiring section 42b, eight element electrodes 60a are bonded. The arrangement pattern of these eight element electrodes 60a on the narrow wiring section 42b is the same as that of the eight element electrodes 60a on the narrow wiring section 41b of the first output wiring 42A. In addition, the first output wiring 42 includes the recessed region 42d, like the recessed region 41d of the first power wiring 41. In the recessed region 42d, the connecting end section 47c of the control wiring 47, electrically connected to the second region R2 (see FIG. 27) of the second circuit 62, is located.

The first ground wiring 43 extends along the x-direction. The first ground wiring 43 is without the slit 43a. The shape of the second power wiring 44 viewed in the z-direction is symmetrical to that of the first power wiring 41, with respect to the imaginary center line of the substrate 10, passing the center thereof in the x-direction and extending in the y-direction. Accordingly, the second power wiring 44 includes, like the wide wiring section 41a and the narrow wiring section 41b of the first power wiring 41, the wide wiring section 44a and the narrow wiring section 44b. To the narrow wiring section 44b, eight element electrodes 60a are bonded. The arrangement pattern of these eight element electrodes 60a on the narrow wiring section 44b is the same as that of the eight element electrodes 60a on the narrow wiring section 41b. In addition, the second power wiring 44 includes the recessed region 44d, like the recessed region 41d of the first power wiring 41. In the recessed region 44d, the connecting end section 47c of the control wiring 47, electrically connected to the third region R3 (see FIG. 27) of the second circuit 62, is located.

The shape of the second output wiring 45 viewed in the z-direction is symmetrical to that of the first output wiring 42, with respect to the imaginary center line of the substrate 10, passing the center thereof in the x-direction and extending in the y-direction. Accordingly, the second output wiring 45 includes, like the wide wiring section 42a and the narrow wiring section 42b of the first output wiring 42, the wide wiring section 45a and the narrow wiring section 45b. In addition, the second output wiring 45 includes the recessed region 45d, like the recessed region 42d of the first output wiring 42. In the recessed region 45d, the connecting end section 47c of the control wiring 47, electrically connected to the fourth region R4 (see FIG. 27) of the second circuit 62, is located.

The shape of the second ground wiring 46 viewed in the z-direction is symmetrical to that of the first ground wiring 43, with respect to the imaginary center line of the substrate 10, passing the center thereof in the x-direction and extending in the y-direction. The second ground wiring 46 is without the slit 46a. Here, the number of element electrodes 60a bonded to each of the wirings 41 to 46 may be changed as desired.

The plurality of conductors 50X according to this embodiment include a first power conductor 51, a first output conductor 52, the first ground conductor 53, a second power conductor 54, a second output conductor 55, and the second ground conductor 56. In other words, the plurality of conductors 50X according to this embodiment are different from the plurality of conductors 50 of the first embodiment, in only including one each of the first power wiring, the first output wiring, the second power wiring, and the second output wiring. The plurality of conductors 50X also include the plurality of control conductors 57. The number of the plurality of control conductors 57 is equal to that of the plurality of control conductors 57, in the plurality of conductors 50 of the first embodiment. In this embodiment, the first power conductor 51 and the second power conductor 54 correspond to the first drive conductor, and the first output conductor 52, the first ground conductor 53, the second output conductor 55, and the second ground conductor 56 correspond to the second drive conductor.

The first power conductor 51 has the same size and shape, as the first power conductor 51A of the first embodiment. Accordingly, the top face 50A of the first power conductor 51 has the same area as the top face 50A of the first power conductor 51A. The first power conductor 51 has the same volume as the first power conductor 51A.

The first output conductor 52 has the same size and shape, as the first output conductor 52A of the first embodiment. Accordingly, the top face 50A of the first output conductor 52 has the same area as the top face 50A of the first output conductor 52A. The first output conductor 52 has the same volume as the first output conductor 52A.

The first ground conductor 53 has the same size and shape, as the first ground conductor 53 of the first embodiment. Accordingly, the top face 50A of the first ground conductor 53 according to this embodiment has the same area as the top face 50A of the first ground conductor 53 of the first embodiment. The first ground conductor 53 according to this embodiment has the same volume as the first ground conductor 53 of the first embodiment.

Therefore, the top face 50A of the first power conductor 51 is smaller in area than the top face 50A of the first output conductor 52 and the top face 50A of the first ground conductor 53. The top face 50A of the first output conductor 52 has the same area as the top face 50A of the first ground conductor 53. The first power conductor 51 is smaller in volume than the first output conductor 52 and the first ground conductor 53. The first output conductor 52 has the same volume as the first ground conductor 53.

In this embodiment, further, since the number of first power wirings and the number of first output wirings are fewer than those of the first embodiment, the first power wiring 41 and the first output wiring 42 each have an increased width.

As shown in FIG. 26, the first power wiring 41 is equal to or more than twice as wide as the length of the top face 50A of the first power conductor 51 in the y-direction. In this embodiment, the width of the first power wiring 41 is between twice and three times, both ends inclusive, of the width of the first power conductor 51. The first output wiring 42 is equal to or more than twice as wide as the length of the top face 50A of the first output conductor 52 in the y-direction. In this embodiment, the width of the first output wiring 42 is between twice and three times, both ends inclusive, of the length of the top face 50A of the first output conductor 52 in the y-direction.

The second power conductor 54 has the same size and shape as the second power conductor 54A of the first embodiment. Accordingly, the top face 50A of the second power conductor 54 has the same area as the top face 50A of the second power conductor 54A. The second power conductor 54 has the same volume as the second power conductor 54A.

The second output conductor 55 has the same size and shape as the second output conductor 55A of the first embodiment. Accordingly, the top face 50A of the second output conductor 55 has the same area as the top face 50A of the second output conductor 55A. The second output conductor 55 has the same volume as the second output conductor 55A.

The second ground conductor 56 has the same size and shape, as the second ground conductor 56 of the first embodiment. Accordingly, the top face 50A of the second ground conductor 56 according to this embodiment has the same area as the top face 50A of the second ground conductor 56 of the first embodiment. The second ground conductor 56 according to this embodiment has the same volume as the second ground conductor 56 of the first embodiment.

Therefore, the top face 50A of the second power conductor 54 is smaller in area than the top face 50A of the second output conductor 55 and the top face 50A of the second ground conductor 56. The top face 50A of the second output conductor 55 has the same area as the top face 50A of the second ground conductor 56. The second power conductor 54 is smaller in volume than the second output conductor 55 and the second ground conductor 56. The second output conductor 55 has the same volume as the second ground conductor 56.

In this embodiment, further, since the number of second power wirings and the number of second output wirings are fewer than those of the first embodiment, the second power wiring 44 and the second output wiring 45 each have an increased width.

As shown in FIG. 28, the second power wiring 44 is equal to or more than twice as wide as the length of the top face 50A of the second power conductor 54 in the y-direction. In this embodiment, the width of the second power wiring 44 is between twice and three times, both ends inclusive, of the length of the top face 50A of the second power conductor 54 in the y-direction. The second output wiring 45 is equal to or more than twice as wide as the length of the top face 50A of the first output conductor 52 in the y-direction. In this embodiment, the width of the second output wiring 45 is between twice and three times, both ends inclusive, of the length of the top face 50A of the second output conductor 55 in the y-direction.

As shown in FIG. 26, the semiconductor device 18 includes a plurality of terminals 20X. The plurality of terminals 20X include a first power terminal 21, a first output terminal 22, the first ground terminal 23, a second power terminal 24, a second output terminal 25, and the second ground terminal 26. In other words, the plurality of terminals 20X according to this embodiment is different from the plurality of terminals 20 of the first embodiment, in only including one each of the first power terminal, the first output terminal, the second power terminal, and the second output terminal. The plurality of terminals 20X also include the plurality of control terminals 27. The number of the plurality of control terminals 27 is equal to that of the plurality of control terminals 27 in the plurality of terminals 20 of the first embodiment. In this embodiment, the first power terminal 21 and the second power terminal 24 correspond to the first drive terminal, and the first output terminal 22, the first ground terminal 23, the second output terminal 25, and the second ground terminal 26 correspond to the second drive terminal.

The semiconductor device 1B according to this embodiment provides the following advantageous effects, in addition to those provided by the first embodiment.

(2-1) The first power conductor 51, the first output conductor 52, and the first ground conductor 53 are aligned along one of the end portions of the sealing resin 30 in the x-direction, and the second power conductor 54, the second output conductor 55, and the second ground conductor 56 are aligned along the other end portion of the sealing resin 30 in the x-direction. Thus, a fewer number of conductors 50 larger in volume than the control conductor 57 are provided, compared with the first embodiment. Therefore, the warp of the assembled body composed of the resin layer 830 and the base material 810 (see FIG. 25 for both) can be minimized.

In addition, a fewer number of wirings 40 are connected to the first circuit 61, compared with the first embodiment. In other words, a fewer number of wirings 40 are aligned in the y-direction. Accordingly, the first power wiring 41 and the first output wiring 42 are each made wider, in this embodiment. In addition, the second power wiring 44 and the second output wiring 45 are each made wider. Therefore, the electrical resistance of each of the first power wiring 41, the first output wiring 42, the second power wiring 44, and the second output wiring 45 can be reduced.

(2-2) The first power wiring 41 is equal to or more than twice as wide as the length of the top face 50A of the first power conductor 51 in the y-direction, and the second power wiring 44 is equal to or more than twice as wide as the length of the top face 50A of the second power conductor 54. Therefore, the electrical resistance of each of the first power wiring 41 and the second power wiring 44 can be reduced. Such a configuration is appropriate for supplying a larger current to each of the first switching unit 61A and the second switching unit 61B of the first circuit 61.

(2-3) The first output wiring 42 is equal to or more than twice as wide as the length of the top face 50A of the first output conductor 52 in the y-direction, and the second output wiring 45 is equal to or more than twice as wide as the length of the top face 50A of the second output conductor 55. Therefore, the electrical resistance of each of the first output wiring 42 and the second output wiring 45 can be reduced. Such a configuration is appropriate for supplying a larger current to each of the first switching unit 61A and the second switching unit 618 of the first circuit 61.

### <Variation (First Aspect)>

The foregoing embodiments merely exemplify possible configurations of the semiconductor device according to the present disclosure, and are in no way intended to limit the configuration. The semiconductor device according to the present disclosure may assume a form different from those exemplified by the embodiments. For example, a part of the configuration of the foregoing embodiments may be substituted, modified, or excluded, and a new element may be added to the foregoing embodiments. Further, the variations described hereunder may be combined with each other, unless a technical contradiction is incurred. In the following variations, the elements employed in common with the embodiments are given the same numeral, and the description thereof will not be repeated.

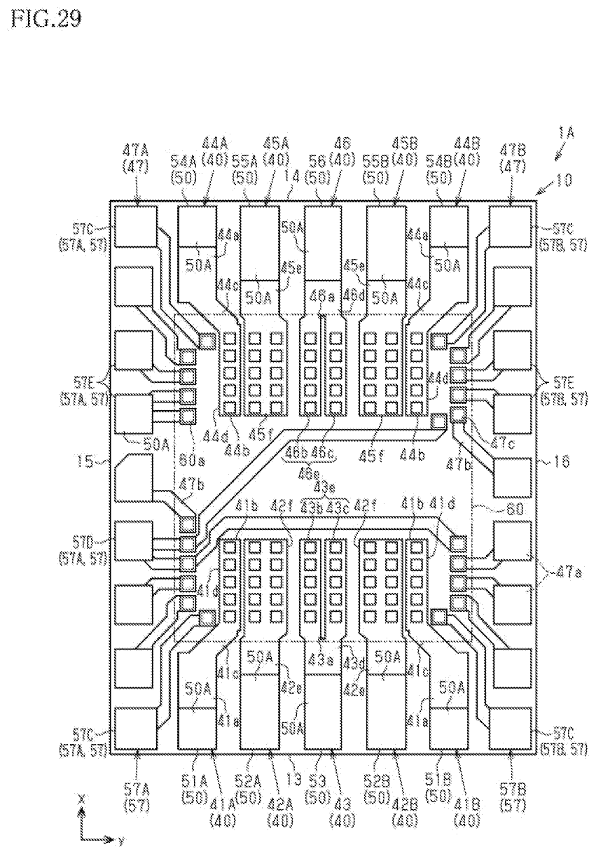

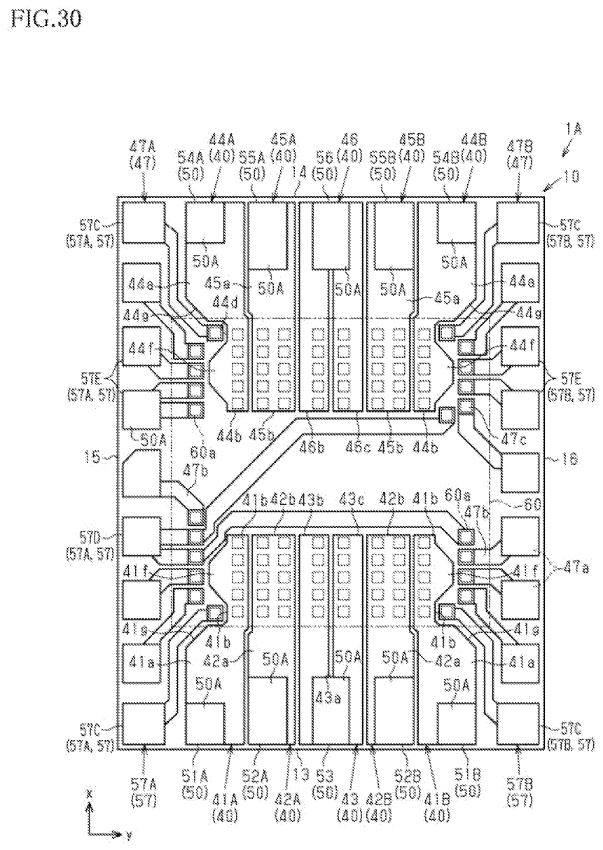

In the first embodiment, the shape of each of the first power wirings 41A and 41B, the first output wirings 42A and 428, the first ground wiring 43, the second power wirings 44A and 44B, the second output wirings 45A and 45B, and the second ground wiring 46 may be modified. For example, the shape of these wirings may be modified to a first example shown in FIG. 29, or a second example shown in FIG. 30.

In the first example, as shown in FIG. 29, the plurality of wirings 40 are narrower than the plurality of wirings 40 of the first embodiment. To be more detailed, the first power wirings 41A and 41B each include, like the first power wiring 41A of the first embodiment, the wide wiring section 41a, the narrow wiring section 41b, and the connecting wiring section 41c. The wide wiring section 41a of the first power wiring 41A is narrower than the wide wiring section 41a of the first power wiring 41A of the first embodiment, and the wide wiring section 41a of the first power wiring 41B is narrower than the wide wiring section 41a of the first power wiring 41B of the first embodiment. In the illustrated example, the wide wiring section 41a of the first power wiring 41A has the same width as the length of the top face 50A of the first power conductor 51A in the y-direction, and the wide wiring section 41a of the first power wiring 41B has the same width as the length of the top face 50A of the first power conductor 51B in the y-direction. Here, when the difference between the width of the wide wiring section 41a of the first power wiring 41A and the length of the top face 50A of the first power conductor 51A in the y-direction is, for example, within 5% of the length of the top face 50A of the first power conductor 51A in the y-direction, the width of the wide wiring section 41a of the first power wiring 41A may be regarded as being equal to the length of the top face 50A of the first power conductor 51A in the y-direction. Likewise, when the difference between the width of the wide wiring section 41a of the first power wiring 41B and the length of the top face 50A of the first power conductor 51B in the y-direction is, for example, within 51 of the length of the top face 50A of the first power conductor 51B in the y-direction, the width of the wide wiring section 41a of the first power wiring 41B may be regarded as being equal to the length of the top face 50A of the first power conductor 51B in the y-direction.

In the illustrated example, the connecting wiring section 41c of the first power wiring 41A is narrower than the connecting wiring section 41c of the first power wiring 41A of the first embodiment, and the connecting wiring section 41c of the first power wiring 41B is narrower than the connecting wiring section 41c of the first power wiring 41B of the first embodiment. In the illustrated example, the connecting wiring section 41c of the first power wiring 41A has the same width as the narrow wiring section 41b of the first power wiring 41A, and the connecting wiring section 41c of the first power wiring 419 has the same width as the narrow wiring section 41b of the first power wiring 41B.

The first output wirings 42A and 42B each include an outer wiring section 42e and an inner wiring section 42f. The inner wiring section 42f of the first output wiring 42A corresponds to the narrow wiring section 42b of the first output wiring 42A of the first embodiment, and the inner wiring section 42f of the first output wiring 42B corresponds to the narrow wiring section 42b of the first output wiring 42B of the first embodiment. The outer wiring section 42e of the first output wiring 42A is located on the outer side (on the side of the substrate side face 13) in the x-direction, with respect to the inner wiring section 42f of the first output wiring 42A. The outer wiring section 42e of the first output wiring 42B is located on the outer side (on the side of the substrate side face 13) in the x-direction, with respect to the inner wiring section 42f of the first output wiring 42b.

In the illustrated example, the outer wiring section 42e of the first output wiring 42A is narrower than the inner wiring section 42f of the first output wiring 42A. On the outer wiring section 42e, the first output conductor 52A is located. The outer wiring section 42e has the same width as the length of the top face 50A of the first output conductor 52A in the y-direction. Here, when the difference between the width of the outer wiring section 42e and the length of the top face 50A of the first output conductor 52A in the y-direction is, for example, within 5% of the length of the top face 50A of the first output conductor 52A in the y-direction, the width of the outer wiring section 42e may be regarded as being equal to the length of the top face 50A of the first output conductor 52A in the y-direction.

In the illustrated example, the outer wiring section 42e of the first output wiring 42B is narrower than the inner wiring section 42f of the first output wiring 42B. On the outer wiring section 42e, the first output conductor 52B is located. The outer wiring section 42e has the same width as the length of the top face 50A of the first output conductor 52B in the y-direction. Here, when the difference between the width of the outer wiring section 42e and the length of the top face 50A of the first output conductor 52B in the y-direction is, for example, within 5% of the length of the top face 50A of the first output conductor 52B in the y-direction, the width of the outer wiring section 42e may be regarded as being equal to the length of the top face 50A of the first output conductor 52B in the y-direction.

The first ground wiring 43 includes an outer wiring section 43d and an inner wiring section 43e. The inner wiring section 43e includes the slit 43a extending in the x-direction. The inner wiring section 43e corresponds to the portion of the first ground wiring 43 where the slit 43a is formed in the x-direction, and overlaps with the semiconductor element 60 see (FIG. 4), as viewed in the z-direction. The inner wiring section 43e includes a first wiring section 43b and a second wiring section 43c, defined by the slit 43a. The outer wiring section 43d is located on the outer side (on the side of the substrate side face 13) in the x-direction, with respect to the inner wiring section 43e. The outer wiring section 43d may also be described as being located on the outer side (on the side of the substrate side face 13) in the x-direction, with respect to the slit 43a.

In the illustrated example, the inner wiring section 43e is narrower than the first ground wiring 43 of the first embodiment. The outer wiring section 43d is narrower than the inner wiring section 43e. The outer wiring section 43d has the same width as the length of the top face 50A of the first ground conductor 53 in the y-direction. Here, when the difference between the width of the outer wiring section 43d and the length of the top face 50A of the first ground conductor 53 in the y-direction is, for example, within 5% of the length of the top face 50A of the first ground conductor 53 in the y-direction, the width of the outer wiring section 43d may be regarded as being equal to the length of the top face 50A of the first ground conductor 53 in the y-direction.

The shape of the second power wirings 44A and 44B viewed in the z-direction is symmetrical to that of the first power wirings 41A and 41B, with respect to the imaginary center line of the substrate 10, passing the center thereof in the x-direction and extending in the y-direction. Accordingly, the wide wiring section 44a of the second power wiring 44A corresponds to the wide wiring section 41a of the first power wiring 41A, the narrow wiring section 44b of the second power wiring 44A corresponds to the narrow wiring section 41b of the first power wiring 41A, and the connecting wiring section 44c of the second power wiring 44A corresponds to the connecting wiring section 41c of the first power wiring 41A. Likewise, the wide wiring section 44a of the second power wiring 44B corresponds to the wide wiring section 41a of the first power wiring 41B, the narrow wiring section 44b of the second power wiring 44B corresponds to the narrow wiring section 41b of the first power wiring 41B, and the connecting wiring section 44c of the second power wiring 44B corresponds to the connecting wiring section 41c of the first power wiring 41B.

On the wide wiring section 44a of the second power wiring 44A, the second power conductor 54A is located, and on the wide wiring section 44a of the second power wiring 44B, the second power conductor 54B is located. The wide wiring section 44a of the second power wiring 44A has the same width as the length of the top face 50A of the second power conductor 54A in the y-direction, and the wide wiring section 44a of the second power wiring 44B has the same width as the length of the top face 50A of the second power conductor 54B in the y-direction. Here, when the difference between the width of the wide wiring section 44a of the second power wiring 44A and the length of the top face 50A of the second power conductor 54A in the y-direction is, for example, within 5% of the length of the top face 50A of the second power conductor 54A in the y-direction, the width of the wide wiring section 44a of the second power wiring 44A may be regarded as being equal to the length of the top face 50A of the second power conductor 54A in the y-direction. Likewise, when the difference between the width of the wide wiring section 44a of the second power wiring 44B and the length of the top face 50A of the second power conductor 54B in the y-direction is, for example, within 5% of the length of the top face 50A of the second power conductor 54B in the y-direction, the width of the wide wiring section 44a of the second power wiring 44B may be regarded as being equal to the length of the top face 50A of the second power conductor 54B in the y-direction.

The shape of the second output wirings 45A and 45B viewed in the z-direction is symmetrical to that of the first output wirings 42A and 42B, with respect to the imaginary center line of the substrate 10, passing the center thereof in the x-direction and extending in the y-direction. Accordingly, the second output wirings 45A and 45B each include an outer wiring section 45e and an inner wiring section 45f. The outer wiring section 45e corresponds to the outer wiring section 42e, and the inner wiring section 45f corresponds to the inner wiring section 42f.

On the outer wiring section 45e of the second output wiring 45A, the second output conductor 55A is located, and on the outer wiring section 45e of the second output wiring 45B, the second output conductor 55B is located. The outer wiring section 45e of the second output wiring 45A has the same width as the length of the top face 50A of the second output conductor 55A in the y-direction, and the outer wiring section 45e of the second output wiring 45B has the same width as the length of the top face 50A of the second output conductor 55B in the y-direction. Here, when the difference between the width of the outer wiring section 45e of the second output wiring 45A and the length of the top face 50A of the second output conductor 55A in the y-direction is, for example, within 5% of the length of the top face 50A of the second output conductor 55A in the y-direction, the width of the outer wiring section 45e of the second output wiring 45A may be regarded as being equal to the length of the top face 50A of the second output conductor 55A in the y-direction. Likewise, when the difference between the width of the outer wiring section 45e of the second output wiring 45B and the length of the top face 50A of the second output conductor 55B in the y-direction is, for example, within 5% of the length of the top face 50A of the second output conductor 55B in the y-direction, the width of the outer wiring section 45e of the second output wiring 45B may be regarded as being equal to the length of the top face 50A of the second output conductor 55B in the y-direction.

The shape of the second ground wiring 46 viewed in the z-direction is symmetrical to that of the first ground wiring 43, with respect to the imaginary center line of the substrate 10, passing the center thereof in the x-direction and extending in the y-direction. Accordingly, the second ground wiring 46 includes an outer wiring section 46d and an inner wiring section 46e. The outer wiring section 46d corresponds to the outer wiring section 43d, and the inner wiring section 46e corresponds to the inner wiring section 43e.

On the outer wiring section 46d, the second ground conductor 56 is located. The outer wiring section 46d has the same width as the length of the top face 50A of the second ground conductor 56 in the y-direction. Here, when the difference between the width of the outer wiring section 46d and the length of the top face 50A of the second ground conductor 56 in the y-direction is, for example, within 5% of the length of the top face 50A of the second ground conductor 56 in the y-direction, the width of the outer wiring section 46d may be regarded as being equal to the length of the top face 50A of the second ground conductor 56 in the y-direction. With the mentioned configuration, the same advantageous effects as (1-1) to (1-8), (1-11), and (1-15) from the first embodiment can be attained.

In the second example, as shown in FIG. 30, the respective shapes viewed in the z-direction, of the first power wirings 41A and 41B, the first output wirings 42A and 428, the second power wirings 44A and 44B, and the second output wirings 45A and 45B are different from those of the first power wirings 41A and 41B, the first output wirings 42A and 42B, the second power wirings 44A and 44B, and the second output wirings 45A and 45B of the first embodiment.

The first power wiring 41A is different from the first power wiring 41A of the first embodiment, in being without the connecting wiring section 41c, in the position of the narrow wiring section 41b with respect to the wide wiring section 41a in the y-direction, and in the width of the wide wiring section 41a. To be more detailed, the narrow wiring section 41b extends from the wide wiring section 41a in the x-direction, toward the center of the substrate 10. As viewed in the x-direction, the narrow wiring section 41b overlaps with the wide wiring section 41a. The narrow wiring section 41b is slightly shifted in the y-direction toward the first output wiring 42A, with respect to the wide wiring section 41a. The wide wiring section 41a is wider than the wide wiring section 41a of the first power wiring 41A of the first embodiment. In the illustrated example, the width of the wide wiring section 41a is approximately 150% of the length of the top face 50A of the first power conductor 51A in the y-direction. The first power conductor 51A is located in the region of the wide wiring section 41a on the side of the substrate side face 15 (opposite side of the first output wiring 42A) in the y-direction. The wide wiring section 41a includes a sloped section 41g, formed in the vicinity of the narrow wiring section 41b in the x-direction. The sloped section 41g is formed in the wide wiring section 41a at the position on the side of the substrate side face 15 (opposite side of the first output wiring 42A) in the y-direction, and obliquely extends so as to be closer to the first output wiring 42A (substrate side face 16), toward the narrow wiring section 41b in the x-direction.

The narrow wiring section 41b includes a widened section 41f, where the width of the narrow wiring section 41b is increased. The widened section 41f protrudes from the narrow wiring section 41b in the y-direction, to the opposite side of the first output wiring 42A. The widened section 41f has a trapezoidal shape, as viewed in the z-direction.

The first power wiring 41B is different from the first power wiring 41B of the first embodiment, in the position of the narrow wiring section 41b with respect to the wide wiring section 41a in the y-direction, and in the width of the wide wiring section 41a. To be more detailed, the narrow wiring section 41b is located so as to overlap with the wide wiring section 41a, as viewed in the x-direction. The narrow wiring section 41b is slightly shifted in the y-direction toward the first output wiring 42B, with respect to the wide wiring section 41a. The wide wiring section 41a is wider than the wide wiring section 41a of the first power wiring 41B of the first embodiment. In the illustrated example, the width of the wide wiring section 41a is approximately 150% of the length of the top face 50A of the first power conductor 51B in the y-direction. The first power conductor 51B is located in the region of the wide wiring section 41a on the side of the substrate side face 16 (opposite side of the first output wiring 42B) in the y-direction. The wide wiring section 41a includes the sloped section 41g, formed in the vicinity of the narrow wiring section 41b in the x-direction. The sloped section 41g is formed in the wide wiring section 41a at the position on the side of the substrate side face 16 (opposite side of the first output wiring 42B) in the y-direction, and obliquely extends so as to be closer to the first output wiring 42B (substrate side face 15), toward the narrow wiring section 41b in the x-direction.

The narrow wiring section 41b includes the widened section 41f, like the narrow wiring section 41b of the first power wiring 41A. The widened section 41f protrudes from the narrow wiring section 41b in the y-direction, to the opposite side of the first output wiring 428. The widened section 41f has a trapezoidal shape, as viewed in the z-direction.

The first output wiring 42A is different from the first output wiring 42A of the first embodiment, in the shape of the wide wiring section 42a. The wide wiring section 42a of the first output wiring 42A shown in FIG. 30 is narrower than the wide wiring section 42a of the first output wiring 42A of the first embodiment. The wide wiring section 42a of the first output wiring 42A is wider than the length of the top face 50A of the first output conductor 52A in the y-direction, but narrower than 150% of the length of the top face 50A of the first output conductor 52A in the y-direction. The wide wiring section 42a is slightly wider than the narrow wiring section 42b.

The first output wiring 420 is different from the first output wiring 42B of the first embodiment, in the shape of the wide wiring section 42a. The wide wiring section 42a of the first output wiring 42B shown in FIG. 30 is narrower than the wide wiring section 42a of the first output wiring 42B of the first embodiment. The wide wiring section 42a of the first output wiring 428 is wider than the length of the top face 50A of the first output conductor 52B in the y-direction, but narrower than 150% of the length of the top face 50A of the first output conductor 52B in the y-direction. The wide wiring section 42a is slightly wider than the narrow wiring section 42b.

The shape of the second power wirings 44A and 44B viewed in the z-direction is symmetrical to that of the first power wirings 41A and 41B, with respect to the imaginary center line of the substrate 10, passing the center thereof in the x-direction and extending in the y-direction. Accordingly, the second power wirings 44A and 44B each include a sloped section 44g formed in the wide wiring section 44a, and a widened section 44f formed in the narrow wiring section 44b.

The sloped section 44g of the second power wiring 44A is formed in the wide wiring section 44a at the position on the side of the substrate side face 15 (opposite side of the second output wiring 45A) in the y-direction, and obliquely extends so as to be closer to the second output wiring 45A (substrate side face 16), toward the narrow wiring section 44b in the x-direction. The widened section 44f of the second power wiring 44A protrudes from the narrow wiring section 44b, to the opposite side of the second output wiring 45A.

The sloped section 44g of the second power wiring 44B is formed in the wide wiring section 44a at the position on the side of the substrate side face 16 (opposite side of the second output wiring 45B) in the y-direction, and obliquely extends so as to be closer to the second output wiring 45B (substrate side face 15), toward the narrow wiring section 44b in the x-direction. The widened section 44f of the second power wiring 44B protrudes from the narrow wiring section 44b, to the opposite side of the second output wiring 45B.

The shape of the second output wirings 45A and 45B viewed in the z-direction is symmetrical to that of the first output wirings 42A and 42B, with respect to the imaginary center line of the substrate 10, passing the center thereof in the x-direction and extending in the y-direction. The wide wiring section 45a of the second output wiring 45A has the same width as the wide wiring section 42a of the first output wiring 42A, and the wide wiring section 45a of the second output wiring 45B has the same width as the wide wiring section 42a of the first output wiring 42B.

The mentioned configuration provides the following advantageous effects, in addition to (1-1) to (1-8), (1-11), and (1-15) from the first embodiment. The wide wiring section 41a of each of the first power wirings 41A and 41B includes the sloped section 41g, formed in the vicinity of the narrow wiring section 41b. Such a configuration suppresses a reduction in area of the region between the wide wiring section 41a and the narrow wiring section 41b, thereby reducing the electrical resistance of the first power wirings 41A and 41B. Likewise, the wide wiring section 44a of each of the second power wirings 44A and 44B includes the sloped section 41g, formed in the vicinity of the narrow wiring section 44b. Such a configuration reduces the electrical resistance of the second power wirings 44A and 44B, as in the case of the first power wirings 41A and 41B.

In addition, the narrow wiring section 41b of each of the first power wirings 41A and 41B includes the widened section 41f, and the narrow wiring section 44b of each of the second power wirings 44A and 44B includes the widened section 44f. Therefore, the electrical resistance of the first power wirings 41A and 41B and the second power wirings 44A and 44B can be reduced.

In the variation shown in FIG. 30, the element electrode 60a of the semiconductor element 60 may be bonded to the widened section 41f of the first power wirings 41A and 41B. Likewise, the element electrode 60a may be bonded to the widened section 44f of the second power wirings 44A and 44B. Further, the plurality of wirings 40X of the semiconductor device 1B according to the second embodiment may also be made narrower, like the plurality of wirings 40 shown in FIG. 29 and FIG. 30.

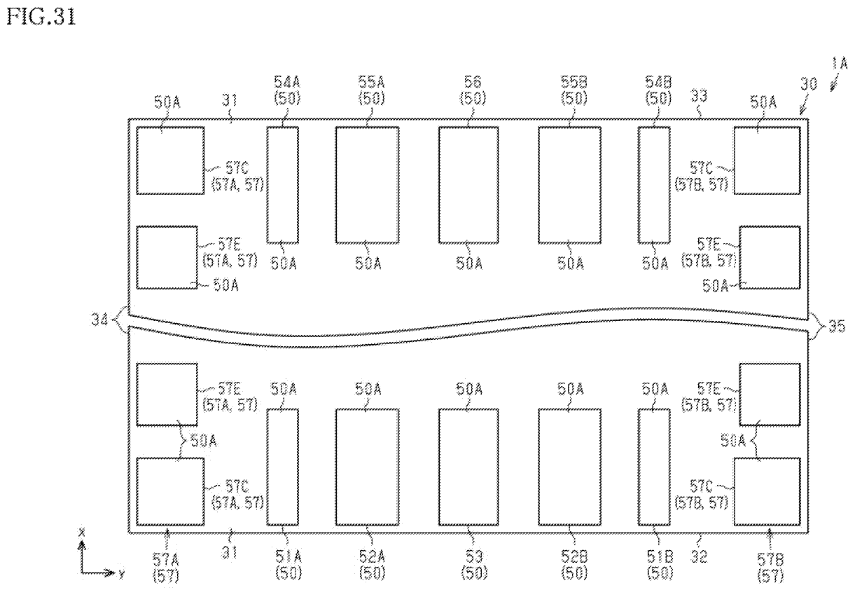

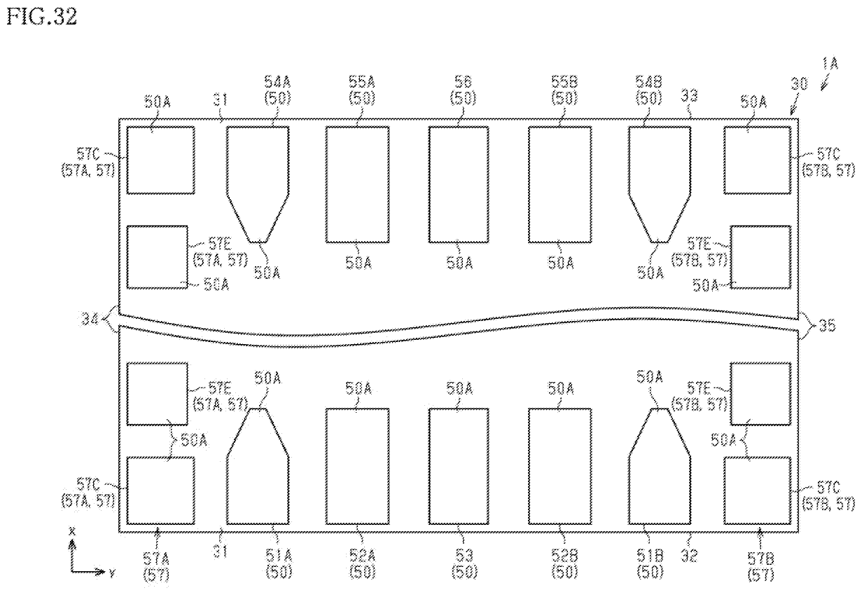

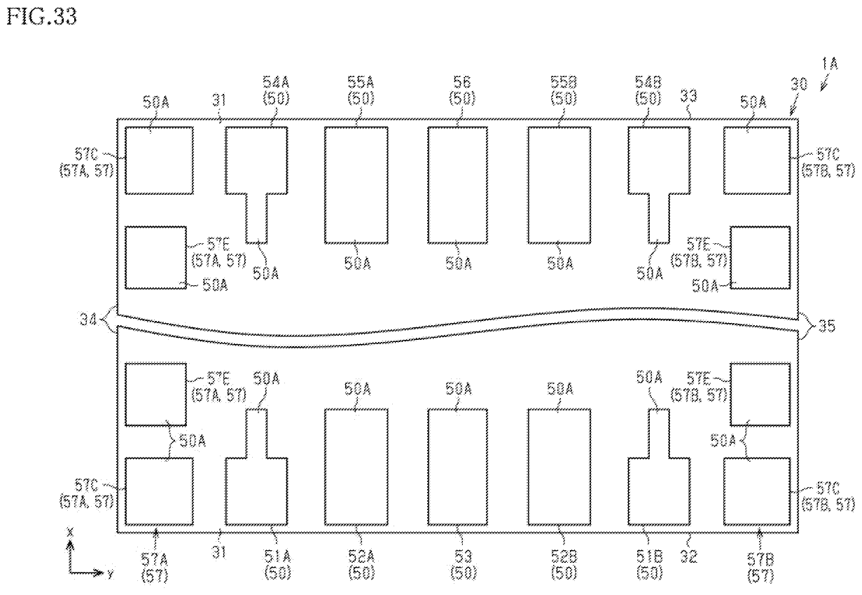

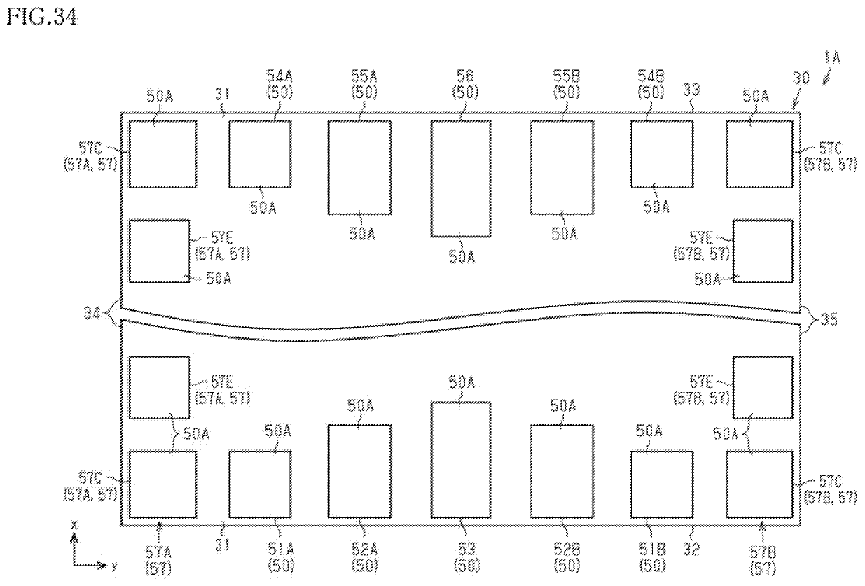

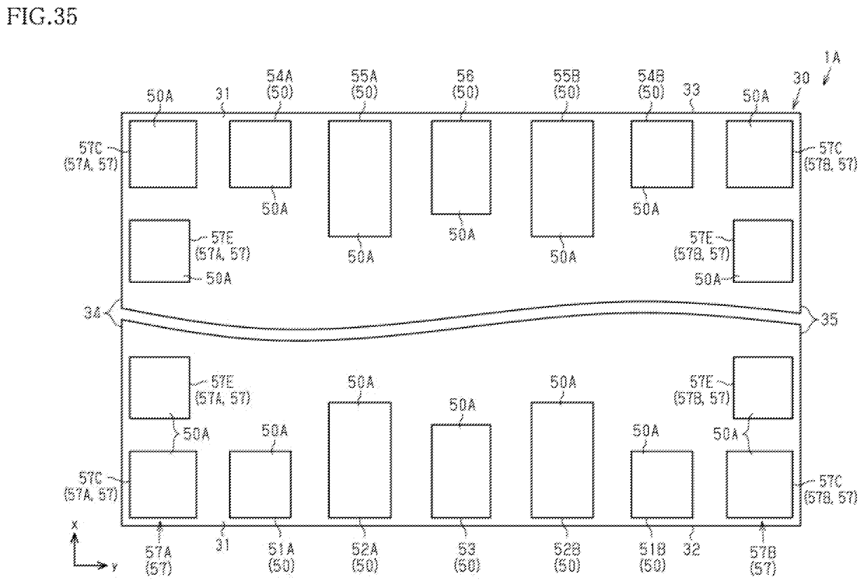

In the first embodiment, the respective top faces 50A of the first power conductors 51A and 51B, the first output conductors 52A and 52B, the first ground conductor 53, the second power conductors 54A and 54B, the second output conductors 55A and 55B, and the second ground conductor 56, which are exposed from the sealing resin 30 in the z-direction, may each be formed in a different shape as desired. For example, the shape of those top faces 50A may be modified as a first example shown in FIG. 31, a second example shown in FIG. 32, a third example shown in FIG. 33, a fourth example shown in FIG. 34, or a fifth example shown in FIG. 35. In FIG. 31 to FIG. 35, the plurality of terminals 20 are omitted for the sake of clarity.

In the first example, as shown in FIG. 31, the top face 50A of each of the first power conductors 51A and 51B has the same length in the x-direction, as the top face 50A of the first output conductors 52A and 52B, and the top face 50A of the first ground conductor 53. On the other hand, the top face 50A of each of the first power conductors 51A and 51B is shorter in the y-direction, than the top face 50A of the first output conductors 52A and 52B, and the top face 50A of the first ground conductor 53. Accordingly, the top face 50A of each of the first power conductors 51A and 51B is smaller in area, than the top face 50A of the first output conductors 52A and 523, and the top face 50A of the first ground conductor 53.

Though not shown, the first power conductors 51A and 51B have the same thickness as the first output conductors 52A and 52B, and the first ground conductor 53. Accordingly, the first power conductors 51A and 51B are smaller in volume, than the first output conductors 52A and 52B and the first ground conductor 53.

In addition, as shown in FIG. 31, the top face 50A of each of the second power conductors 54A and 54B has the same length in the x-direction, as the top face 50A of the second output conductors 55A and 55B, and the top face 50A of the second ground conductor 56. On the other hand, the top face 50A of each of the second power conductors 54A and 54B is shorter in the y-direction, than the top face 50A of the second output conductors 55A and 55B, and the top face 50A of the second ground conductor 56. Accordingly, the top face 50A of each of the second power conductors 54A and 54B is smaller in area, than the top face 50A of the second output conductors 55A and 55B, and the top face 50A of the second ground conductor 56.

Though not shown, the second power conductors 54A and 54B have the same thickness as the second output conductors 55A and 55B, and the second ground conductor 56. Accordingly, the second power conductors 54A and 54B are smaller in volume, than the second output conductors 55A and 55B and the second ground conductor 56.

In the second example, as shown in FIG. 32, the top face 50A of each of the first power conductors 51A and 51B has the same length in the x-direction, as the top face 50A of the first output conductors 52A and 52B, and the top face 50A of the first ground conductor 53. On the other hand, a portion of the top face 50A of each of the first power conductors 51A and 51B, on the side of the center of the substrate 10 in the x-direction, is formed in a tapered shape so as to be narrower toward the center of the substrate 10 in the x-direction. Accordingly, the top face 50A of each of the first power conductors 51A and 51B is smaller in area, than the top face 50A of the first output conductors 52A and 52B, and the top face 50A of the first ground conductor 53.

Though not shown, the first power conductors 51A and 51B have the same thickness as the first output conductors 52A and 52B, and the first ground conductor 53. Accordingly, the first power conductors 51A and 51B are smaller in volume, than the first output conductors 52A and 52B and the first ground conductor 53.

In addition, as shown in FIG. 32, the top face 50A of each of the second power conductors 54A and 54B has the same length in the x-direction, as the top face 50A of the second output conductors 55A and 55B, and the top face 50A of the second ground conductor 56. On the other hand, a portion of the top face 50A of each of the second power conductors 54A and 54B, on the side of the center of the substrate 10 in the x-direction, is formed in a tapered shape so as to be narrower toward the center of the substrate 10 in the x-direction. Accordingly, the top face 50A of each of the second power conductors 54A and 54B is smaller in area than the top face 50A of the second output conductors 55A and 55B, and the top face 50A of the second ground conductor 56.

Though not shown, the second power conductors 54A and 54B have the same thickness as the second output conductors 55A and 55B, and the second ground conductor 56. Accordingly, the second power conductors 54A and 54B are smaller in volume than the second output conductors 55A and 55B and the second ground conductor 56. Therefore, the same advantageous effects as (1-1) and (1-2) from the first embodiment can be attained.

In the third example, as shown in FIG. 33, the top face 50A of each of the first power conductors 51A and 51B has the same length in the x-direction, as the top face 50A of the first output conductors 52A and 52B, and the top face 50A of the first ground conductor 53. On the other hand, a portion of the top face 50A of each of the first power conductors 51A and 51B, on the side of the center of the substrate 10 in the x-direction, is formed in a stepped shape, such that the length of the top face 50A in the y-direction is reduced. Accordingly, the top face 50A of each of the first power conductors 51A and 51B is smaller in area, than the top face 50A of the first output conductors 52A and 52B, and the top face 50A of the first ground conductor 53.

Though not shown, the first power conductors 51A and 51B have the same thickness as the first output conductors 52A and 52B, and the first ground conductor 53. Accordingly, the first power conductors 51A and 51B are smaller in volume, than the first output conductors 52A and 52B and the first ground conductor 53.

In addition, as shown in FIG. 33, the top face 50A of each of the second power conductors 54A and 54B has the same length in the x-direction, as the top face 50A of the second output conductors 55A and 55B, and the top face 50A of the second ground conductor 56. On the other hand, a portion of the top face 50A of each of the second power conductors 54A and 54B, on the side of the center of the substrate 10 in the x-direction, is formed in a stepped shape, such that the length of the top face 50A in the y-direction is reduced. Accordingly, the top face 50A of each of the second power conductors 54A and 55B is smaller in area than the top face 50A of the second output conductors 55A and 55B, and the top face 50A of the second ground conductor 56.

Though not shown, the second power conductors 54A and 54B have the same thickness as the second output conductors 55A and 55B, and the second ground conductor 56. Accordingly, the second power conductors 54A and 54B are smaller in volume than the second output conductors 55A and 55B and the second ground conductor 56. Therefore, the same advantageous effects as (1-1) from the first embodiment can be attained.

Here, in the first to the third examples shown in FIG. 31 to FIG. 33, the length of the top face 50A of the first power conductors 51A and 51B in the x-direction may be changed as desired. For example, the top face 50A of the first power conductors 51A and 51B may be shorter in the x-direction, than the top face 50A of the first output conductors 52A and 52B and the top face 50A of the first ground conductor 53. In addition, provided that the top face 50A of the first power conductors 51A and 51B becomes smaller in area than the top face 50A of the first output conductors 52A and 52B and the top face 50A of the first ground conductor 53, the top face 50A of the first power conductors 51A and 51B may be longer in the x-direction, than the top face 50A of the first output conductors 52A and 52B and the top face 50A of the first ground conductor 53.

Likewise, the length of the top face 50A of the second power conductors 54A and 54B in the x-direction may be changed as desired. For example, the top face 50A of the second power conductors 54A and 54B may be shorter in the x-direction, than the top face 50A of the second output conductors 55A and 55B and the top face 50A of the second ground conductor 56. In addition, provided that the top face 50A of the second power conductors 54A and 54B becomes smaller in area than the top face 50A of the second output conductors 55A and 55B and the top face 50A of the second ground conductor 56, the top face 50A of the second power conductors 54A and 54B may be longer in the x-direction, than the top face 50A of the second output conductors 55A and 55B and the top face 50A of the second ground conductor 56.

In the fourth example, as shown in FIG. 34, the top face 50A of each of the first power conductors 51A and 51B is shorter in the x-direction, than the top face 50A of the first ground conductor 53. In the illustrated example, the top face 50A of each of the first output conductors 52A and 528 is longer in the x-direction, than the top face 50A of the first power conductors 51A and 51B. In other words, the top face 50A of the first power conductors 51A and 51B is shorter in the x-direction, than the top face 50A of the first output conductors 52A and 52B. Accordingly, the top face 50A of each of the first output conductors 52A and 52B is smaller in area than the top face 50A of the first ground conductor 53, and larger in area than the top face 50A of the first power conductors 51A and 51B. In other words, the top face 50A of the first power conductors 51A and 51B is smaller in area than the top face 50A of the first output conductors 52A and 52B, and the top face 50A of the first ground conductor 53.

Though not shown, the first output conductors 52A and 528 each have the same thickness as the first power conductors 51A and 51B, and the first ground conductor 53. Accordingly, the first output conductors 52A and 52B are smaller in volume than the first ground conductor 53, and larger in volume than the first power conductors 51A and 51B. In other words, the first power conductors 51A and 51B are each smaller in volume than the first output conductors 52A and 52B and the first ground conductor 53.

In addition, as shown in FIG. 34, the top face 50A of each of the second output conductors 55A and 55B is shorter in the x-direction, than the top face 50A of the second ground conductor 56. In the illustrated example, the top face 50A of each of the second output conductors 55A and 55B is longer in the x-direction, than the top face 50A of the second power conductors 54A and 54B. In other words, the top face 50A of the second power conductors 54A and 54B is shorter in the x-direction, than the top face 50A of the second output conductors 55A and 55B. Accordingly, the top face 50A of each of the second output conductors 55A and 55B is smaller in area than the top face 50A of the second ground conductor 56, and larger in area than the top face 50A of the second power conductors 54A and 54B. In other words, the top face 50A of the second power conductors 54A and 54B is smaller in area than the top face 50A of the second output conductors 55A and 55B, and the top face 50A of the second ground conductor 56.

Though not shown, the second output conductors 55A and 55B each have the same thickness as the second power conductors 54A and 54B, and the second ground conductor 56. Accordingly, the second output conductors 55A and 55B are smaller in volume than the first ground conductor 53, and larger in volume than the second power conductors 54A and 54B. In other words, the second power conductors 54A and 54B are each smaller in volume than the second output conductors 55A and 55B and the second ground conductor 56. Therefore, the same advantageous effects as (1-1) and (1-2) from the first embodiment can be attained.

In the fifth example, as shown in FIG. 35, the top face 50A of the first ground conductor 53 is shorter in the x-direction, than the top face 50A of the first output conductors 52A and 523. In the illustrated example, the top face 50A of the first ground conductor 53 is longer in the x-direction, than the top face 50A of the first power conductors 51A and 51B. Accordingly, the top face 50A of the first ground conductor 53 is smaller in area than the top face 50A of the first output conductors 52A and 52B, and larger in area than the top face 50A of the first power conductors 51A and 51D. In other words, the top face 50A of the first power conductors 51A and 51B is smaller in area than the top face 50A of the first output conductors 52A and 52B, and the top face 50A of the first ground conductor 53.

Though not shown, the first ground conductor 53 has the same thickness as the first power conductors 51A and 51B, and the first output conductors 52A and 52B. Accordingly, the first ground conductor 53 is smaller in volume than the first output conductors 52A and 528, and larger in volume than the first power conductors 51A and 513. In other words, the first power conductors 51A and 51B are smaller in volume than the first output conductors 52A and 52B and the first ground conductor 53.

In addition, as shown in FIG. 35, the top face 50A of the second ground conductor 56 is shorter in the x-direction, than the top face 50A of the second output conductors 55A and 55B. In the illustrated example, the top face 50A of the second ground conductor 56 is longer in the x-direction, than the top face 50A of the second power conductors 54A and 54B. Accordingly, the top face 50A of the second ground conductor 56 is smaller in area than the top face 50A of the second output conductors 55A and 55B, and larger in area than the top face 50A of the second power conductors 54A and 54B. In other words, the top face 50A of the second power conductors 54A and 54B is smaller in area than the top face 50A of the second output conductors 55A and 55B, and the top face 50A of the second ground conductor 56.

Though not shown, the second ground conductor 56 has the same thickness as the second power conductors 54A and 54B, and the second output conductors 55A and 55B. Accordingly, the second ground conductor 56 is smaller in volume than the second output conductors 55A and 55B, and larger in volume than the second power conductors 54A and 54B. In other words, the second power conductors 54A and 54B are smaller in volume than the second output conductors 55A and 55B and the second ground conductor 56. Therefore, the same advantageous effects as (1-1) and (1-2) from the first embodiment can be attained. Here, the modifications illustrated in FIG. 31 to FIG. 35 may be applied to the plurality of conductors 50X of the semiconductor device 10 according to the second embodiment.

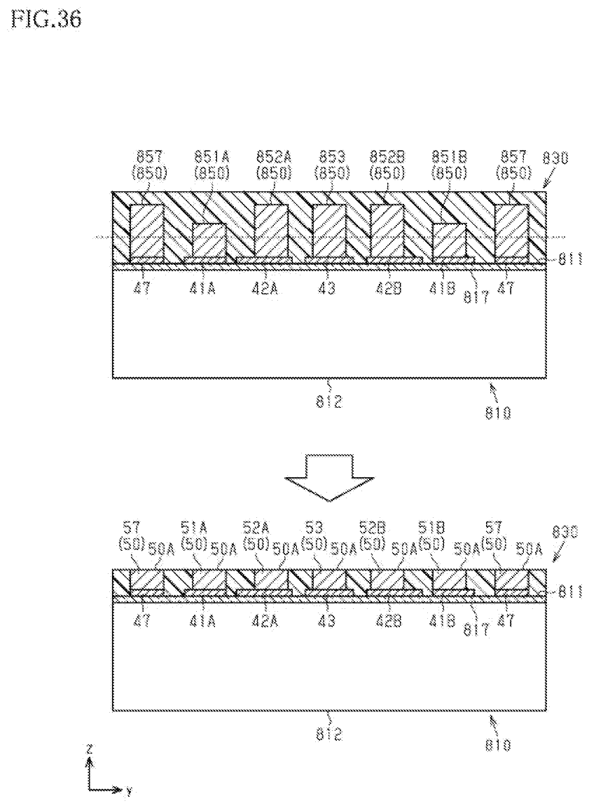

In the manufacturing method of the semiconductor devices 1A and 1B according to the respective embodiments, the plurality of conductors 850 are formed in the same thickness as one another. However, a different process may be adopted. For example, as shown in FIG. 36, among the plurality of conductors 850, the first power conductors 851A and 851B may be thinner than the first output conductors 852A and 852B and the first ground conductor 853. In this case, in the process of removing the resin layer 830 in the thickness direction, the resin layer 830 is removed so as to make the thickness of the first power conductors 851A and 851B, the first output conductors 852A and 852B, and the first ground conductor 853 the same as one another.

With such an arrangement, the same advantageous effects as (1-1) from the first embodiment can be attained. Though not shown, the second power conductor may be thinner than the second output conductor and the second ground conductor.

Although the plurality of conductors 50 are exposed from the sealing resin 30 in the z-direction in the foregoing embodiments, a different configuration may be adopted. For example, the plurality of conductors 50 may be exposed in the z-direction, from the substrate supporting the semiconductor element 60.

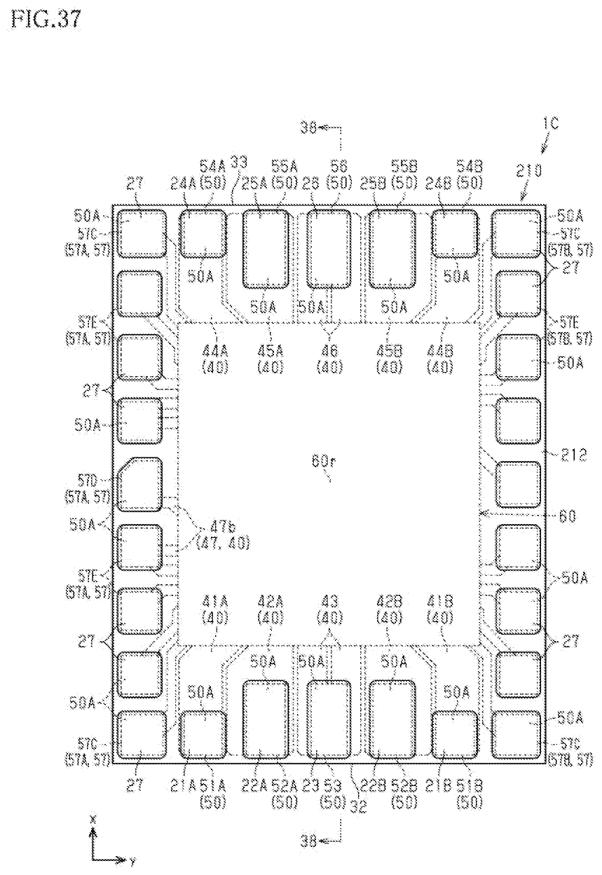

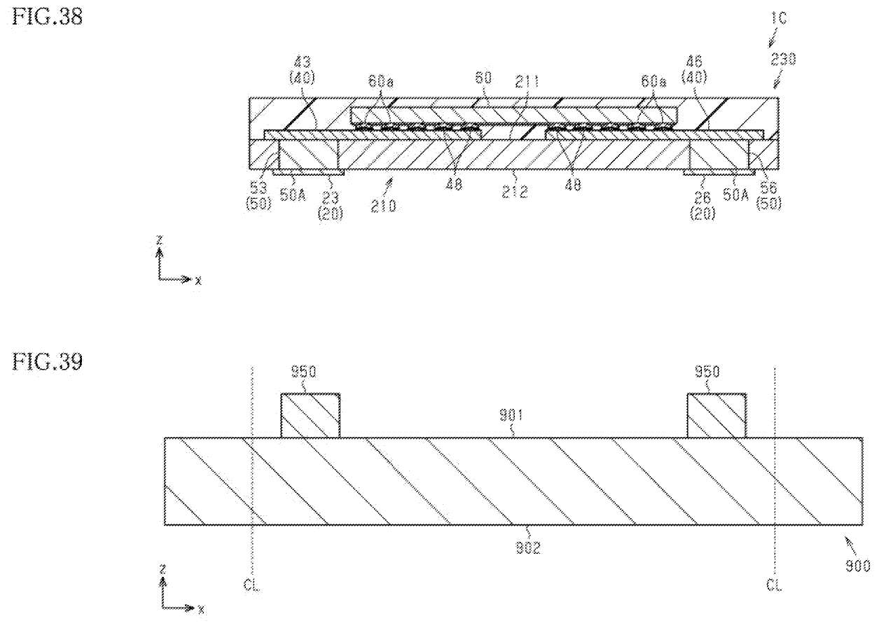

In an example, as shown in FIG. 37 and FIG. 38, a semiconductor device 1C includes a substrate 210, the plurality of terminals 20, a sealing resin 230, the plurality of wirings 40, the plurality of conductors 50, and the semiconductor element 60.

The substrate 210 is a support member that serves as the base for the semiconductor device 1C, and formed of an electrically insulative material. Examples of such a material include a synthetic resin predominantly composed of an epoxy resin, ceramics, and glass. In the illustrated example, the substrate 210 is formed of a synthetic resin predominantly composed of an epoxy resin. The substrate 210 includes a substrate obverse face 211 and a substrate reverse face 212, oriented to opposite sides to each other in the z-direction. Here, the z-direction may also be referred to as thickness direction of the substrate 210. As viewed in the z-direction, the substrate 10 has a rectangular shape with the long sides extending in the x-direction, and the short sides extending in the y-direction.

The plurality of wirings 40 are formed on the substrate obverse face 211. The plurality of wirings 40 include, as in the first embodiment, the first power wirings 41A and 41B, the first output wirings 42A and 42B, the first ground wiring 43, the second power wirings 44A and 44B, the second output wirings 45A and 45B, the second ground wiring 46, and the plurality of control wirings 47. The respective shapes of the plurality of wirings 40 viewed in the z-direction are the same as those of the plurality of wirings 40 of the first embodiment. The plurality of wirings 40 each extend, as in the first embodiment, from inside the semiconductor element 60 to outside of the semiconductor element 60.

As shown in FIG. 38, the semiconductor element 60 is located on the opposite side of the substrate 210 with respect to the plurality of wirings 40 in the z-direction, and bonded to the plurality of wirings 40 via the solder layer 48.

The plurality of conductors 50 are located on the opposite side of the semiconductor element 60 with respect to the plurality of wirings 40, in the z-direction. The plurality of conductors 50 are formed so as to penetrate through the substrate 210 in the z-direction. Accordingly, the plurality of conductors 50 are exposed in each of the substrate obverse face 211 and the substrate reverse face 212. The plurality of conductors 50 exposed in the substrate obverse face 211 are respectively bonded to the plurality of wirings 40. In other words, the plurality of conductors 50 are electrically connected to the respective wirings 40. As shown in FIG. 37, as viewed in the z-direction, the plurality of conductors 50 are located in the region outside the semiconductor element 60, so as to surround the semiconductor element 60.

The plurality of conductors 50 include, as in the first embodiment, the first power conductors 51A and 51B, the first output conductors 52A and 52B, the first ground conductor 53, the second power conductors 54A and 54B, the second output conductors 55A and 55B, the second ground conductor 56, and the plurality of control conductor 57.

As shown in FIG. 37, the arrangement of the plurality of conductors 50 and the plurality of terminals 20, viewed in the z-direction from the substrate reverse face 212, is similar to that of the plurality of conductors 50 and the plurality of terminals 20 according to the first embodiment, for example shown in FIG. 3. The plurality of conductors 50 each include the top face 50A, exposed from the substrate reverse face 212.

To be more detailed, the top face 50A of each of the first power conductors 51A and 51B is shorter in the x-direction, than the top face 50A of the first output conductors 52A and 52B and the top face 50A of the first ground conductor 53. The top face 50A of each of the first power conductors 51A and 51B has the same length in the y-direction, as the top face 50A of the first output conductors 52A and 52B and the top face 50A of the first ground conductor 53. Accordingly, the top face 50A of each of the first power conductors 51A and 51B is smaller in area, than the top face 50A of the first output conductors 52A and 52B and the top face 50A of the first ground conductor 53. Here, when the difference in length in the y-direction between the top face 50A of the first power conductors 51A and 51B and the top face 50A of the first output conductors 52A and 52B is, for example, within 5% of the length in the y-direction of the top face 50A of the first output conductors 52A and 52B, the length in the y-direction of the top face 50A of the first power conductors 51A and 51B may be regarded as being equal to that of the top face 50A of the first output conductors 52A and 52B. Likewise, when the difference in length in the y-direction between the top face 50A of the first power conductors 51A and 51B and the top face 50A of the first ground conductor 53 is, for example, within 5% of the length in the y-direction of the top face 50A of the first ground conductor 53, the length in the y-direction of the top face 50A of the first power conductors 51A and 51B may be regarded as being equal to that of the top face 50A of the first ground conductor 53.

In addition, since the first power conductors 51A and 51B, the first output conductors 52A and 52B, and the first ground conductor 53 have the same thickness as one another, the first power conductors 51A and 51B are smaller in volume than the first output conductors 52A and 52B and the first ground conductor 53.

Likewise, the top face 50A of each of the second power conductors 54A and 54B is shorter in the x-direction, than the top face 50A of the second output conductors 55A and 55B and the top face 50A of the second ground conductor 56. The top face 50A of each of the second power conductors 54A and 54B has the same length in the y-direction, as the top face 50A of the second output conductors 55A and 55B and the top face 50A of the second ground conductor 56. Accordingly, the top face 50A of each of the second power conductors 54A and 54B is smaller in area, than the top face 50A of the second output conductors 55A and 55B and the top face 50A of the second ground conductor 56. Here, when the difference in length in the y-direction between the top face 50A of the second power conductors 54A and 54B and the top face 50A of the second output conductors 55A and 55B is, for example, within 5% of the length in the y-direction of the top face 50A of the second output conductors 55A and 55B, the length in the y-direction of the top face 50A of the second power conductors 54A and 54B may be regarded as being equal to that of the top face 50A of the second output conductors 55A and 55B. Likewise, when the difference in length in the y-direction between the top face 50A of the second power conductors 54A and 54B and the top face 50A of the second ground conductor 56 is, for example, within 5% of the length in the y-direction of the top face 50A of the second ground conductor 56, the length in the y-direction of the top face 50A of the second power conductors 54A and 54B may be regarded as being equal to that of the top face 50A of the second ground conductor 56.

In addition, since the second power conductors 54A and 54B, the second output conductors 55A and 55B, and the second ground conductor 56 have the same thickness as one another, the second power conductors 54A and 54B are smaller in volume than the second output conductors 55A and 559 and the second ground conductor 56.

Hereunder, a manufacturing method of the semiconductor device 1C will be described, with reference to FIG. 39 to FIG. 46. Referring to FIG. 39, the manufacturing method of the semiconductor device 1C includes a process of preparing a support substrate 900. The support substrate 900 is, for example, formed of an intrinsic monocrystalline material of Si. The support substrate 900 includes an upper face 901 and a lower face 902 oriented to opposite sides to each other in the z-direction.

Referring to FIG. 39, the manufacturing method of the semiconductor device 1C includes a process of forming a terminal pillar 950. To be more detailed, a plurality of terminal pillars 950 are formed on the upper face 901 of the support substrate 900. The terminal pillars 950 are, for example, formed of Cu or a Cu-based alloy, and formed through an electrolytic plating process.

To be more detailed, the terminal pillars 950 are formed through a process of forming a seed layer, a process of forming a mask on the seed layer by photolithography, and a process of forming the terminal pillars 950 in contact with the seed layer. The seed layer is formed on the upper face 901 of the support substrate 900, for example by a sputtering method. Then the seed layer is covered with a photosensitive resist layer, and the resist layer is exposed and developed, to form a mask having openings. Then the electrolytic plating is performed using the seed layer as the conduction path, to thereby precipitate the plated metal on the surface of the seed layer exposed from the mask, thus forming the terminal pillars 950. After the formation of the terminal pillars 950, the mask is removed. Here, a Cu columnar material may be employed to form the terminal pillars 950. The plurality of terminal pillars 950 have the same thickness as one another.

Though not shown, the plurality of terminal pillars 950 are to be formed into the plurality of conductors 50. Accordingly, the terminal pillars 950 to be formed into the first power conductors 51A and 51B are smaller in volume, than the terminal pillars 950 to be formed into the first output conductors 52A and 52B, and the terminal pillars 950 to be formed into the first ground conductor 53. To be more detailed, as viewed in the z-direction, the plurality of terminal pillars 950 to be formed into the first power conductors 51A and 51B, the first output conductors 52A and 528, and the first ground conductor 53 each have a rectangular shape with the long sides extending in the x-direction, and short sides extending in the y-direction. The terminal pillars 950 to be formed into the first power conductors 51A and 51B are shorter in the x-direction, than the terminal pillars 950 to be formed into the first output conductors 52A and 520, and the terminal pillars 950 to be formed into the first ground conductor 53. The terminal pillars 950 to be formed into the first power conductors 51A and 51B have the same length in the y-direction, as the terminal pillars 950 to be formed into the first output conductors 52A and 52B, and the terminal pillars 950 to be formed into the first ground conductor 53.

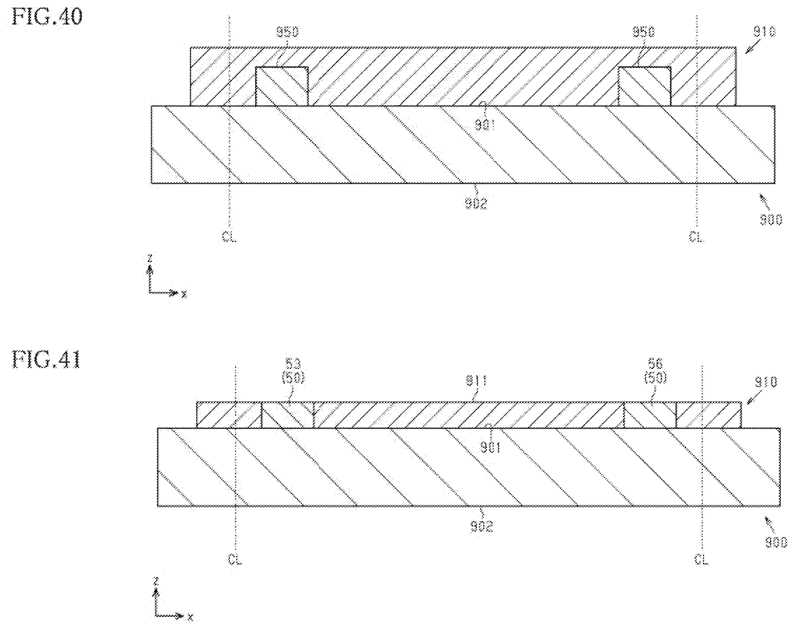

Referring to FIG. 40, the manufacturing method of the semiconductor device 1C includes a process of forming a base material 910. The base material 910 is formed so as to cover the upper face of the terminal pillar 950. To form the base material 910, the material to form the substrate 210 shown in FIG. 38 may be employed. In the illustrated example, a synthetic resin material predominantly composed of an epoxy resin is employed as the material for the base material 910.

Referring to FIG. 41, a part of each of the base material 910 and the terminal pillar 950 in the z-direction is ground, to form the plurality of conductors 50 exposed in the upper face 911 of the base material 910. The base material 910 is ground so as to make the thickness of the base material 910 equal to that of the substrate 210.

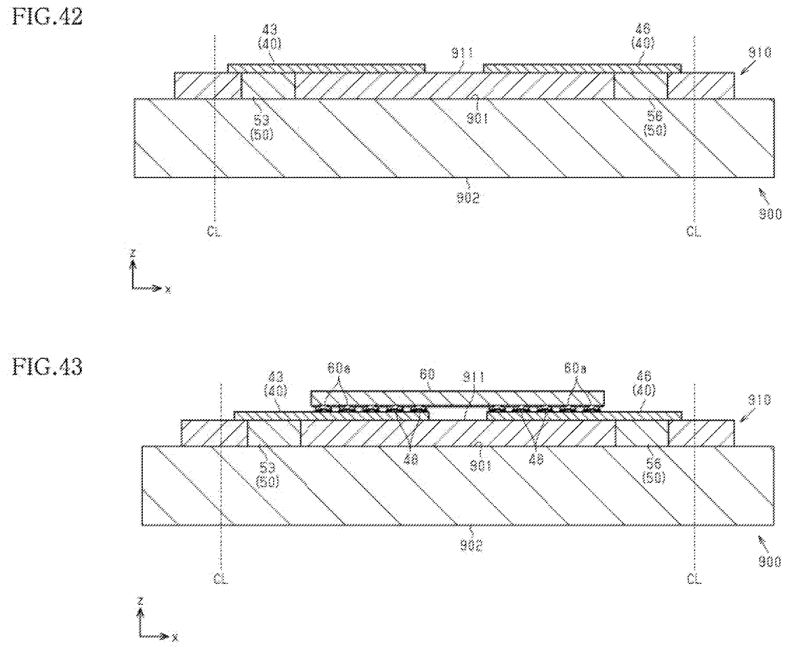

Referring to FIG. 42, the plurality of wirings 40 are formed on the upper face 911 of the base material 910, and the upper face of the plurality of conductors 50 exposed in the upper face 911. The plurality of wirings 40 are formed on the respective conductors 50. To be more detailed, the plurality of wirings 40 are formed through a process of forming a metal layer, a process of forming a mask on the metal layer by photolithography, and a process of forming a conductive layer in contact with the metal layer.

First, the metal layer is formed, for example by a sputtering method. For example, a Ti layer is formed on the upper face 911 of the base material 910 and the upper face of the plurality of conductors 50, and a Cu layer is formed in contact with the Ti layer. Then the metal layer is covered with a photosensitive resist layer, and the resist layer is exposed and developed, to form a mask having openings. Then the electrolytic plating is performed using the metal layer as the conduction path, to thereby precipitate the plated metal on the upper face of the metal layer exposed from the mask, thus to be engaged with the conductive layer. The plurality of wirings 40 can be formed through the mentioned process. After the formation of the plurality of wirings 40, the mask is removed.

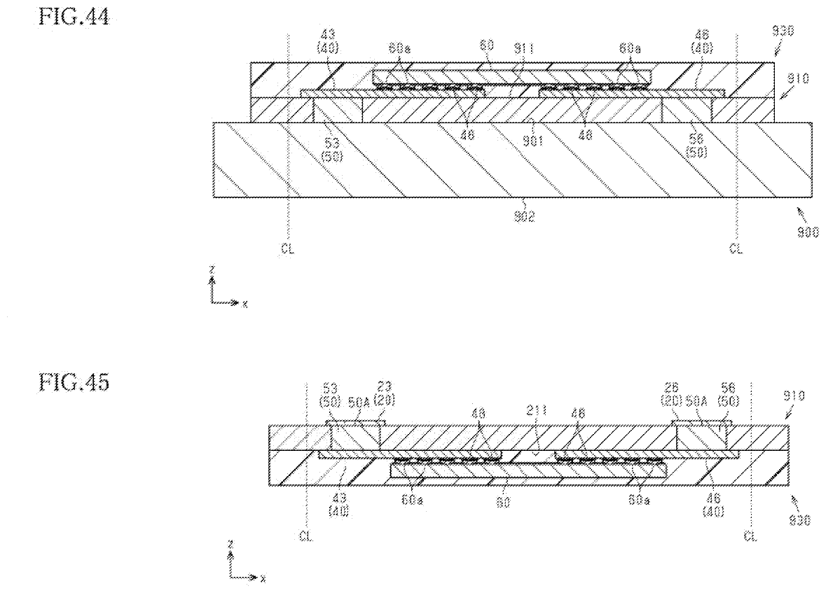

Referring to FIG. 43, the manufacturing method of the semiconductor device 1C includes a process of mounting the semiconductor element 60. The process of mounting the semiconductor element 60 is the same as the process of mounting the semiconductor element 60 according to the first embodiment.

Referring to FIG. 44, the manufacturing method of the semiconductor device 1C includes a process of forming a resin layer 930. The resin layer 930 is to be formed into the sealing resin 230 shown in FIG. 38. The resin layer 930 is, for example, formed of a synthetic resin predominantly composed of an epoxy resin. The resin layer 930 can be formed, for example, by a transfer molding method. Here, although one resin layer 930 is formed to cover one semiconductor element 60 in the illustrated example, the resin layer 930 may be formed so as to cover all of the semiconductor elements 60.

Referring to FIG. 45, the manufacturing method of the semiconductor device 1C includes a process of removing the support substrate 900 shown in FIG. 44. Here, FIG. 45 is turned upside down form FIG. 44. The support substrate 900 can be removed, for example by grinding.

Referring to FIG. 45, the manufacturing method of the semiconductor device 1C includes a process of forming the plurality of terminals 20. The plurality of terminals 20 are formed of plated metals. The plated metals, such as Ni, Pd, and Au may be precipitated in this order, for example through a non-electrolytic plating process, so that the plurality of terminals 20 are formed.

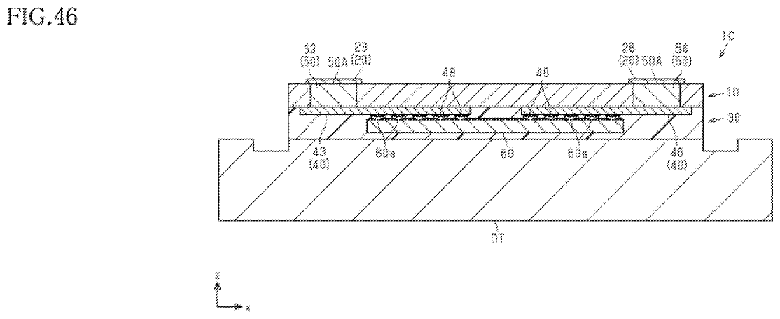

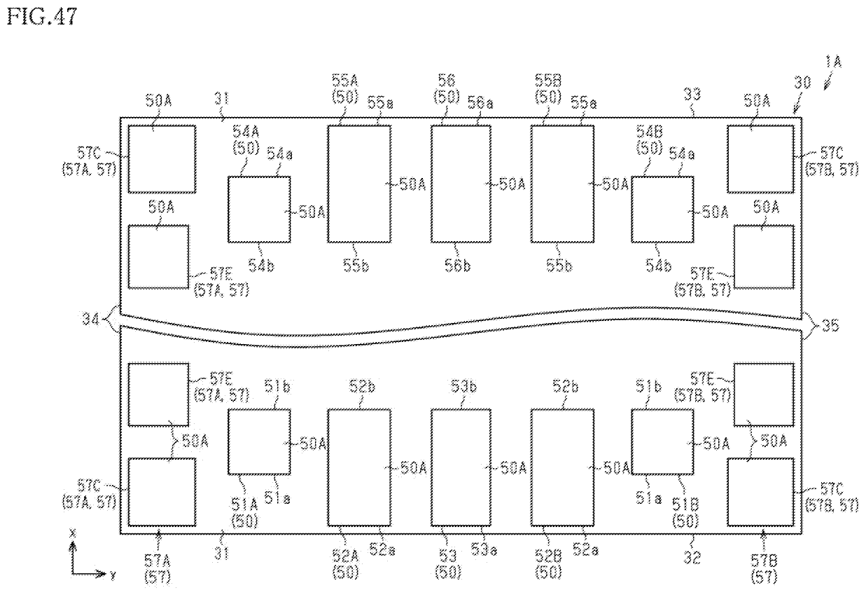

Referring to FIG. 46, the manufacturing method of the semiconductor device 1C includes a process of forming the individual pieces of the semiconductor device 1C. To be more detailed, a dicing tape DT is stuck to the lower face of the resin layer 930. Then the base material 910 and the resin layer 930 are cut in this order, for example by a dicing blade, along the cutting lines CL indicated by broken lines. Through the foregoing process, the semiconductor device 1C can be obtained.

Here, although the plurality of terminals 20, the plurality of wirings 40, and the plurality of conductors 50 of the semiconductor device 1C are configured in the same way as those of the first embodiment as shown in FIG. 37 and FIG. 38, the plurality of terminals 20, the plurality of wirings 40, and the plurality of conductors 50 may be formed in the same way as the plurality of terminals 20X, the plurality of wirings 40X, and the plurality of conductors 50X of the second embodiment. In other words, the semiconductor device 1C may include the first power wiring 41, the first output wiring 42, the first ground wiring 43, the second power wiring 44, the second output wiring 45, the second ground wiring 46, and the plurality of control wirings 47. The semiconductor device 1C may include the first power conductor 51, the first output conductor 52, the first ground conductor 53, the second power conductor 54, the second output conductor 55, the second ground conductor 56, and the plurality of control conductors 57. The semiconductor device 1C may include the first power terminal 21, the first output terminal 22, the first ground terminal 23, the second power terminal 24, the second output terminal 25, the second ground terminal 26, and the plurality of control terminals 27.

Although the first power conductors 51A and 510 are smaller in volume than the first output conductors 52A and 52B and the first ground conductor 53, in the first embodiment, a different configuration may be adopted. For example, the first output conductors 52A and 52B may be made smaller in volume than the first power conductors 51A and 51B and the first ground conductor 53, or the first ground conductor 53 may be made smaller in volume than the first power conductors 51A and 51B and the first output conductors 52A and 52B. The above also applies to the second power conductors 54A and 54B, the second output conductors 55A and 55, and the second ground conductor 56.

In addition, the type of the conductor to be made smaller in volume is not limited to one, but two types of the conductors may be made smaller in volume. For example, the first power conductors 51A and 51B and the first output conductors 52A and 52B may be made smaller in volume than the first ground conductor 53. The first power conductors 51A and 51B and the first ground conductor 53 may be made smaller in volume than the first output conductors 52A and 52B. The first output conductors 52A and 52B and the first ground conductor 53 may be made smaller in volume than the first power conductors 51A and 51B. The above also applies to the second power conductors 54A and 54B, the second output conductors 55A and 55B, and the second ground conductor 56. Further, the configuration in which the conductors are made smaller in volume may be applied to one of the configurations according to the foregoing embodiments and the variations thereof.

Although the same type of conductors are made smaller in volume in the first embodiment, such that the first power conductors 51A and 51B are smaller in volume than the first output conductors 52A and 528 and the first ground conductor 53, a different configuration may be adopted. For example, different types of conductors may be made smaller in volume. More specifically, one to four conductors, optionally selected out of the five conductors namely the first power conductors 51A and 51B, the first output conductors 52A and 52B, and the first ground conductor 53, may be made smaller in volume than the remaining conductors. For example, the first power conductor 51A and the first output conductor 52A may be made smaller in volume than the first power conductor 51B, the first output conductor 52B, and the first ground conductor 53. The above also applies to the second power conductors 54A and 54B, the second output conductors 55A and 55B, and the second ground conductor 56. Further, the configuration in which the conductors are made smaller in volume may be applied to one of the configurations according to the foregoing embodiments and the variations thereof.

Although the same type of conductors, located close to the substrate side face 13 and the substrate side face 14 respectively, are made smaller in volume in the first embodiment, such that the first power conductors 51A and 51B and the second power conductors 54A and 54B are each made smaller in volume, a different configuration may be adopted. Different types of conductors, out of those located close to the substrate side face 13 and close to the substrate side face 14, may be made smaller in volume. In other words, the type of the conductor made smaller in volume, out of the first power conductors 51A and 51B, the first output conductors 52A and 528, and the first ground conductor 53, and the type of the conductor made smaller in volume, out of the second power conductors 54A and 54B, the second output conductors 55A and 55B, and the second ground conductor 56, may be different from each other. For example, the first power conductors 51A and 51B may be made smaller in volume than the first output conductors 52A and 52B and the first ground conductor 53, and the second output conductors 55A and 55B may be smaller in volume than the second power conductors 54A and 54B and the second ground conductor 56. Here, the configuration in which the conductors are made smaller in volume may be applied to one of the configurations according to the foregoing embodiments and the variations thereof.

Although the first power conductor 51 is smaller in volume than the first output conductor 52 and the first ground conductor 53 in the second embodiment, a different configuration may be adopted. For example, the first output conductor 52 may be made smaller in volume than the first power conductor 51 and the first ground conductor 53, or the first ground conductor 53 may be made smaller in volume than the first power conductor 51 and the first output conductor 52.

The type of the conductor to be made smaller in volume is not limited to one, but two types of the conductors may be made smaller in volume. For example, the first power conductor 51 and the first output conductor 52 may be made smaller in volume than the first ground conductor 53. The first power conductor 51 and the first ground conductor 53 may be made smaller in volume than the first output conductor 52. The first output conductor 52 and the first ground conductor 53 may be made smaller in volume than the first power conductor 51. The above also applies to the second power conductor 54, the second output conductor 55, and the second ground conductor 56. Further, the configuration in which the conductors are made smaller in volume may be applied to one of the configurations according to the foregoing embodiments and the variations thereof.

Although the same type of conductors, located close to the substrate side face 13 and the substrate side face 14 respectively, are made smaller in volume in the first embodiment, such that the first power conductor 51 and the second power conductor 54 are each made smaller in volume, a different configuration may be adopted. Different types of conductors, out of those located close to the substrate side face 13 and close to the substrate side face 14, may be made smaller in volume. In other words, the type of the conductor made smaller in volume, out of the first power conductor 51, the first output conductor 52, and the first ground conductor 53, and the type of the conductor made smaller in volume, out of the second power conductor 54, the second output conductor 55, and the second ground conductor 56, may be different from each other. For example, the first power conductor 51 may be made smaller in volume than the first output conductor 52 and the first ground conductor 53, and the second output conductor 55 may be made smaller in volume than the second power conductor 54 and the second ground conductor 56. Here, the configuration in which the conductors are made smaller in volume may be applied to one of the configurations according to the foregoing embodiments and the variations thereof.

In the first embodiment, the arrangement pattern of the first power wirings 41A and 41B, the first output wirings 42A and 42B, and the first ground wiring 43 in the y-direction may be modified as desired. For example, the first power wirings 41A and 41B may be separately located on the respective sides of the first ground wiring 43 located at the center of the substrate 10 in the y-direction, the first output wiring 42A may be located on the opposite side of the first ground wiring 43 in the y-direction with respect to the first power wiring 41A, and the first output wiring 42B may be located on the opposite side of the first ground wiring 43 in the y-direction with respect to the first power wiring 41B. Because of such modification, the arrangement pattern of the first power conductors 51A and 51B, the first output conductors 52A and 52B, and the first ground conductor 53 in the y-direction is also modified.

Likewise, the arrangement pattern of the second power wirings 44A and 44B, the second output wirings 45A and 45B, and the second ground wiring 46 in the y-direction may be modified as desired. For example, the second power wirings 44A and 44B may be separately located on the respective sides of the second ground wiring 46 located at the center of the substrate 10 in the y-direction, the second output wiring 45A may be located on the opposite side of the second ground wiring 46 in the y-direction with respect to the second power wiring 44A, and the second output wiring 45B may be located on the opposite side of the second ground wiring 46 in the y-direction with respect to the second power wiring 44B. Because of such modification, the arrangement pattern of the second power conductors 54A and 54B, second output conductors 55A and 55B, and the second ground conductor 56 in the y-direction is also modified. Here, the arrangement pattern of the second power wirings 44A and 44B, the second output wirings 45A and 45B, and the second ground wiring 46 in the y-direction may be different from that of the first power wirings 41A and 41B, the first output wirings 42A and 428, and the first ground wiring 43.

In the foregoing embodiments, the control conductors 57 include the distal control conductors 57C, the central control conductor 57D, and the intermediate control conductors 57E, which are different in area of the top face 50A. However, a different configuration may be adopted. For example, the control conductors 57 may include the distal control conductors 57C and the intermediate control conductors 57E. In other words, the central control conductor 57D may be substituted with the intermediate control conductor 57E. Alternatively, the control conductors 57 may only include the intermediate control conductors 57E. In other words, the distal control conductors 57C and the central control conductor 57D may each be substituted with the intermediate control conductor 57E.

In the foregoing embodiments, the length in the x-direction and the y-direction, of the top face 50A of each of the four distal control conductors 57C may be changed as desired. For example, the top face 50A of the distal control conductor 57C may be longer or shorter in the x-direction, than the top face 50A of the first power conductors 51A and 51B and the top face 50A of the second power conductors 54A and 54B. The top face 50A of the distal control conductor 57C may have the same length in the y-direction, as the top face 50A of the first power conductors 51A and 51B and the top face 50A of the second power conductors 54A and 54B. Further, the top face 50A of the distal control conductor 57C may be shorter in the y-direction, than the length in the x-direction of the top face 50A of the first power conductors 51A and 51B, and the length in the x-direction of the top face 50A of the second power conductors 54A and 54B.

In the foregoing embodiments, the length in the x-direction and the y-direction, of the top face 50A of each of the plurality of intermediate control conductors 57E may be changed as desired. For example, the top face 50A of the intermediate control conductor 57E may have the same length in the x-direction, as the top face 50A of the first power conductors 51A and 51B, and the top face 50A of the second power conductors 54A and 54B. The top face 50A of the intermediate control conductor 57E may be longer in the x-direction, than the top face 50A of the first power conductors 51A and 51B, and the top face 50A of the second power conductors 54A and 54B. The top face 50A of the intermediate control conductor 578 may be longer or shorter in the y-direction, than the top face 50A of the first power conductors 51A and 51B, and the top face 50A of the second power conductors 54A and 54B.

In the foregoing embodiments, the length in the x-direction and the y-direction of the central control conductor 57D may be changed as desired. For example, the central control conductor 57D may have the same length in the x-direction, as the top face 50A of the first power conductors 51A and 51B, and the top face 50A of the second power conductors 54A and 54B. The top face 50A of the central control conductor 57D may be shorter in the x-direction, than the top face 50A of the first power conductors 51A and 51B, and the top face 50A of the second power conductors 54A and 54B. The top face 50A of the central control conductor 57D may be longer or shorter in the y-direction, than the top face 50A of the first power conductors 51A and 51B, and the top face 50A of the second power conductors 54A and 54B.

In the foregoing embodiments, at least one of the top face 50A of the first power conductors 51A and 51B and the top face 50A of the second power conductors 54A and 54B may have the same area as the top face 50A of the control conductor 57. Alternatively, at least one of the top face 50A of the first power conductors 51A and 51B and the top face 50A of the second power conductors 54A and 54B may have the same area as the top face 50A of the intermediate control conductor 57E, among the control conductors 57.

In the foregoing embodiments, at least one of the first power conductors 51A and 51B and the second power conductors 54A and 54B may have the same volume as the control conductor 57. Alternatively, at least one of the first power conductors 51A and 51B and the second power conductors 54A and 54B may have the same volume as the intermediate control conductor 578, among the control conductors 57.

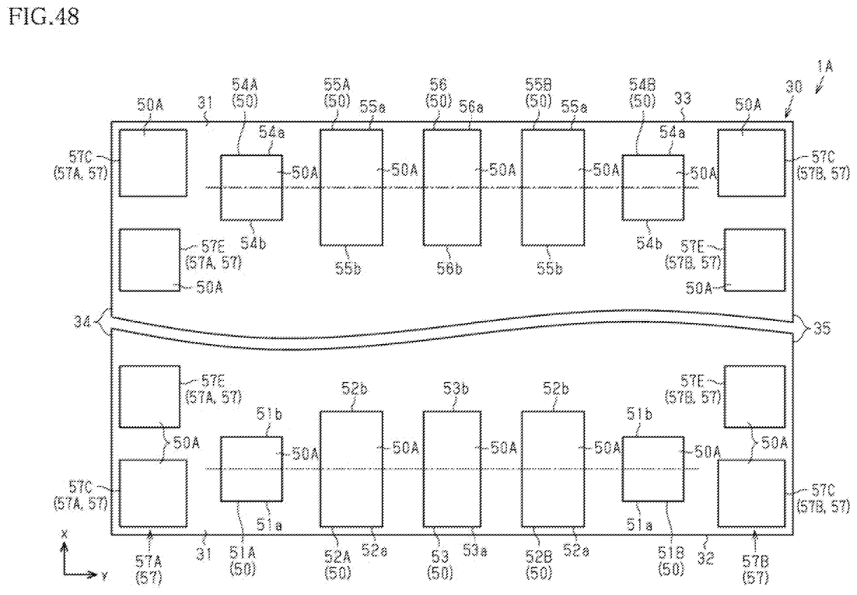

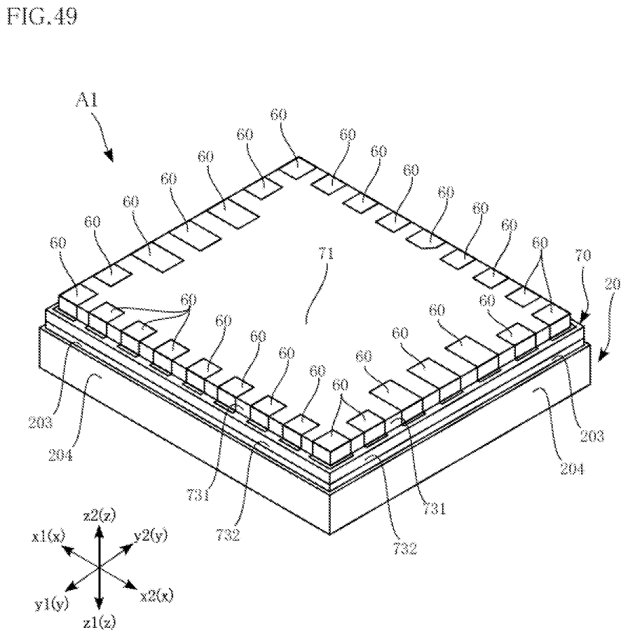

In the foregoing embodiments, the position of the first power conductors 51A and 51B, with respect to the first output conductors 52A and 523 and the first ground conductor 53 in the x-direction, may be changed as desired. The position of the second power conductors 54A and 54B, with respect to the second output conductors 55A and 55B and the second ground conductor 56 in the x-direction, may be changed as desired. For example, the respective positions of the first power conductors 51A and 51B and the second power conductors 54A and 54B in the x-direction may be shifted, as a first example shown in FIG. 47, and a second example shown in FIG. 48.

As shown in FIG. 47 and FIG. 48, one of the edges of the top face 50A of the first power conductors 51A and 51B in the x-direction, on the side of the resin side face 32, will be defined as edge 51a, and the other edge on the opposite side of the resin side face 32 will be defined as edge 51b. One of the edges of the top face 50A of the first output conductors 52A and 528 in the x-direction, on the side of the resin side face 32, will be defined as edge 52a, and the other edge on the opposite side of the resin side face 32 will be defined as edge 52b. One of the edges of the top face 50A of the first ground conductor 53 in the x-direction, on the side of the resin side face 32, will be defined as edge 53a, and the other edge on the opposite side of the resin side face 32 will be defined as edge 53b. One of the edges of the top face 50A of the second power conductors 54A and 54B in the x-direction, on the side of the resin side face 33, will be defined as edge 54a, and the other edge on the opposite side of the resin side face 33 will be defined as edge 54b. One of the edges of the top face 50A of the second output conductors 55A and 55B in the x-direction, on the side of the resin side face 33, will be defined as edge 55a, and the other edge on the opposite side of the resin side face 33 will be defined as edge 55b. One of the edges of the top face 50A of the second ground conductor 56 in the x-direction, on the side of the resin side face 33, will be defined as edge 56a, and the other edge on the opposite side of the resin side face 33 will be defined as edge 56b.

In the first example, as shown in FIG. 47, the edge 51b of the first power conductors 51A and 51B is aligned with the edge 52b of the first output conductors 52A and 52B and the edge 53b of the first ground conductor 53, in the x-direction. The edge 54b of the second power conductors 54A and 54B is aligned with the edge 55b of the second output conductors 55A and 55B and the edge 56b of the second ground conductor 56, in the x-direction.

In the second example, as shown in FIG. 48, the edge 51b of the first power conductors 51A and 51B is located closer to the substrate side face 13 in the x-direction, than are the edge 52b of the first output conductors 52A and 52B and the edge 53b of the first ground conductor 53. In addition, the edge 51a of the first power conductors 51A and 51B is located farther from the substrate side face 13 in the x-direction, than are the edge 52a of the first output conductors 52A and 528 and the edge 53a of the first ground conductor 53. More specifically, the first power conductors 51A and 51B, the first output conductors 52A and 52B, and the first ground conductor 53 are located such that, as indicated by a dash-dot line in FIG. 48, the center of the first power conductors 51A and 51B in the x-direction, the center of the first output conductors 52A and 52B in the x-direction, and the center of the first ground conductor 53 in the x-direction are aligned with each other in the x-direction.

Likewise, the edge 54b of the second power conductors 54A and 54B is located closer to the substrate side face 14 in the x-direction, than are the edge 55b of the second output conductors 55A and 55B and the edge 56b of the second ground conductor 56. In addition, the edge 54a of the second power conductors 54A and 54B is located farther from the substrate side face 14 in the x-direction, than are the edge 55a of the second output conductors 55A and 55B and the edge 56a of the second ground conductor 56. More specifically, the second power conductors 54A and 543, the second output conductors 55A and 55B, and the second ground conductor 56 are located such that, as indicated by a dash-dot line in FIG. 48, the center of the second power conductors 54A and 54B in the x-direction, the center of the second output conductors 55A and 55B in the x-direction, and the center of the second ground conductor 56 in the x-direction are aligned with each other in the x-direction.

The position of the first power conductors 51A and 51B in the x-direction and the position of the second power conductors 54A and 54B in the x-direction are changed as shown in FIG. 47 and FIG. 48, by reducing the volume of the first power conductors 51A and 51B and the second power conductors 54A and 54B. However, a different arrangement may be adopted. The position in the x-direction of any of the first power conductors 51A and 51B, the first output conductors 52A and 52B, and the first ground conductor 53, the volume of which is reduced by reducing the length of the top face 50A in the x-direction, may be changed. Likewise, the position in the x-direction of any of the second power conductors 54A and 54B, the second output conductors 55A and 55B, and the second ground conductor 56, the volume of which is reduced by reducing the length of the top face 50A in the x-direction, may be changed. The above also applies to the first power conductor 51, the first output conductor 52, the first ground conductor 53, the second power conductor 54, the second output conductor 55, and the second ground conductor 56 according to the second embodiment.

The technical ideas that can be perceived from the embodiments of the first aspect and the variations thereof will be described in the following clauses.

Clause A1.

A manufacturing method of a semiconductor device, the method including:
a wiring formation process including forming wirings including a first drive wiring and a second drive wiring, on a base material obverse face of a base material having the base material obverse face and a base material reverse face, oriented to opposite sides to each other in a thickness direction;
a conductor formation process including forming a first drive conductor on the first drive wiring, and forming a second drive conductor on the second drive wiring;
an element mounting process including mounting a semiconductor element on the first drive wiring and the second drive wiring; and
a resin layer formation process including forming a resin layer covering the wiring, the semiconductor element, the first drive conductor, and the second drive conductor,
in which the conductor formation process includes forming the first drive conductor so as to make the first drive conductor smaller in volume than the second drive conductor.

In the mentioned manufacturing method, the first drive conductor is made smaller in volume than the second drive conductor. Such a configuration can minimize the warp of the base material constituting the substrates, despite being heated during the resin layer formation process. Consequently, the semiconductor device can be stably manufactured.

Clause A2.

The method according to Clause A1, further including a resin layer processing process including reducing a thickness of the resin layer, and processing the resin layer so as to expose an end face of the first drive conductor in the thickness direction, and an end face of the second drive conductor in the thickness direction, from the resin layer.

Clause B1.

A manufacturing method of a semiconductor device, the method including:
a wiring formation process including forming a wiring including a first drive wiring and a second drive wiring, on a base material obverse face of a base material having a base material obverse face and the base material reverse face, oriented to opposite sides to each other in a thickness direction;
a conductor formation process including forming a first drive conductor on the first drive wiring, and forming a second drive conductor on the second drive wiring;
an element mounting process including mounting a semiconductor element on the first drive wiring and the second drive wiring;
a resin layer formation process including forming a resin layer covering the wiring, the semiconductor element, the first drive conductor, and the second drive conductor; and
a resin layer processing process including reducing a thickness of the resin layer, a thickness of the first drive conductor, and a thickness of the second drive conductor,
in which the conductor formation process includes forming the first drive conductor so as to make the first drive conductor smaller in volume than the second drive conductor.
the conductor formation process making the first drive conductor thinner than the second drive conductor, and the resin layer processing process includes making the thickness of the first drive conductor and the second drive conductor equal to each other.

In the mentioned manufacturing method, the first drive conductor is made smaller in volume than the second drive conductor, in the process preceding the resin layer formation process. Such a configuration can minimize the warp of the base material, despite being heated during the resin layer formation process. Consequently, the semiconductor device can be stably manufactured.

Clause C1.

A manufacturing method of a semiconductor device, the method including:
a terminal pillar formation process including forming a plurality of terminal pillars, on a base material obverse face of a base material having the base material obverse face and a base material reverse face, oriented to opposite sides to each other in a thickness direction;
a substrate formation process including forming a substrate by molding with an electrically insulative resin so as to insulate between the plurality of terminal pillars;
a wiring formation process including forming a plurality of wirings electrically connected to the terminal pillars, on one of faces of the substrate in the thickness direction; and
an element mounting process including mounting a semiconductor element on the plurality of wirings,
in which the plurality of terminal pillars include a first drive terminal pillar and a second drive terminal pillar in which a driving current for the semiconductor element flows, and the terminal pillar formation process includes making the first drive terminal pillar smaller in volume than the second drive terminal pillar.

In the mentioned manufacturing method, the first drive terminal pillar is made smaller in volume than the second drive terminal pillar. Such a configuration can minimize the warp of the base material constituting the substrates, despite being heated during the molding operation in the substrate formation process. Consequently, the semiconductor device can be stably manufactured.

Clause C2.

The method according to Clause C1, further including a substrate processing process including reducing a thickness of the substrate, and processing the substrate so as to expose respective end faces of the plurality of terminal pillars in the thickness direction from the substrate.

Clause D1.

A semiconductor device including:
a substrate having a substrate obverse face and a substrate reverse face, oriented to opposite sides to each other in a thickness direction;
wirings located on the substrate obverse face, and including a first drive wiring and a second drive wiring;
a semiconductor element electrically connected to the first drive wiring and the second drive wiring;
a first drive conductor located on a same side as the semiconductor element with respect to the substrate, in a region on an outer side of the semiconductor element as viewed in the thickness direction, and electrically connected to the first drive wiring;
a second drive conductor located on the same side as the semiconductor element with respect to the substrate, in a region on an outer side of the semiconductor element as viewed in the thickness direction, and electrically connected to the second drive wiring; and
a sealing resin covering the wirings and the semiconductor element, and covering the first drive conductor and the second drive conductor such that respective faces of the first drive conductor and the second drive conductor, on an opposite side of the substrate in the thickness direction, are exposed,
in which the first drive conductor and the second drive conductor are aligned, with a spacing between each other, in a predetermined direction along the substrate obverse face, and
the first drive conductor is smaller in volume than the second drive conductor.

Clause D2.

The semiconductor device according to Clause D1,
in which the first drive conductor and the second drive conductor each include a top face exposed from a side of the sealing resin opposite to the substrate in the thickness direction, and
the top face of the first drive conductor is smaller in area than the top face of the second drive conductor.

Clause D3.

The semiconductor device according to Clause D2,
in which, when an alignment direction of the first drive conductor and the second drive conductor is defined as a first direction, and a direction orthogonal to the thickness direction and the first direction is defined as a second direction,
the respective top faces of the first drive conductor and the second drive conductor have a rectangular shape having short sides extending in the first direction and long sides extending in the second direction, as viewed in the thickness direction, and the top face of the first drive conductor is shorter in the second direction, than the top face of the second drive conductor.

Clause D4.

The semiconductor device according to Clause D2,
in which, when an alignment direction of the first drive conductor and the second drive conductor is defined as a first direction, and a direction orthogonal to the thickness direction and the first direction is defined as a second direction,
the respective top faces of the first drive conductor and the second drive conductor have a rectangular shape having short sides extending in the first direction and long sides extending in the second direction, as viewed in the thickness direction, and
the top face of the first drive conductor is shorter in the first direction, than the top face of the second drive conductor.

Clause D5.

The semiconductor device according to any one of appendices D1 to D4,
in which the second drive conductor is located closer to a center of the substrate obverse face than is the first drive conductor, in the alignment direction of the first drive conductor and the second drive conductor.

Clause D6.

The semiconductor device according to any one of appendices D1 to D5,
in which, when an alignment direction of the first drive conductor and the second drive conductor is defined as a first direction, and a direction orthogonal to the thickness direction and the first direction is defined as a second direction,
the semiconductor element includes a control circuit,
a plurality of control conductors electrically connected to the control circuit are provided,
the plurality of control conductors are aligned in the second direction with a spacing between each other, and
the second drive conductor is larger in volume than the control conductor.

Clause D7.

The semiconductor device according to Clause D6,
in which the first drive conductor, the second drive conductor, and the control conductor each include a top face exposed from the face of the sealing resin on the opposite side of the substrate in the thickness direction, and
the top face of the second drive conductor is larger in area than the top face of the control conductor.

Clause D8.

The semiconductor device according to Clause D7,
in which the top face of the second drive conductor has a rectangular shape having the short sides extending in the first direction and the long sides extending in the second direction, as viewed in the thickness direction,
the top face of the control conductor has a rectangular shape having sides extending in the first direction and sides extending in the second direction, as viewed in the thickness direction, and
the top face of the second drive conductor is longer in the second direction, than a length of the top face of the control conductor in the first direction, and a length in the second direction.

Clause D9.

The semiconductor device according to any one of appendices D6 to D8,
in which the plurality of control conductors are located on an outer side in the first direction, with respect to the first drive conductor and the second drive conductor.

Clause D10.

The semiconductor device according to Clause D9,
in which the substrate has a rectangular shape having the sides extending in the first direction and the sides extending in the second direction, as viewed in the thickness direction,
the control conductors include distal control conductors respectively located at four corners of the substrate viewed in the thickness direction, and intermediate control conductors located between two of the distal control conductors in the second direction,
the distal control conductors and the intermediate control conductors each include a top face exposed from the face of the sealing resin on the opposite side of the substrate in the thickness direction, and
the top face of the distal control conductor is larger in area than the top face of the intermediate control conductor.

Clause D11.

The semiconductor device according to Clause D10,
in which the second drive conductor is larger in volume than the distal control conductor.

Clause D12.

The semiconductor device according to Clause D11,
in which the second drive conductor includes a top face exposed from the face of the sealing resin on the opposite side of the substrate in the thickness direction, and
the top face of the second drive conductor is larger in area than the top face of the distal control conductor.

Clause D13.

The semiconductor device according to Clause D12,
in which the top face of the second drive conductor has a rectangular shape having the short sides extending in the first direction and the long sides extending in the second direction, as viewed in the thickness direction,
the top face of the distal control conductor has a rectangular shape having the sides extending in the first direction and the sides extending in the second direction, as viewed in the thickness direction, and
the top face of the second drive conductor is longer in the second direction, than a length of the top face of the distal control conductor in the first direction, and a length in the second direction.

Clause D14.

The semiconductor device according to any one of appendices D6 to D9,
in which a volume of the first drive conductor is equal to or larger than a volume of the control conductor.

Clause D15.

The semiconductor device according to any one of appendices D10 to D13,
in which the first drive conductor is smaller in volume than the distal control conductor.

Clause D16.

The semiconductor device according to Clause D15,
in which the first drive conductor includes a top face exposed from the face of the sealing resin on the opposite side of the substrate in the thickness direction, and the top face of the first drive conductor is smaller in area than the top face of the distal control conductor.

Clause D17.

The semiconductor device according to Clause D16,
in which the top face of the first drive conductor has a rectangular shape having the short sides extending in the first direction and the long sides extending in the second direction, as viewed in the thickness direction, and
the top face of the first drive conductor is shorter in the second direction, than at least one of the length of the top face of the distal control conductor in the first direction, and the length in the second direction.

Clause D18.

The semiconductor device according to any one of appendices D10 to D13,
in which the volume of the first drive conductor is equal to or larger than a volume of the intermediate control conductor.

Clause D19.

The semiconductor device according to Clause D18,
in which the first drive conductor includes a top face exposed from the face of the sealing resin on the opposite side of the substrate in the thickness direction, and
an area of the top face of the first drive conductor is equal to or larger than an area of the top face of the intermediate control conductor.

Clause D20.

The semiconductor device according to any one of appendices D10 to D19,
in which the wiring includes a control wiring connecting the control circuit and the control conductor, and
the first drive wiring and the second drive wiring are each wider than the control wiring.

Clause D21.

The semiconductor device according to any one of appendices D10 to D20,
in which the plurality of control conductors are each located on an outer side of the semiconductor element.

Clause D22.

A semiconductor device including:
a substrate having a substrate obverse face and a substrate reverse face, oriented to opposite sides to each other in a thickness direction;
wirings located on the substrate obverse face, and including a first drive wiring and a second drive wiring;
a semiconductor element mounted on the substrate obverse face, and electrically connected to the first drive wiring and the second drive wiring;
a first drive conductor penetrating through the substrate in the thickness direction, so as to be exposed on the substrate obverse face and the substrate reverse face, and electrically connected to the first drive wiring;
a second drive conductor penetrating through the substrate in the thickness direction, so as to be exposed on the substrate obverse face and the substrate reverse face, and electrically connected to the second drive wiring; and
a sealing resin covering the wirings and the semiconductor element,
in which the first drive conductor and the second drive conductor are aligned, with a spacing between each other, in a predetermined direction as viewed from the substrate reverse face, and
the first drive conductor is smaller in volume than the second drive conductor.

Clause D23.

The semiconductor device according to Clause D22,
in which the first drive conductor and the second drive conductor each include a top face exposed from the substrate reverse face, and
the top face of the first drive conductor is smaller in area than the top face of the second drive conductor.

Clause D24.

The semiconductor device according to Clause D23,
in which, when an alignment direction of the first drive conductor and the second drive conductor is defined as a first direction, and a direction orthogonal to the thickness direction and the first direction is defined as a second direction,
the respective top faces of the first drive conductor and the second drive conductor have a rectangular shape having short sides extending in the first direction and long sides extending in the second direction, as viewed in the thickness direction, and the top face of the first drive conductor is shorter in the second direction, than the top face of the second drive conductor.

Clause D25.

The semiconductor device according to Clause D23,
in which, when an alignment direction of the first drive conductor and the second drive conductor is defined as a first direction, and a direction orthogonal to the thickness direction and the first direction is defined as a second direction,
the respective top faces of the first drive conductor and the second drive conductor have a rectangular shape having short sides extending in the first direction and long sides extending in the second direction, as viewed in the thickness direction, and
the top face of the first drive conductor is shorter in the first direction, than the top face of the second drive conductor.

Clause D26.

The semiconductor device according to any one of appendices D22 to D25,
in which the second drive conductor is located closer to a center of the substrate obverse face than is the first drive conductor, in the alignment direction of the first drive conductor and the second drive conductor.

Clause D27.

The semiconductor device according to any one of appendices D22 to D26,
in which, when an alignment direction of the first drive conductor and the second drive conductor is defined as a first direction, and a direction orthogonal to the thickness direction and the first direction is defined as a second direction,
the semiconductor element includes a control circuit,
a plurality of control conductors electrically connected to the control circuit are provided,
the plurality of control conductors are aligned in the second direction with a spacing between each other, and
the second drive conductor is larger in volume than the control conductor.

Clause D28.

The semiconductor device according to Clause D27,
in which the first drive conductor, the second drive conductor, and the control conductor each include a top face exposed from the substrate reverse face, and
the top face of the second drive conductor is larger in area than the top face of the control conductor.

Clause D29.

The semiconductor device according to Clause D28,
in which the top face of the second drive conductor has a rectangular shape having the short sides extending in the first direction and the long sides extending in the second direction, as viewed in the thickness direction.
the top face of the control conductor has a rectangular shape having sides extending in the first direction and sides extending in the second direction, and
the top face of the second drive conductor is longer in the second direction, than a length of the top face of the control conductor in the first direction, and a length in the second direction.

Clause D30.

The semiconductor device according to any one of appendices D27 to D29,
in which the plurality of control conductors are located on an outer side in the first direction, with respect to the first drive conductor and the second drive conductor.

Clause D31.

The semiconductor device according to Clause D30.
in which the substrate has a rectangular shape having the sides extending in the first direction and the sides extending in the second direction, as viewed in the thickness direction,
the control conductors include distal control conductors respectively located at four corners of the substrate viewed in the thickness direction, and intermediate control conductors located between two of the distal control conductors in the second direction,
the distal control conductors and the intermediate control conductors each include a top face exposed from the substrate reverse face, and
the top face of the distal control conductor is larger in area than the top face of the intermediate control conductor.

Clause D32.

The semiconductor device according to Clause D31,
in which the second drive conductor is larger in volume than the distal control conductor.

Clause D33.

The semiconductor device according to Clause D32.
in which the second drive conductor includes a top face exposed from the substrate reverse face, and
the top face of the second drive conductor is larger in area than the top face of the distal control conductor.

Clause D34.

The semiconductor device according to Clause D33,
in which the top face of the second drive conductor has a rectangular shape having the short sides extending in the first direction and the long sides extending in the second direction, as viewed in the thickness direction,
the top face of the distal control conductor has a rectangular shape having the sides extending in the first direction and the sides extending in the second direction, and
the top face of the second drive conductor is longer in the second direction, than a length of the top face of the distal control conductor in the first direction, and a length in the second direction.

Clause D35.

The semiconductor device according to any one of appendices D27 to D30,
in which a volume of the first drive conductor is equal to or larger than a volume of the control conductor.

Clause D36.

The semiconductor device according to any one of appendices D31 to D34,
in which the first drive conductor is smaller in volume than the distal control conductor.

Clause D37.

The semiconductor device according to Clause D36,
in which the first drive conductor includes a top face exposed from the substrate reverse face, and
the top face of the first drive conductor is smaller in area than the top face of the distal control conductor.

Clause D38.

The semiconductor device according to Clause D37,
in which the top face of the first drive conductor has a rectangular shape having the short sides extending in the first direction and the long sides extending in the second direction, as viewed in the thickness direction, and
the top face of the first drive conductor is shorter in the second direction, than the length of the top face of the distal control conductor in the first direction.

Clause D39.

The semiconductor device according to any one of appendices D31 to D34,
in which the volume of the first drive conductor is equal to or larger than a volume of the intermediate control conductor.

Clause D40.

The semiconductor device according to Clause D39,
in which the first drive conductor includes a top face exposed from the substrate reverse face, and
an area of the top face of the first drive conductor is equal to or larger than an area of the top face of the intermediate control conductor.

Clause D41.

The semiconductor device according to any one of appendices D31 to D40,
in which the wiring includes a control wiring connecting the control circuit and the control conductor, and
the first drive wiring and the second drive wiring are each wider than the control wiring.

Clause D42.

The semiconductor device according to any one of appendices D31 to D41,
in which the plurality of control conductors are each located on an outer side of the semiconductor element.

Clause D43.

The semiconductor device according to any one of appendices D1 to D42,
in which the first drive conductor is thicker than the first drive wiring, and
the second drive conductor is thicker than the second drive wiring.

Clause D44.

The semiconductor device according to any one of appendices D1 to D43,
in which the first drive wiring includes a wide wiring section which is relatively wider, and a narrow wiring section which is relatively narrower,
on the wide wiring section, the first drive conductor is located, and
the narrow wiring section is located on an inner side with respect to the wide wiring section, in the direction in which the first drive wiring extends.

Clause D45.

The semiconductor device according to Clause D44,
in which the wide wiring section is wider than the length of the top face of the first drive conductor in the first direction.

Clause D46.

The semiconductor device according to Clause D44 or D45,
in which the narrow wiring section of the first drive wiring includes a widened section where a width of the narrow wiring section is increased.

Clause D47.

The semiconductor device according to any one of appendices D1 to D46,
in which the second drive wiring includes a wide wiring section which is relatively wider, and a narrow wiring section which is relatively narrower,
on the wide wiring section, the second drive conductor is located, and
the narrow wiring section is located on an inner side with respect to the wide wiring section, in the direction in which the second drive wiring extends.

Clause D48.

The semiconductor device according to Clause D47,
in which the wide wiring section of the second drive wiring is wider than the length of the second drive conductor in the first direction.

Clause D49.

The semiconductor device according to Clause D47 or D48,
in which a portion of the second drive wiring connecting the wide wiring section and the narrow wiring section includes a sloped section, inclined so as to be narrower in a direction from the wide wiring section toward the narrow wiring section.

Clause D50.

The semiconductor device according to any one of appendices D1 to D21, further including a first drive terminal and a second drive terminal,
in which the first drive conductor and the second drive conductor each include a top face exposed from the face of the sealing resin on the opposite side of the substrate in the thickness direction,
the first drive terminal is formed so as to cover the top face of the first drive conductor, and
the second drive terminal is formed so as to cover the top face of the second drive conductor.

Clause D51.

The semiconductor device according to any one of appendices D22 to D42, further including a first drive terminal and a second drive terminal,
in which the first drive conductor and the second drive conductor each include a top face exposed from the substrate reverse face,
the first drive terminal is formed so as to cover the top face of the first drive conductor, and
the second drive terminal is formed so as to cover the top face of the second drive conductor.

Clause D52.

The semiconductor device according to any one of appendices D1 to D21,
in which the substrate includes a monocrystalline intrinsic semiconductor material.

Clause D53.

The semiconductor device according to any one of appendices D1 to D52,
in which the sealing resin includes a thermosetting resin.

Listed hereunder are the elements related to the embodiments and/or the variations of the first aspect.
1A, 1B, 1C semiconductor device
10 substrate
11 substrate obverse face
12 substrate reverse face
20, 20X terminal
21, 21A, 21B first power terminal (first drive terminal)
22, 22A, 22B first output terminal (second drive terminal)
23 first ground terminal (second drive terminal)
24, 24A, 24B second power terminal (first drive terminal)
25, 25A, 25B second output terminal (second drive terminal)
26 second ground terminal (second drive terminal)
30 sealing resin
31 mounting surface
40, 40X wiring
41, 41A, 41B first power wiring (first drive wiring)
41a wide wiring section
41b narrow wiring section
41f widened section
41g sloped section
42, 42A, 42B first output wiring (second drive wiring)
42a wide wiring section
42b narrow wiring section
42c sloped section
43 first ground wiring (second drive wiring)
44, 44A, 44B second power wiring (first drive wiring)
44a wide wiring section
44b narrow wiring section
44f widened section
44g sloped section
45, 45A, 45B second output wiring (second drive wiring)
45a wide wiring section
45b narrow wiring section
45c sloped section
46 second ground wiring (second drive wiring)
47, 47A, 47B control wiring
50, 50X conductor
50A top face
51, 51A, 51B first power conductor (first drive conductor)
52, 52A, 529 first output conductor (second drive conductor)
53 first ground conductor (second drive conductor)
54, 54A, 54B second power conductor (first drive conductor)
55, 55A, 55B second output conductor (second drive conductor)
56 second ground conductor (second drive conductor)
57, 57A, 57 control conductor
57C distal control conductor
57B intermediate control conductor
60, 60X semiconductor element
210 substrate
211 substrate obverse face
212 substrate reverse face
230 sealing resin

Hereunder, a semiconductor device (and a manufacturing method thereof) according to some embodiments and variations of a second aspect of the present disclosure, will be described with reference to FIG. 49 to FIG. 76.

The terms “first”, “second”, “third”, and so forth used in the present disclosure merely serve as a label, and are not intended to specify an order or grade with respect to the objects accompanied with these terms. The term “flush” used in the present disclosure refers to the state where surfaces located adjacent to each other are smoothly connected to each other, as result of the manufacturing method exemplified in the present disclosure. However, a discontinuous portion or a stepped portion may inevitably be formed between such surfaces, owing to, for example, the manufacturing method, a manufacturing error, or a difference in thermal expansion coefficient of the material.

In the description of the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Further, the expression “An object A is stacked in an object B”, and “An object A is stacked on an object B” imply the situation where, unless otherwise specifically noted, “the object A is stacked directly in or on the object B”, and “the object A is stacked in or on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”.

### First Embodiment (Second Aspect)

FIG. 49 to FIG. 59 illustrate a semiconductor device A1 according to a second aspect of the first embodiment. The semiconductor device A1 includes a semiconductor element 10, a substrate 20, an insulation film 29, a plurality of wiring layers 30, a plurality of second columnar electrodes 41, a plurality of first columnar electrodes 42, a plurality of bonding sections 50, a plurality of external electrodes 60, and a resin member 70.

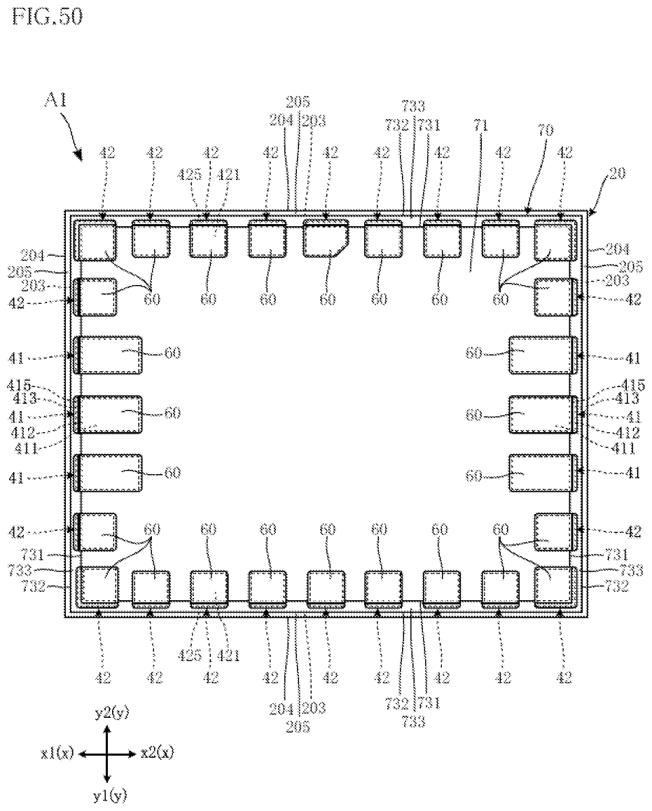

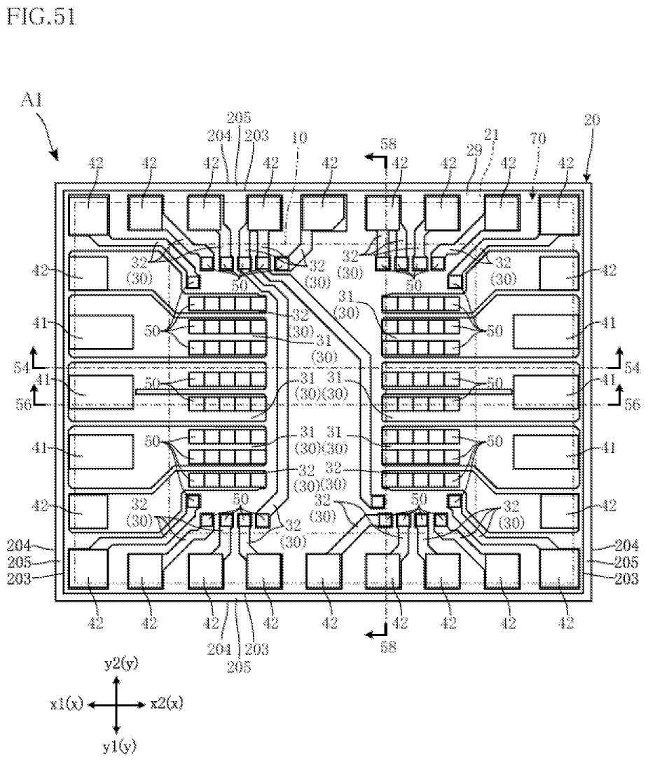

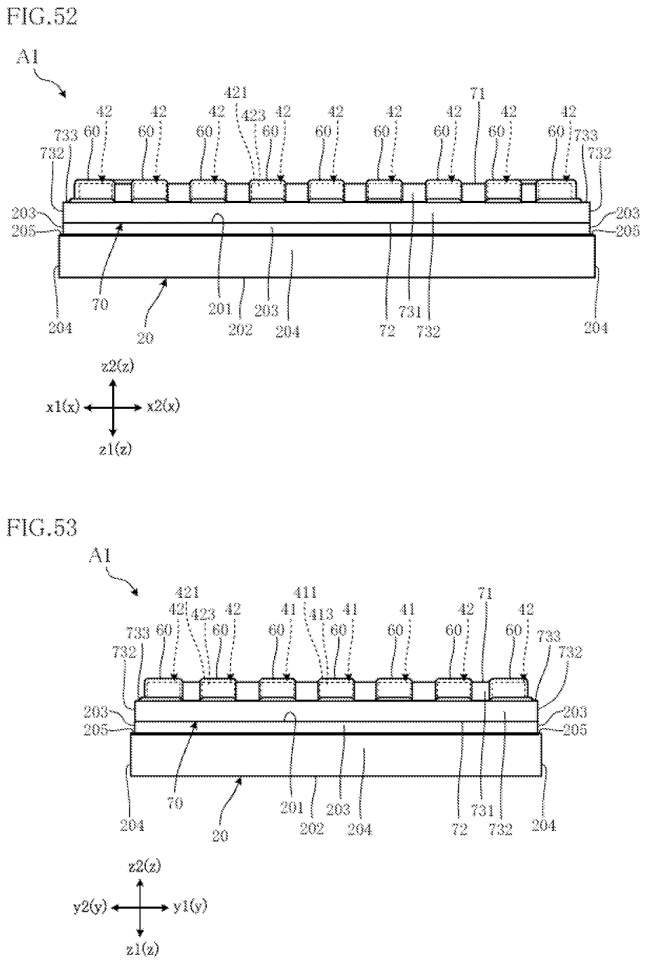

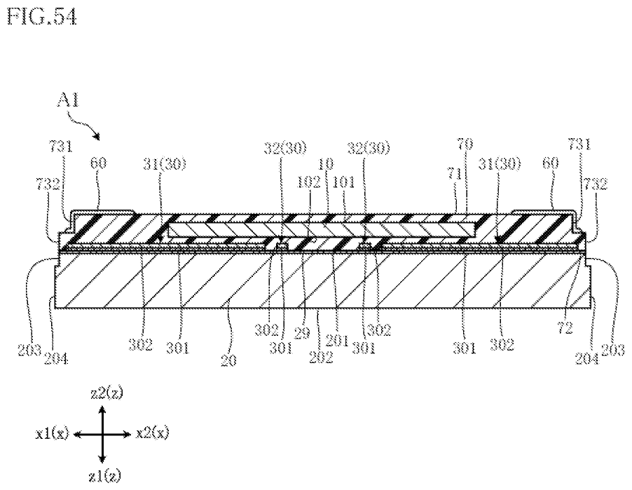

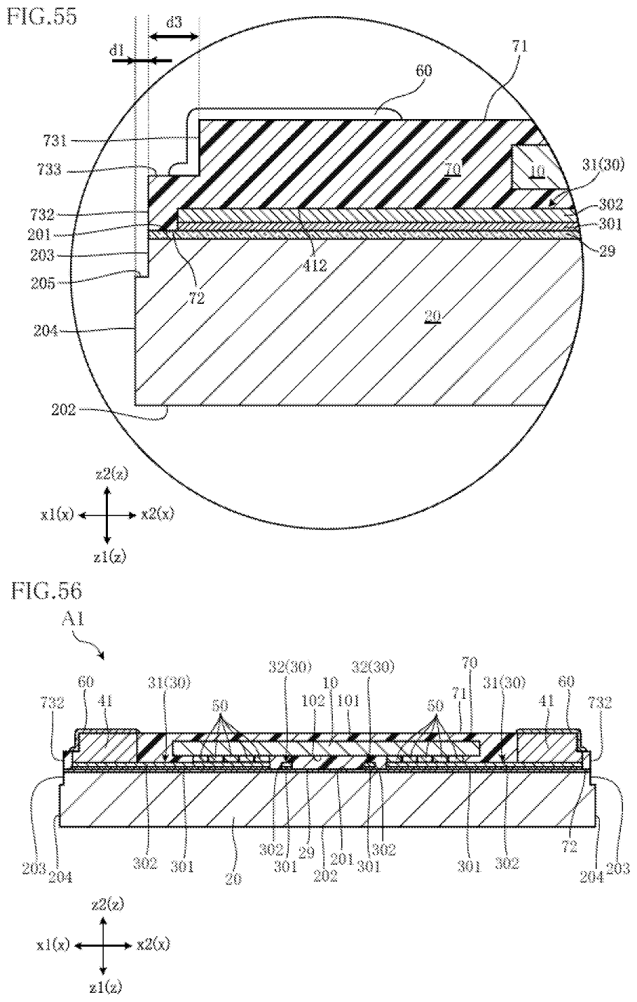

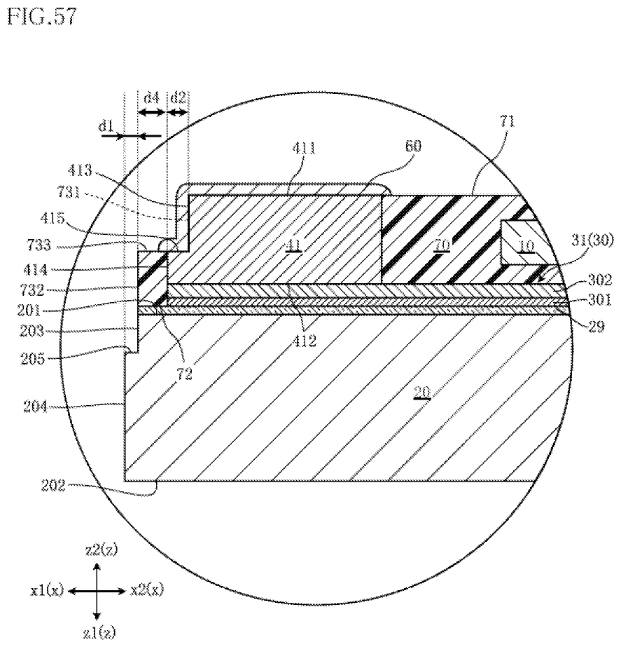

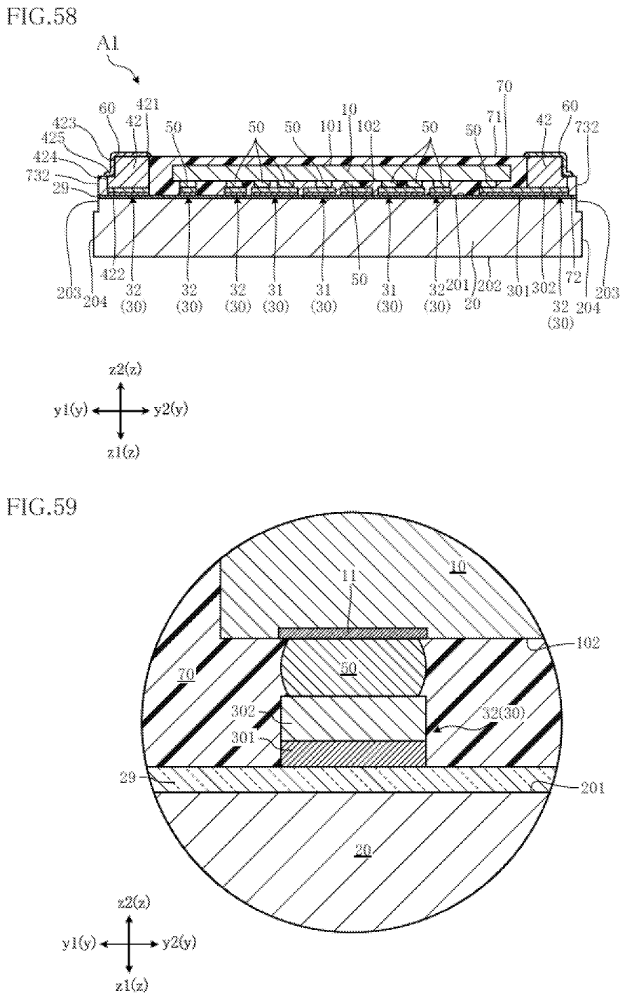

FIG. 49 is a perspective view showing the semiconductor device A1. FIG. 50 is a plan view showing the semiconductor device A1. FIG. 51 is a plan view corresponding to FIG. 50, with a plurality of external electrodes excluded, and a semiconductor element 10 and a resin member 70 indicated by imaginary lines (dash-dot-dot lines). FIG. 52 is a front view showing the semiconductor device A1. FIG. 53 is a side view (left-side view) showing the semiconductor device A1. FIG. 54 is a cross-sectional view taken along a line 54-54 in FIG. 51. FIG. 55 is a partially enlarged cross-sectional view from FIG. 54. FIG. 56 is a cross-sectional view taken along a line 56-56 in FIG. 51. FIG. 57 is a partially enlarged cross-sectional view from FIG. 56. FIG. 58 is a cross-sectional view taken along a line 58-58 in FIG. 51. FIG. 59 is a partially enlarged cross-sectional view from FIG. 58.

For the sake of convenience in description, three directions orthogonal to each other will be defined as x-direction, y-direction, and z-direction. The z-direction corresponds to the thickness direction of the semiconductor device A1. The x-direction corresponds to the left-right direction in the plan view (see FIG. 50) of the semiconductor device A1. The y-direction corresponds to the up-down direction in the plan view (see FIG. 50) of the semiconductor device A1. If necessary, one side in the x-direction will be defined as x1-side, and the other side in the x-direction will be defined as x2-side. Likewise, one side in the y-direction will be defined as y1-side, and the other side will be defined as y2-side, and one side in the z-direction will be defined as z1-side, and the other side will be defined as z2-side. The z1-side may be referred to as lower side, and the z2-side may be referred to as upper side.

The semiconductor device A1 is to be surface-mounted on a circuit board of an electronic device or the like. To mount the semiconductor device A1 on the circuit board, for example solder is employed (hereinafter, “mount solder”). When the semiconductor device A1 is mounted on the circuit board, the face of the semiconductor device A1 oriented to the z2-side is opposed to the circuit board, in contact with the mount solder. The thickness (size in the z-direction) of the semiconductor device A1 is, for example, approximately 550 μm.

The semiconductor element 10 serves as the functional center of the semiconductor device A1. The semiconductor element 10 may be one of, for example, an integrated circuit (IC) such as a large-scale integration (LSI), a voltage control element such as a low drop out (LDO), an amplifying element such as an operational amplifier, and a discrete part such as a transistor or a diode. The semiconductor element 10 has a structure that allows the surface mounting. The semiconductor element 10 has a rectangular shape as viewed in the z-direction (or “in plan view” where appropriate), though the plan-view shape is not specifically limited. The semiconductor element 10 is conductively bonded to the plurality of wiring layers 30, via the plurality of bonding sections 50.

As shown in FIG. 54, FIG. 56, and FIG. 58, the semiconductor element 10 includes an element obverse face 101 and an element reverse face 102. The element obverse face 101 and the element reverse face 102 are spaced apart from each other in the z-direction. The element obverse face 101 is oriented to the z2-side, and the element reverse face 102 is oriented to the z1-side. As shown in FIG. 59, a plurality of element electrodes 11 are formed on the element reverse face 102. The plurality of element electrodes 11 are each formed of aluminum (Al). The plurality of element electrodes 11 each serve as a terminal of the semiconductor element 10. The plurality of element electrodes 11 overlap with the plurality of bonding section 50, in plan view. The number and position of the plurality of element electrodes 11 may be changed as appropriate, depending on the design of the semiconductor element 10.

The substrate 20 supports the semiconductor element 10. The substrate 20 is formed of a monocrystalline intrinsic semiconductor material (e.g., silicon (Si)). The substrate 20 has, for example, a rectangular shape in plan view. The substrate 20 includes a substrate obverse face 201, a substrate reverse face 202, a plurality of first substrate side faces 203, a plurality of second substrate side faces 204, and a plurality of substrate connecting surfaces 205.

As shown in FIG. 52 to FIG. 58, the substrate obverse face 201 and the substrate reverse face 202 are spaced apart from each other in the z-direction. The substrate obverse face 201 is oriented to the z2-side, and the substrate reverse face 202 is oriented to the z1-side. The substrate obverse face 201 is opposed to the semiconductor element 10. The substrate obverse face 201 and the substrate reverse face 202 are flat.

As shown in FIG. 52 to FIG. 58, the plurality of first substrate side faces 203 and the plurality of second substrate side faces 204 are each located between the substrate obverse face 201 and the substrate reverse face 202, in the z-direction. The plurality of first substrate side faces 203 and the plurality of second substrate side faces 204 are flat. The edge on the z2-side of each of the first substrate side faces 203 is connected to the substrate obverse face 201, and the edge on the z1-side of each of the second substrate side faces 204 is connected to the substrate reverse face 202. The first substrate side faces 203 are smaller in size in the z-direction, than the second substrate side faces 204. For example, the size in the z-direction of the first substrate side face 203 is approximately 50 μm, and the size in the z-direction of the second substrate side face 204 is approximately 310 μm. The substrate 20 includes, as shown in FIG. 50 and FIG. 51, a pair of first substrate side face 203 and second substrate side face 204 each oriented to the x1-side, a pair of first substrate side face 203 and second substrate side face 204 each oriented to the x2-side, a pair of first substrate side face 203 and second substrate side face 204 each oriented to the y1-side, and a pair of first substrate side face 203 and second substrate side face 204 each oriented to the y2-side. In each of the mentioned pairs, the first substrate side face 203 is located on the inner side of the second substrate side face 204.

As shown in FIG. 52 to FIG. 58, the plurality of substrate connecting surfaces 205 are each connected to the pair of first substrate side face 203 and second substrate side face 204. The substrate connecting surfaces 205 are oriented to the z2-side. The substrate connecting surfaces 205 are flat. The substrate connecting surface 205 may be inclined or curved, with respect to a x-y plane. The width d1 of the substrate connecting surfaces 205 (see FIG. 55 and FIG. 57) is, for example, approximately 10 μm. The width d1 of the substrate connecting surface 205 refers to the length of a line segment between the edge of the substrate connecting surface 205 connected to the first substrate side face 203 and the edge connected to the second substrate side face 204, and parallel to the x-direction or y-direction. Therefore, the separation distance between the pair of first substrate side face 203 and second substrate side face 204 in plan view is, for example, approximately 10 μm.

The insulation film 29 is formed on the substrate obverse face 201, as shown in FIG. 54 to FIG. 59. The insulation film 29 covers the entirety of the substrate obverse face 201. The insulation film 29 is, for example, formed of an oxide film (SiO₂) and a nitride film (Si₃N₄) stacked on the oxide film.

The plurality of wiring layers 30 are, as shown in FIG. 51 and FIG. 54 to FIG. 58, formed on the substrate obverse face 201 of the substrate 20, via the insulation film 29. The plurality of wiring layers 30 constitute a part of the conduction path between the semiconductor element 10 and the circuit board on which the semiconductor device A1 is mounted. The plurality of wiring layers 30 are spaced apart from one another.

The plurality of wiring layers 30 each include an underlying layer 301 and a plated layer 302, as shown in FIG. 54 to FIG. 58. The underlying layer 301 is in contact with the insulation film 29. The underlying layer 301 includes a barrier layer formed in contact with the insulation film 29, and a seed layer stacked on the barrier layer. The barrier layer is, for example, formed of titanium (Ti). The seed layer is, for example, formed of copper (Cu). The underlying layer 301 can be formed, for example, by a sputtering method. The plated layer 302 is stacked on the underlying layer 301. In each of the wiring layers 30, the plated layer 302 serves as the primary conduction path. The plated layer 302 is, for example, formed of Cu. The plated layer 302 can be formed, for example, through an electrolytic plating process. The thickness (size in the z-direction) of the underlying layer 301 is, for example, approximately 200 nm to 900 nm, and the thickness (size in the z-direction) of the plated layer 302 is, for example, approximately 5 μm to 25 μm. The thickness (size in the z-direction) of each of the wiring layers 30 is, for example, approximately 5 μm to 25 μm.

The plurality of wiring layers 30 include a plurality of wiring sections 31 and a plurality of wiring sections 32, as shown in FIG. 51 and FIG. 54 to FIG. 58. The plurality of wiring sections 31 are each electrically connected to one of the power terminals of the semiconductor element 10 or one of the ground terminals of the semiconductor element 10. The plurality of wiring sections 32 are each electrically connected to the terminal of the semiconductor element 10, other than the power terminal and the ground terminal (e.g., signal terminal).

The plurality of second columnar electrodes 41 and the plurality of first columnar electrodes 42 are formed on the plurality of wiring layers 30, as shown in FIG. 51 and FIG. 56 to FIG. 58. The plurality of second columnar electrodes 41 and the plurality of first columnar electrodes 42 are spaced apart from one another. The plurality of second columnar electrodes 41 and the plurality of first columnar electrodes 42 are located on the outer side of the semiconductor element 10, in plan view. In other words, the semiconductor element 10 is surrounded by the plurality of second columnar electrodes 41 and the plurality of first columnar electrodes 42. The plurality of second columnar electrodes 41 and the plurality of first columnar electrodes 42 each protrude to the z2-side from the wiring layer 30, in plan view. The plurality of second columnar electrodes 41 and the plurality of first columnar electrodes 42 are each located on the inner side of the peripheral edge of both of the substrate 20 and the resin member 70 in plan view, as shown in FIG. 51. The plurality of second columnar electrodes 41 and the plurality of first columnar electrodes 42 are, for example, formed of Cu. The plurality of second columnar electrodes 41 and the plurality of first columnar electrodes 42 can be formed, for example, through an electrolytic plating process.

The plurality of second columnar electrodes 41 are formed on the plurality of wiring sections 31, as shown in FIG. 56 and FIG. 57. The second columnar electrodes 41 each include a second top face 411, a second contact surface 412, a second exposed side face 413, a second covered side face 414, and a second connecting surface 415.

The second top face 411 and the second contact surface 412 are spaced apart from each other in the z-direction, as shown in FIG. 57. The second top face 411 is oriented to the z2-side, and the second contact surface 412 is oriented to the z1-side. The second top face 411 is exposed from the resin member 70. The second contact surface 412 is in contact with the wiring sections 31.

The second exposed side face 413 and the second covered side face 414 are oriented to the outer side of the semiconductor device A1 from the second columnar electrode 41, as shown in FIG. 57. The second exposed side face 413 and the second covered side face 414 are located between the second top face 411 and the second contact surface 412, in the z-direction. The edge on the z2-side of the second exposed side face 413 is connected to the second top face 411, and the edge on the z1-side of the second covered side face 414 is connected to the second contact surface 412. The second exposed side face 413 is exposed from the resin member 70, and the second covered side face 414 is covered with the resin member 70. The size of the second exposed side face 413 in the z-direction is, for example, approximately 100 μm, and the size of the second covered side face 414 in the z-direction is, for example, approximately 60 μm to 90 μm.

The second connecting surface 415 is connected to the second exposed side face 413 and the second covered side face 414, as shown in FIG. 57. The second connecting surface 415 is exposed from the resin member 70. The second connecting surface 415 overlaps with the semiconductor element 10, as viewed in the x-direction or y-direction. The width d2 (see FIG. 57) of the second connecting surface 415 is, for example, approximately 15 μm. The width d2 of the second connecting surface 415 refers to the length of a line segment between the edge of the second connecting surface 415 connected to the second exposed side face 413 and the edge connected to the second covered side face 414, and parallel to the x-direction or y-direction.

The plurality of first columnar electrodes 42 are formed on the plurality of wiring sections 32, as shown in FIG. 58. The first columnar electrodes 42 each include a first top face 421, a first contact surface 422, a first exposed side face 423, a first covered side face 424, and a first connecting surface 425. Four out of the plurality of first columnar electrodes 42, located at the respective corners of the semiconductor device A1 in plan view, each include two each of the first exposed side faces 423, the first covered side faces 424, and the first connecting surfaces 425.

The first top face 421 and the first contact surface 422 are spaced apart from each other in the z-direction, as shown in FIG. 58. The first top face 421 is oriented to the z2-side, and the first contact surface 422 is oriented to the z1-side. The first top face 421 is exposed from the resin member 70. The first contact surface 422 is in contact with the wiring sections 32. In the example shown in FIG. 50 and FIG. 51, the four out of the plurality of first columnar electrodes 42, located at the respective corners of the semiconductor device A1 in plan view, are larger in plan-view area of the first top face 421, than the remaining first columnar electrodes 42.

The first exposed side face 423 and the first covered side face 424 are oriented to the outer side of the semiconductor device A1 from the first columnar electrode 42, as shown in FIG. 58. The first exposed side face 423 and the first covered side face 424 are located between the first top face 421 and the first contact surface 422, in the z-direction. The edge on the z2-side of the first exposed side face 423 is connected to the first top face 421, and the edge on the z1-side of the first covered side face 424 is connected to the first contact surface 422. The first exposed side face 423 is exposed from the resin member 70, and the first covered side face 424 is covered with the resin member 70. The size of the first exposed side face 423 in the z-direction is, for example, approximately 100 μm, and the size of the first covered side face 424 in the z-direction is, for example, approximately 60 μm to 90 μm.

The first connecting surface 425 is connected to the first exposed side face 423 and the first covered side face 424, as shown in FIG. 58. The first connecting surface 425 is exposed from the resin member 70. The first connecting surface 425 overlaps with the semiconductor element 10, as viewed in the x-direction or y-direction. The width of the first connecting surface 425 is, for example, approximately 15 μm. The width of the second connecting surface 415 refers to the length of a line segment between the edge of the first connecting surface 425 connected to the first exposed side face 423 and the edge connected to the first covered side face 424, and parallel to the x-direction or y-direction.

As shown in FIG. 50 and FIG. 51, the second top face 411 of each of the second columnar electrodes 41 is larger in plan-view area, than the first top face 421 of each of the first columnar electrodes 42. In the example shown in FIG. 50 and FIG. 51, the second top face 411 of each of the second columnar electrodes 41 extends farther into the semiconductor device A1, than the first top face 421 of each of the first columnar electrodes 42. Here, the plan-view area of the second top face 411 may be equal to or smaller than that of the first top face 421, without limitation to being larger.

The plurality of bonding sections 50 are for bonding the semiconductor element 10 to the plurality of wiring layers 30. The bonding sections 50 are, for example, formed of solder. The bonding sections 50 are, for example, what is known as a solder bump. The bonding sections 50 are, as shown in FIG. 59, each interposed between the element electrode 11 of the semiconductor element 10 and the wiring layer 30, to conductively bond these components.

The plurality of external electrodes 60 each serve as a terminal of the semiconductor device A1. The plurality of external electrodes 60 include, as shown in FIG. 50, FIG. 52, and FIG. 53, those covering the second top face 411 and the second exposed side face 413 of the second columnar electrodes 41, and those covering the first top face 421 and the first exposed side face 423 of the first columnar electrodes 42. The external electrodes 60 each include, for example, a nickel (Ni) layer, a palladium (Pd) layer, and a gold (Au) layer, stacked in this order from the side in contact with the second columnar electrode 41 or the first columnar electrode 42. Here, the Pd layer may be excluded. The external electrodes 60 can be formed, for example, through a non-electrolytic plating process.

The resin member 70 is formed on the substrate 20. The resin member 70 is a sealing material covering the semiconductor element 10, as shown in FIG. 54, FIG. 56, and FIG. 58. The resin member 70 is, for example, formed of a black epoxy resin. The resin member 70 may be formed of any electrically insulative resin material, without limitation to the epoxy resin. The resin member 70 can be formed, for example, through a molding process. The resin member 70 has, for example, a rectangular shape in plan view. The resin member 70 includes a resin obverse face 71, a resin reverse face 72, a plurality of first resin side faces 731, a plurality of second resin side faces 732, and a plurality of resin connecting surfaces 733.

The resin obverse face 71 and the resin reverse face 72 are spaced apart from each other in the z-direction, as shown in FIG. 54, FIG. 56, and FIG. 58. The resin obverse face 71 is oriented to the z2-side, and the resin reverse face 72 is oriented to the z1-side. The resin obverse face 71 is flat. The resin obverse face 71 is flush with the second top faces 411 (second columnar electrodes 41) and the first top faces 421 (first columnar electrodes 42). The second top faces 411 and the first top faces 421 are exposed from the resin obverse face 71. When the semiconductor device A1 is mounted on the circuit board, the resin obverse face 71 is opposed to the circuit board. The resin reverse face 72 is in contact with the insulation film 29.

The plurality of first resin side faces 731 and the plurality of second resin side faces 732 are each located between the resin obverse face 71 and the resin reverse face 72 in the z-direction, as shown in FIG. 54 to FIG. 58. The plurality of first resin side faces 731 and the plurality of second resin side faces 732 are flat. The edge on the z2-side of each of the first resin side faces 731 is connected to the resin obverse face 71, and the edge on the z1-side of each of the second resin side faces 732 is connected to the resin reverse face 72. The size of each of the first resin side faces 731 in the z-direction is, for example, approximately 100 μm, and the size of each of the second resin side faces 732 in the z-direction is, for example, approximately 90 μm. The first resin side faces 731 are each flush with the second exposed side faces 413 (second columnar electrodes 41) or the first exposed side faces 423 (first columnar electrodes 42). The second exposed side faces 413 and the first exposed side faces 423 are exposed from the first resin side face 731. The second resin side faces 732 are each flush with the first substrate side face 203. The second resin side faces 732 each include a portion overlapping with the second covered side faces 414 (second columnar electrodes 41) or the first covered side faces 424 (first columnar electrodes 42), as viewed in the x-direction or y-direction.

The resin member 70 includes, as shown in FIG. 50, a pair of first resin side face 731 and second resin side face 732 each oriented to the x1-side, a pair of first resin side face 731 and second resin side face 732 each oriented to the x2-side, a pair of first resin side face 731 and second resin side face 732 each oriented to the y1-side, and a pair of first resin side face 731 and second resin side face 732 each oriented to the y2-side. In each of such pairs, the first resin side face 731 is located on the inner side of the second resin side face 732, in plan view.

The plurality of resin connecting surfaces 733 are each connected to the pair of first resin side face 731 and second resin side face 732, as shown in FIG. 55 and FIG. 57. The resin connecting surfaces 733 are each oriented to the z2-side. For example, the resin connecting surfaces 733 may be flat. The resin connecting surfaces 733 may be inclined or curved, with respect to the x-y plane. The resin connecting surfaces 733 are flush with the second connecting surfaces 415 (second columnar electrodes 41) and the first connecting surfaces 425 (first columnar electrodes 42). The second connecting surfaces 415 and the first connecting surfaces 425 are exposed from the resin connecting surface 733. The resin connecting surfaces 733 each overlap with the semiconductor element 10, as viewed in the x-direction or y-direction. The width d3 of the resin connecting surface 733 (see FIG. 55) is, for example, approximately 45 μm. The width d3 of the resin connecting surface 733 refers to the length of a line segment between the edge of the resin connecting surface 733 connected to the first resin side face 731 and the edge connected to the second resin side face 732, and parallel to the x-direction or y-direction. In the semiconductor device A1, since the width d2 of the second connecting surface 415 (see FIG. 57) is for example approximately 15 μm, the separation distance d4 (see FIG. 57) between the second resin side face 732 and the second covered side face 414 in plan view is, for example, approximately 30 μm. This also applies to the separation distance between the second resin side face 732 and the first covered side face 424.

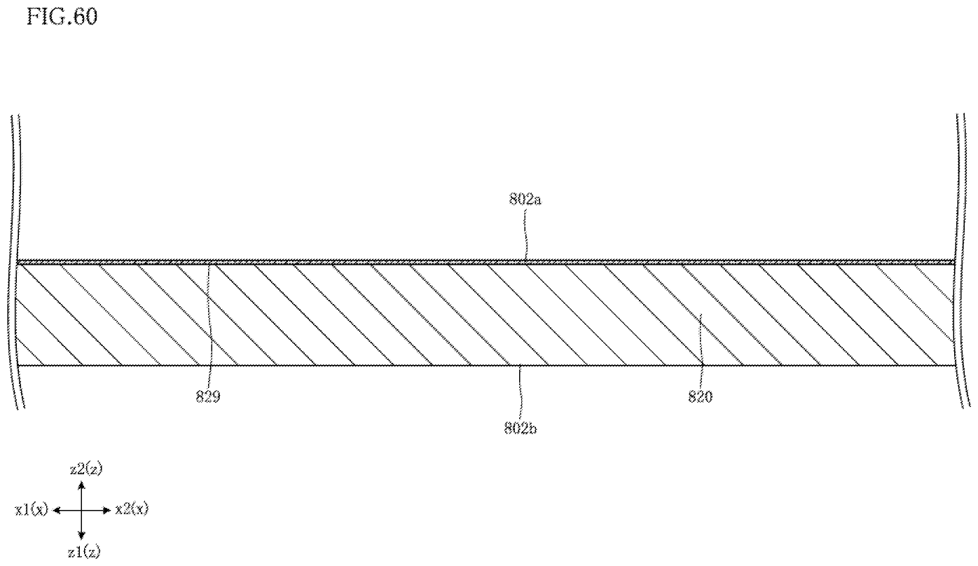

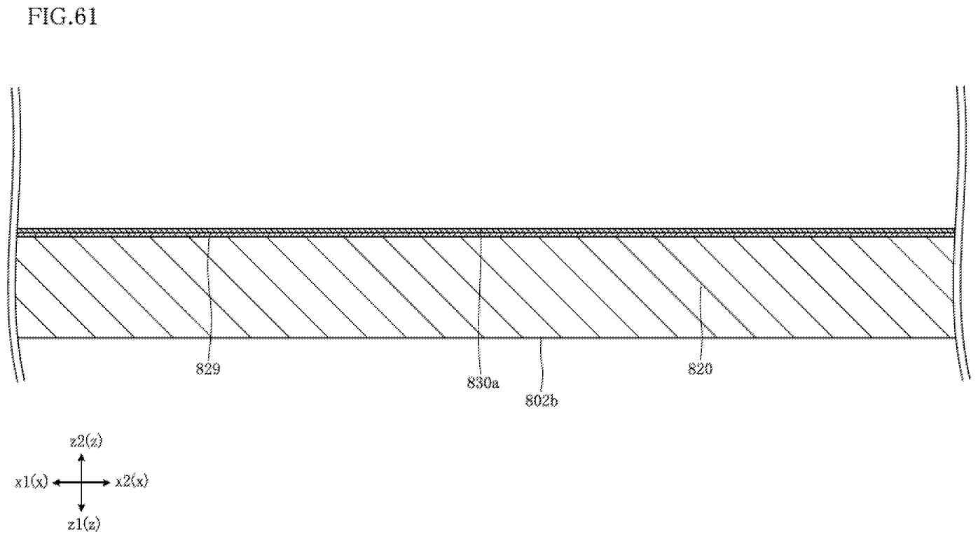

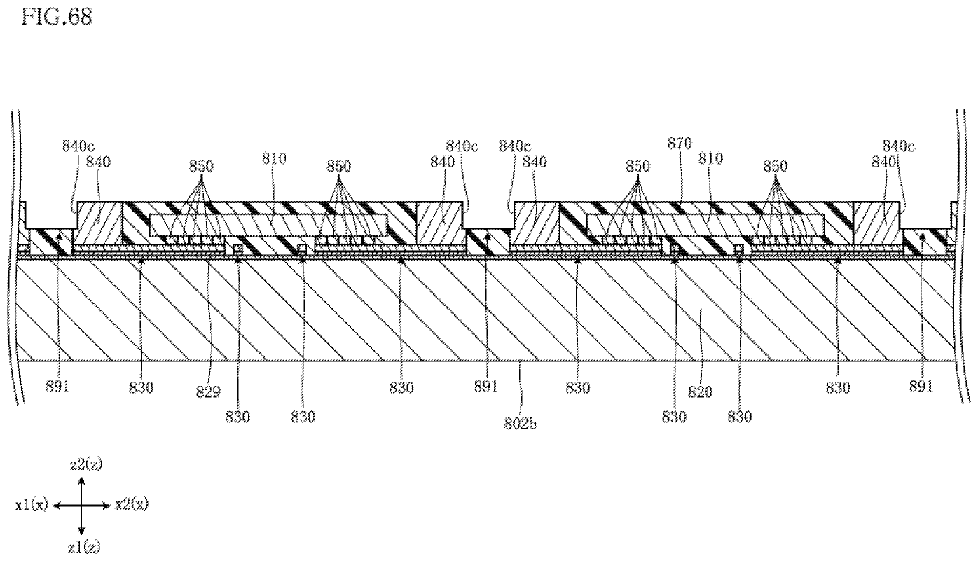

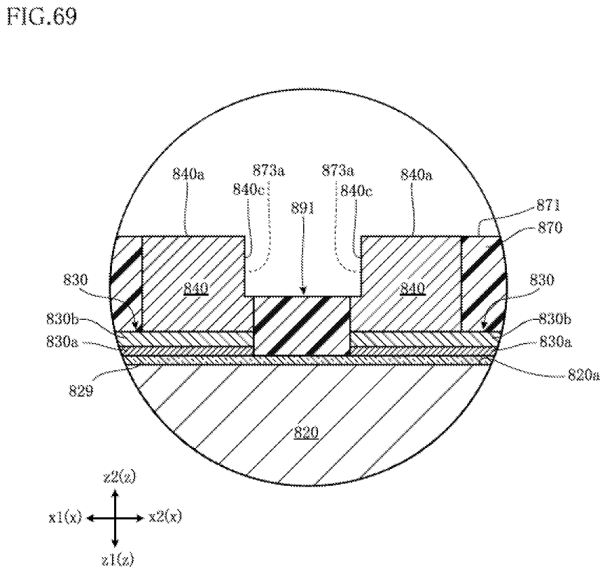

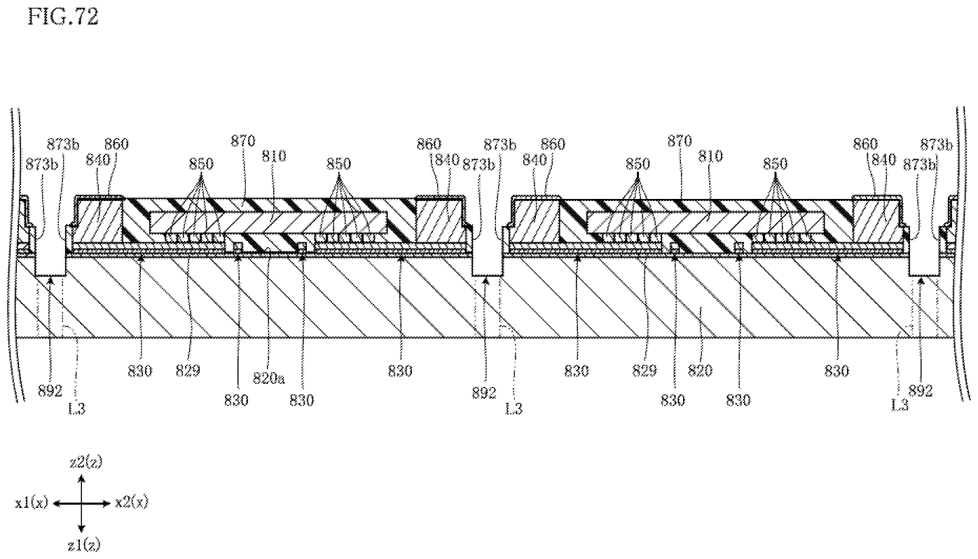

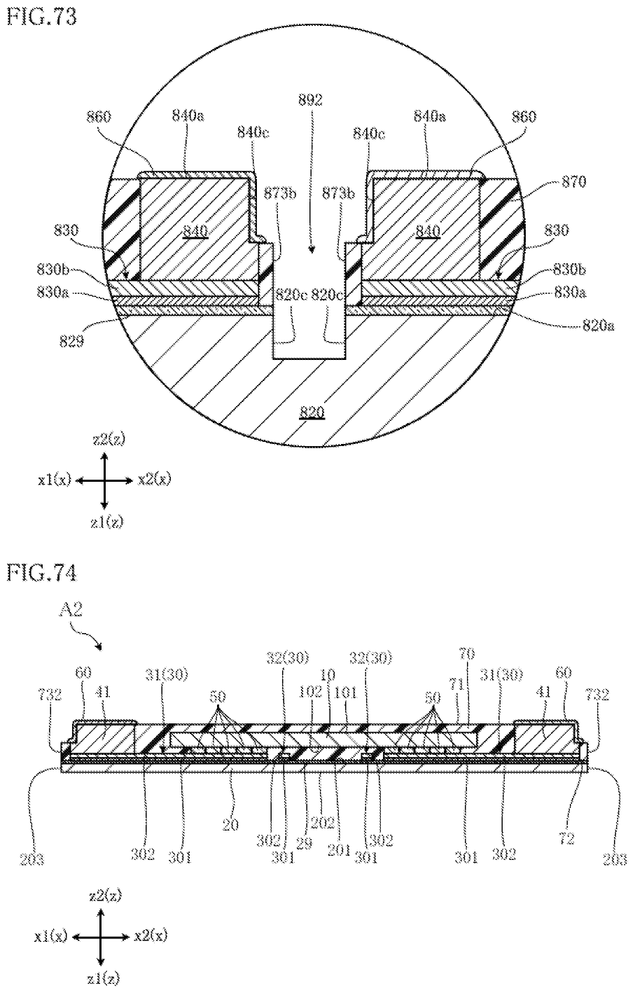

Referring now to FIG. 60 to FIG. 73, a manufacturing method of the semiconductor device A1 according to the first embodiment of the second aspect will be described hereunder. The manufacturing method described hereunder is for manufacturing a plurality of semiconductor devices A1. FIG. 60 to FIG. 73 are cross-sectional views each showing a process in the manufacturing method of the semiconductor device A1, and correspond to the cross-sectional view of FIG. 56 showing the semiconductor device A1, except FIG. 69 and FIG. 73. FIG. 69 is a partially enlarged cross-sectional view from FIG. 68, and FIG. 73 is a partially enlarged cross-sectional view from FIG. 72.

Referring first to FIG. 60, a substrate 820 is prepared, and an insulation film 829 is formed on the substrate 820. The substrate 820 is formed of a monocrystalline intrinsic semiconductor material. The intrinsic semiconductor material may be, for example, Si. In the process of preparing the substrate 820 (substrate preparation process), for example a Si wafer is prepared as the substrate 820. The substrate 820 includes a substrate obverse face 820a and a substrate reverse face 820b spaced apart from each other in the z-direction. The substrate obverse face 820a is oriented to the z2-side, and the substrate reverse face 820b is oriented to the z1-side. In the process of forming the insulation film 829 (insulation film formation process), the insulation film 829 is formed on the substrate obverse face 820a, as shown in FIG. 60. The insulation film 829 can be formed, by depositing an oxide film (e.g., SiO₂) on the substrate obverse face 820a of the substrate 820 by thermal oxidation, and then depositing a nitride film (Si₃N₄) on the oxide film, by plasma chemical vapor deposition (CVD).

Turning to FIG. 61, an underlying layer 830a is formed so as to cover the insulation film 829. In the process of forming the underlying layer 830a (underlying layer formation process), the underlying layer 830a is formed by depositing a barrier layer over the entire surface of the insulation film 829 by a sputtering method, and depositing a seed layer on the barrier layer by the sputtering method. The barrier layer is, for example, formed of Ti in a thickness of 100 nm to 300 nm, and the seed layer is, for example, formed of Cu in a thickness of 200 nm to 600 nm.

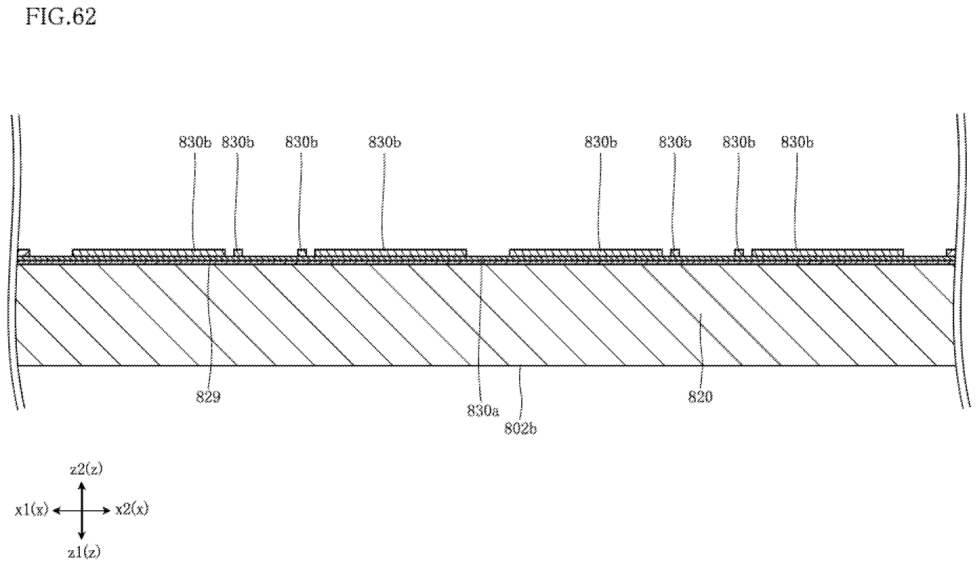

Turning to FIG. 62, a plurality of plated layers 830b are formed. In the process of forming the plurality of plated layers 830b (plated layer formation process), the plurality of plated layers 830b are formed by applying a lithographic pattern on the underlying layer 830a, and performing an electrolytic plating process using the underlying layer 830a as the conduction path. The plated layer 830b is, for example, formed of Cu in a thickness of 5 μm to 25 μm.

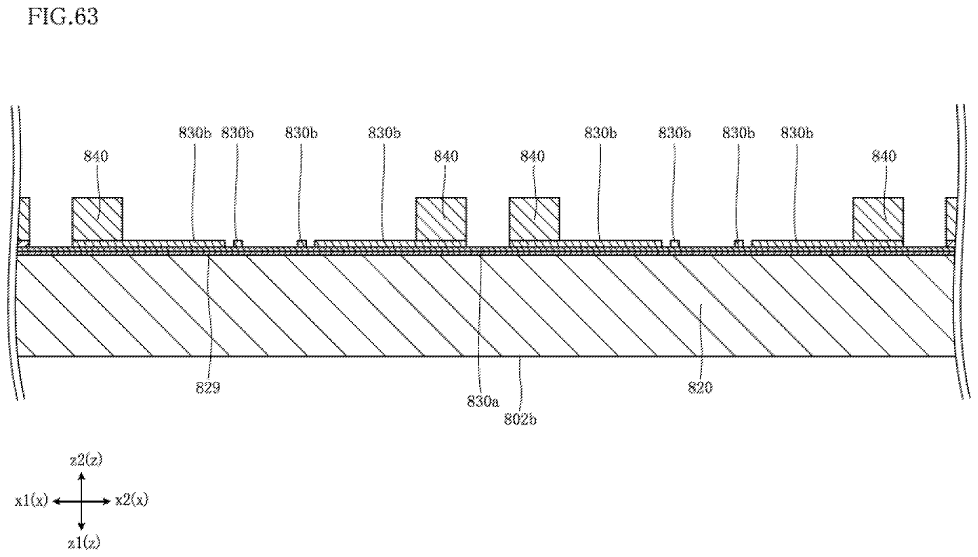

Turning to FIG. 63, a plurality of columnar electrodes 840 are formed on the plurality of plated layers 830b. The columnar electrodes 840 each correspond to one of the second columnar electrode 41 and the first columnar electrode 42 of the semiconductor device A1. In the process of forming the plurality of columnar electrodes 840 (columnar electrode formation process), the plurality of columnar electrodes 840 are formed by applying a lithographic pattern on a part of the underlying layer 830a and a part of the plated layer 830b, and performing the electrolytic plating process using the underlying layer 830a and the plated layer 830b as the conduction path. The plurality of columnar electrodes 840 are, for example, formed of Cu. The plurality of columnar electrodes 840 include those to be subsequently formed into the plurality of second columnar electrodes 41, and those to be subsequently formed into the plurality of first columnar electrodes 42. Since FIG. 63 is the cross-sectional view corresponding to FIG. 56, the plurality of columnar electrodes 840 shown in FIG. 63 are all to be subsequently formed into the plurality of second columnar electrodes 41 of the semiconductor device A1.

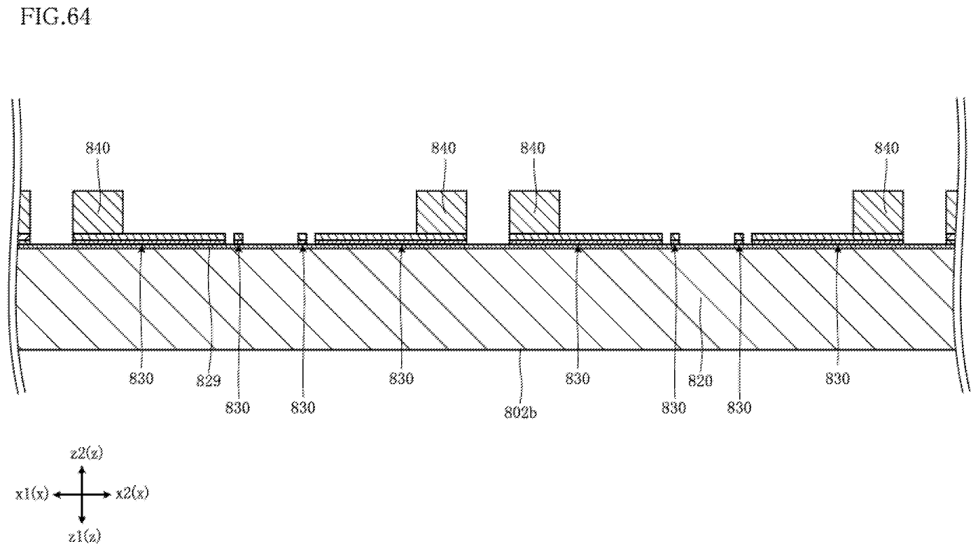

Turning to FIG. 64, a part of the underlying layer 830a is removed. The part of the underlying layer 830a to be removed is the region where the plurality of plated layers 830b are not formed. In the process of removing the underlying layer 830a (underlying layer removing process), the underlying layer 830a is removed by a wet etching method using mixed solution of sulfuric acid (H₂SO₄) and hydrogen peroxide (H₂O₂). Through the mentioned process, the residual portion of the plurality of underlying layers 830a and the plurality of plated layers 830b stacked thereon constitute the plurality of wiring layers 830. The plurality of wiring layers 830 correspond to the plurality of wiring layers 30 of the semiconductor device A1. The plurality of wiring layers 830 include those to be subsequently formed into the plurality of wiring sections 31, and those to be subsequently formed into the plurality of wiring sections 32. The plurality of wiring layers 830 each having the columnar electrode 840 formed thereon are subsequently formed into the plurality of wiring sections 31, and the plurality of wiring layers 830 without the columnar electrode 840 are subsequently formed into the plurality of wiring sections 32.

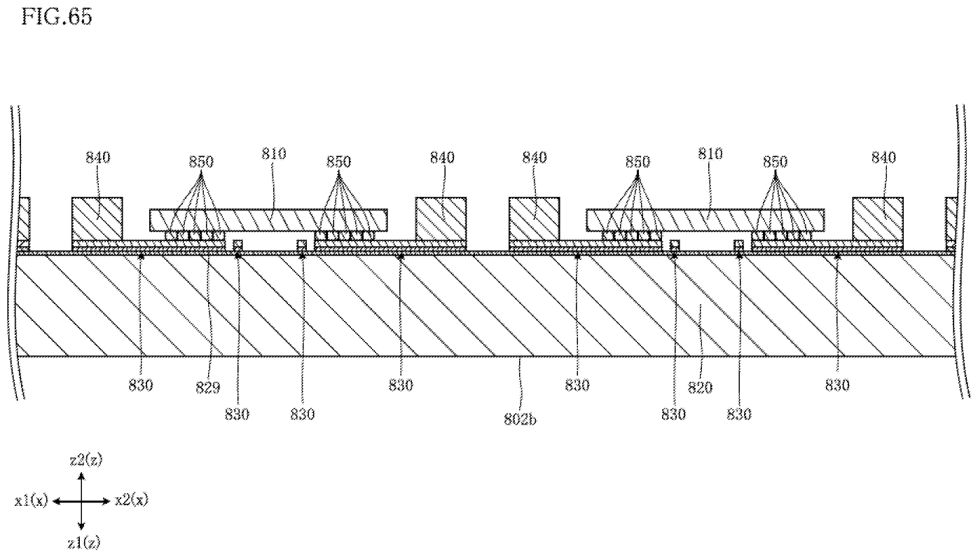

Turning to FIG. 65, a semiconductor element 810 is mounted. The semiconductor element 810 corresponds to the semiconductor element 10 of the semiconductor device A1. The semiconductor element 810 includes an element obverse face 810a oriented to the z2-side and an element reverse face 810b oriented to the z1-side, and an element electrode (not shown) is formed on the element reverse face 810b. On each of the plurality of element electrodes of the semiconductor element 810, a bonding material 850 is formed. The bonding material 850 is, for example, a ball-shaped solder bump. In the process of mounting the semiconductor element 810 (element mounting process), the bonding material 850 (solder bump) is made to contact the wiring layer 830, and the bonding material 85 (solder bump) is heated in a reflow device. Then the bonding material 850 is cooled so as to be solidified, so that the element electrodes of the semiconductor element 810 and the wiring layers 830 are conductively bonded to each other, via the bonding material 850 (solder bump).

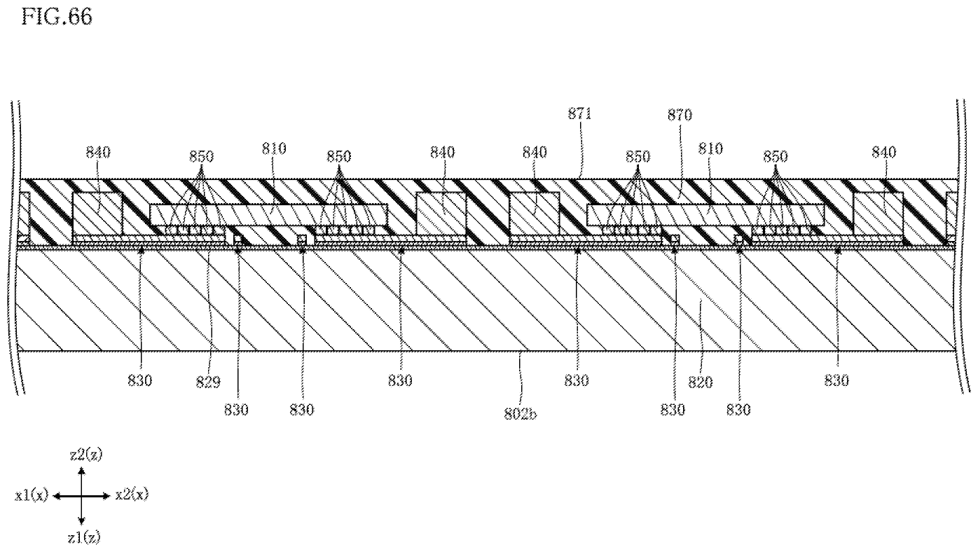

Turning to FIG. 66, a resin member 870 is formed. In the process of forming the resin member 870 (resin formation process), for example a molding process is employed. The molding method may be transfer molding, or compression molding. The resin member 870 is, for example, formed of a material containing a black epoxy resin. The resin member 870 formed through the resin formation process is located on the insulation film 829 (substrate obverse face 820a of the substrate 820), and covers the semiconductor element 810. In addition, the face of the resin member 870 oriented to the z2-side (resin obverse face 871) is located ahead of the face of the columnar electrodes 840 oriented to the z2-side. In other words, the columnar electrodes 840 are covered with the resin member 870, immediately after the resin formation process.

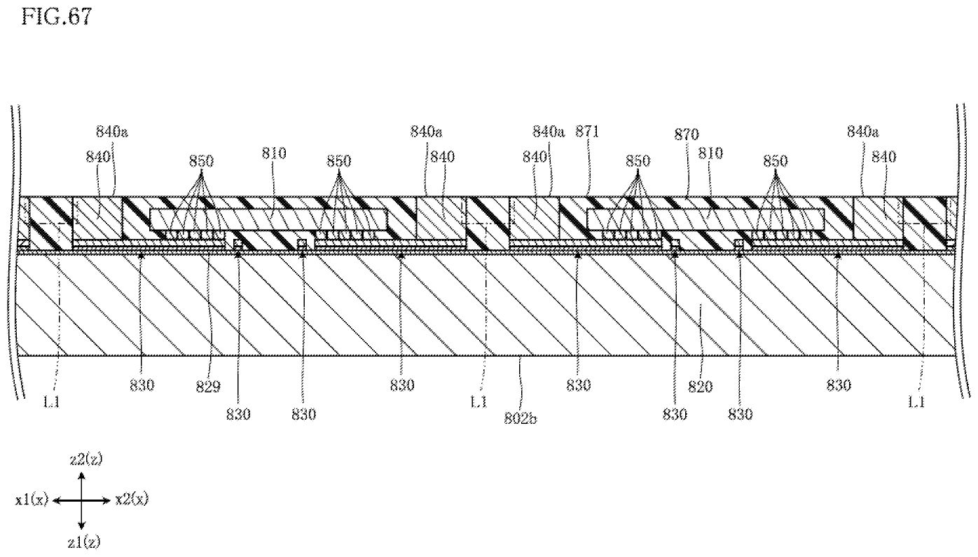

Turning to FIG. 67, the resin member 870 is ground so as to expose the columnar electrodes 840 from the resin obverse face 871. In the process of grinding the resin member 870 (resin grinding process), for example a mechanical grinding machine is employed, to grind the resin member 870 toward the z1-side from the resin obverse face 871, with a grinding stone. In this process, the resin member 870 is ground until the columnar electrodes 840 are exposed from the resin obverse face 871. In the resin grinding process, the plurality of columnar electrodes 840 are also partially removed. Through the resin grinding process, the thickness of the resin member 870 is reduced. In addition, a top face 840a exposed from the resin member 870 appears, on each of the plurality of columnar electrodes 840. The resin obverse face 871 and the respective top faces 840a of the columnar electrodes 840 are flush with each other, and grinding marks resultant from the grinding operation are formed so as to stride over the resin obverse face 871 and the top faces 840a.

Turning to FIG. 68 and FIG. 69, a plurality of first cutaway portions 891 are formed. To be more detailed, the plurality of first cutaway portions 891 are formed by cutting the plurality of columnar electrodes 840 and the resin member 870 to a halfway position thereof in the thickness direction (z-direction). The process of forming the plurality of first cutaway portions 891 (first cutting process) is, for example, a half-cut dicing process using a dicing blade. In the first cutting process, the plurality of first cutaway portions 891 are formed by performing the half-cut dicing, for example along cutting lines L1 shown in FIG. 67. In FIG. 67, the cutting line L1 is illustrated in a rectangular shape, in consideration of the thickness of the dicing blade to be employed. The width of each of the plurality of first cutaway portions 891 formed through the first cutting process is, for example, approximately 180 μm. This width is determined depending on the thickness of the dicing blade to be employed. As result of the first cutting process, a part of each of the columnar electrodes 840 is scraped off, and exposed side faces 840c connected to the top face 840a appear. In addition, a part of the resin member 870 is scraped off, and first resin side faces 873a connected to the resin obverse face 871 appear.

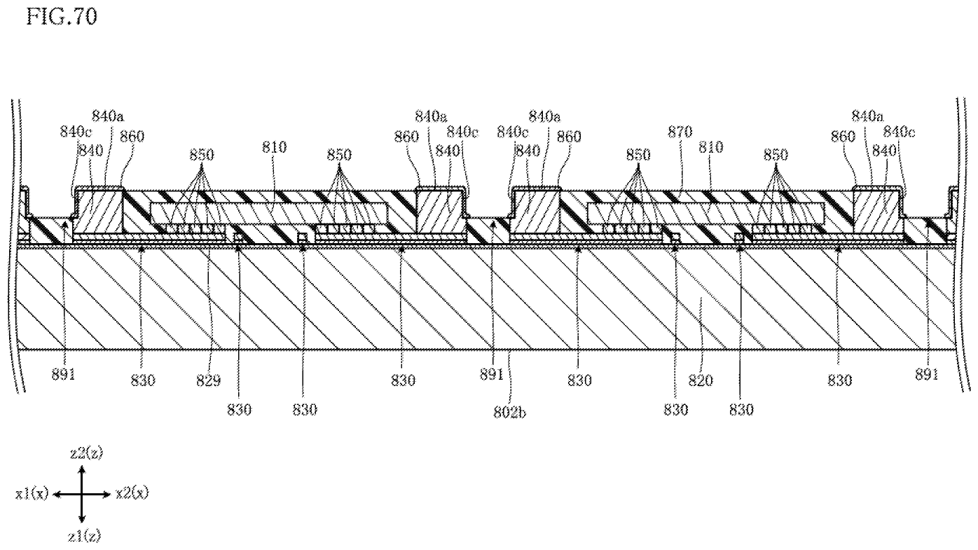

Turning to FIG. 70, external electrodes 860 are formed. In the process of forming the external electrode 860 (external electrode formation process), for example a Ni layer, a Pd layer, and an Au layer are sequentially precipitated through a non-electrolytic plating process, to thereby form the external electrodes 860. To be more detailed, this process includes forming the Ni layer so as to cover the top face 840a and the exposed side face 840c of each of the columnar electrodes 840, in contact therewith, forming the Pd layer on the Ni layer, and forming the Au layer on the Pd layer. The external electrode 860 may only include the Ni layer and the Au layer, instead of the Ni layer, the Pd layer, and the Au layer.

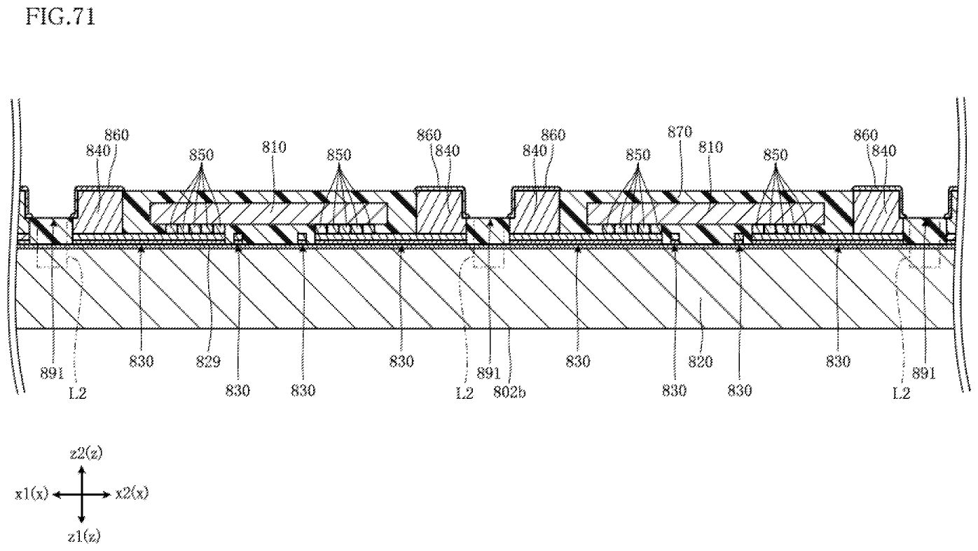

Turning to FIG. 71, a part of the substrate 820 is ground. In the process of grinding the substrate 820 (substrate grinding process), for example a mechanical grinding machine is employed, to grind the substrate 820 toward the z2-side from the substrate reverse face 820b, with a grinding stone. Accordingly, the thickness of the substrate 820 is reduced. On the substrate reverse face 820b, grinding marks resultant from the grinding operation are formed. It is preferable to perform the substrate grinding process after the external electrode formation process, to stably transport the semi-finished semiconductor device to the non-electrolytic plating tank, in the mentioned external electrode formation process.

Turning to FIG. 72 and FIG. 73, a plurality of second cutaway portions 892 are further formed, in the respective first cutaway portions 891 formed through the first cutting process. To be more detailed, the plurality of second cutaway portions 892 are formed by completely cutting the resin member 870 in the z-direction in each of the plurality of first cutaway portions 891, and cutting the substrate 820 to a halfway position thereof in the thickness direction (s-direction). In the process of forming the plurality of second cutaway portions 892 (second cutting process), as in the first cutting process, the half-cut dicing is performed with the dicing blade. In the second cutting process, the plurality of second cutaway portions 892 are formed by performing the half-cut dicing, for example along cutting lines L2 shown in FIG. 71. In FIG. 71, the cutting line L2 is illustrated in a rectangular shape, in consideration of the thickness of the dicing blade to be employed. The width of each of the plurality of second cutaway portions 892 formed through the second cutting process is, for example, approximately 90 μm. This width is determined depending on the thickness of the dicing blade to be employed. As result of the second cutting process, the resin member 870 is cut in the z-direction, into a plurality of pieces each including the semiconductor element 10. After the second cutting process, the second resin side face 873b appears in the resin member 870. After the second cutting process, further, the first substrate side face 820c connected to the substrate obverse face 820a appears in the substrate 820. The second resin side face 873b and the first substrate side face 820c are flush with each other.

Then the substrate 820 is divided into a plurality of individual pieces, each including the semiconductor element 10. In the process of dividing into individual pieces (third cutting process), the substrate 820 is cut in the z-direction at each of the plurality of second cutaway portions 892, for example by blade dicing, along cutting lines L3 shown in FIG. 72. The thickness of the dicing blade used in the third cutting process is, for example, approximately 70 μm. In FIG. 72, the cutting line L3 is illustrated in a rectangular shape, in consideration of the thickness of the dicing blade to be employed. Here, the cutting method is not limited to the blade dicing, but a different dicing method such as laser dicing or plasma dicing may be employed. As result of the third cutting process, the substrate 820 is cut in the z-direction. At this point, the second substrate side face (second substrate side face 204 of the semiconductor device A1), located on the outer side of the first substrate side face 820c in plan view, is formed in the substrate 820. Each of the individual pieces divided in the third cutting process corresponds to the semiconductor device A1 shown in FIG. 49 to FIG. 59.

The semiconductor device A1 can be manufactured through the foregoing process. More specifically, the manufacturing method of the semiconductor device A1 includes the substrate preparation process, the insulation film formation process, the underlying layer formation process, the plated layer formation process, the columnar electrode formation process, the underlying layer removing process, the element mounting process, the resin formation process, the resin grinding process, the first cutting process, the external electrode formation process, the substrate grinding process, the second cutting process, and the third cutting process. The underlying layer formation process, the plated layer formation process, and the underlying layer removing process may be collectively referred to as “wiring layer formation process”. The foregoing manufacturing method of the semiconductor device A1 is merely exemplary. For example, the plurality of columnar electrodes 840 to be subsequently formed into the plurality of second columnar electrodes 41, and the plurality of columnar electrodes 840 to be subsequently formed into the plurality of first columnar electrodes 42 may be formed through separate processes, in the columnar electrode formation process. In addition, the substrate grinding process may be skipped.

The semiconductor device A1 and the manufacturing method thereof provide the following advantageous effects.

The semiconductor device A1 includes the first columnar electrode 42 and the resin member 70. The resin member 70 includes the first resin side face 731 and the second resin side face 732. The first resin side face 731 is located on the inner side of the second resin side face 732, in plan view. The first columnar electrode 42 includes the first exposed side face 423. The first exposed side face 423 is exposed from the resin member 70, in the first resin side face 731. With such a configuration, the side face of the semiconductor device A1 includes a stepped portion, and the first columnar electrode 42 is exposed from the resin member 70, in the recessed portion of the stepped portion. Accordingly, when the semiconductor device A1 is mounted on a circuit board of an electronic device or the like, with the mount solder, a solder fillet is formed so as to cover the first exposed side face 423. Because of the presence of the solder fillet, the bonding condition of the semiconductor device A1 (bonding condition of the mount solder) can be visually checked, without the need to employ X-ray inspection equipment. Consequently, the semiconductor device A1 makes it easy to check the bonding condition of the mount solder.

In the semiconductor device A1, the separation distance d4 (see FIG. 57) is longer than the width d2 of the second connecting surface 415 (see FIG. 57). With such a configuration, the portion of the resin member 70 covering the second covered side face 414 (second columnar electrode 41) is given an appropriate thickness (size in the x-direction or y-direction), and therefore the resin member 70 can be prevented from being separated from the second columnar electrode 41. Consequently, the reliability of the semiconductor device A1 can improved. Likewise, since the separation distance d4 is longer than the width of the first connecting surface 425, the resin member 70 can be prevented from being separated from the first columnar electrode 42.

In the semiconductor device A1, the respective second top faces 411 of the second columnar electrodes 41 are larger in plan-view area, than the respective top faces 421 of the first columnar electrodes 42. With such a configuration, the electrical resistance of the second columnar electrodes 41 becomes lower than that of the first columnar electrodes 42, and therefore the second columnar electrodes 41 can accept a relatively larger current, compared with the first columnar electrode 42. In the semiconductor device A1, for example, the second columnar electrodes 41 are each electrically connected to the element electrode 11, serving as the power terminal or ground terminal of the semiconductor element 10, via the wiring section 31. The first columnar electrodes 42 are each electrically connected to the element electrode 11, serving as the terminal other than the power terminal or ground terminal (e.g., signal terminal) of the semiconductor element 10, via the wiring section 32. The power terminal or the ground terminal can accept a relatively larger current, compared with other terminals. Consequently, in the semiconductor device A1, a conduction loss, for example originating from parasitic capacitance, can be suppressed.

In the semiconductor device A1, the first columnar electrodes 42 (first top face 421) respectively located at the four corners in plan view are larger in plan-view area, than the remaining first columnar electrodes 42 (first top face 421). The temperature in the semiconductor device A1 fluctuates, owing to the operation thereof and the external environment. When the semiconductor device A1 is mounted on a circuit board of an electronic device or the like, with the mount solder, the mount solder bonding the semiconductor device A1 and the circuit board to each other is subjected to thermal stress, owing to the fluctuation in temperature. The thermal stress originates from a difference in thermal contraction between the circuit board and the semiconductor device A1. When the mount solder is repeatedly subjected to the thermal stress, the mount solder may suffer a crack. In particular, when the semiconductor device A1 is mounted on the circuit board, relatively larger thermal stress is applied to the mount solder located at the four corners of the semiconductor device A1. In the semiconductor device A1, therefore, the first columnar electrodes 42 (first top faces 421) located at the four corners are made larger in plan-view area than the remaining first columnar electrodes 42 (first top faces 421), to improve the bonding strength of the mount solder at the four corners. Consequently, the resistance against temperature cycle can be improved, in the semiconductor device A1.

The manufacturing method of the semiconductor device A1 includes the first cutting process and the second cutting process. In the first cutting process, the plurality of columnar electrodes 840 and the resin member 870 are cut at a time. In the second cutting process, the resin member 870 and the substrate 820 are cut at a time. Accordingly, in the manufacturing method of the semiconductor device A1 includes two cutting processes, namely the first cutting process and the second cutting process, so that the plurality of columnar electrodes 840 and the substrate 820 are kept from being cut at a time. It is difficult to cut the plurality of columnar electrodes 840 and the substrate 820 at a time, because of the difference in material. However, since the semiconductor device A1 is manufactured without cutting the plurality of columnar electrodes 840 and the substrate 820 at a time, the semiconductor device A1 can be manufactured free from technical difficulty.

In the semiconductor device A1, the first substrate side faces 203 are smaller in size in the z-direction, than the second substrate side faces 204. As described above, the first substrate side faces 203, in other words the first substrate side faces 820c, are formed in the second cutting process where the resin member 870 and the substrate 820 are diced at a time. In contrast, the second substrate side faces 204 are formed in the third cutting process, where only the substrate 820 is diced. In general, higher processing accuracy and higher processing speed can be attained, when a single type of material is diced, than when two types of materials are diced. Accordingly, by making the size of the first substrate side faces 203 in the z-direction smaller than that of the second substrate side faces 204, a smaller amount of the substrate 820 is diced away in the second cutting process, than in the third cutting process. Therefore, with the manufacturing method of the semiconductor device A1, higher processing accuracy and higher processing speed can be attained, in the dicing process of the substrate 820.

### Second Embodiment (Second Aspect)

FIG. 74 illustrates a semiconductor device A2 according to a second embodiment of the second aspect. FIG. 74 is a cross-sectional view showing the semiconductor device A2, corresponding to the cross-section of the semiconductor device A1 shown in FIG. 56.

The semiconductor device A2 is different from the semiconductor device A1, in that the substrate 20 is without the plurality of second substrate side faces 204. In other words, the side face of the substrate 20 is without the stepped portion. In addition, the substrate 20 of the semiconductor device A2 is smaller in thickness (size in the z-direction) than the substrate 20 of the semiconductor device A1. Accordingly, the semiconductor device A2 can be made thinner than the semiconductor device A1.

The semiconductor device A2 can be manufactured, for example, by grinding off a larger amount of the substrate 820, in the substrate grinding process of the manufacturing method of the semiconductor device A1. In the manufacturing method of the semiconductor device A2, the resin member 870 is completely cut, and the substrate 820 is also completely cut, in the second cutting process. As result, the substrate 820 is divided into the individual pieces each including the semiconductor element 10, and the semiconductor device A2 is obtained. Therefore, the third cutting process is skipped.

In the semiconductor device A2 also, as in the semiconductor device A1, the side face of the semiconductor device A2 includes a stepped portion, and a part of the first columnar electrode 42 is exposed, in the recessed portion of the stepped portion. Accordingly, the semiconductor device A2 enables, like the semiconductor device A1, the bonding condition of the mount solder to be visually checked. Consequently, the semiconductor device A2 makes it easy to check the bonding condition of the mount solder.

### Third Embodiment (Second Aspect)

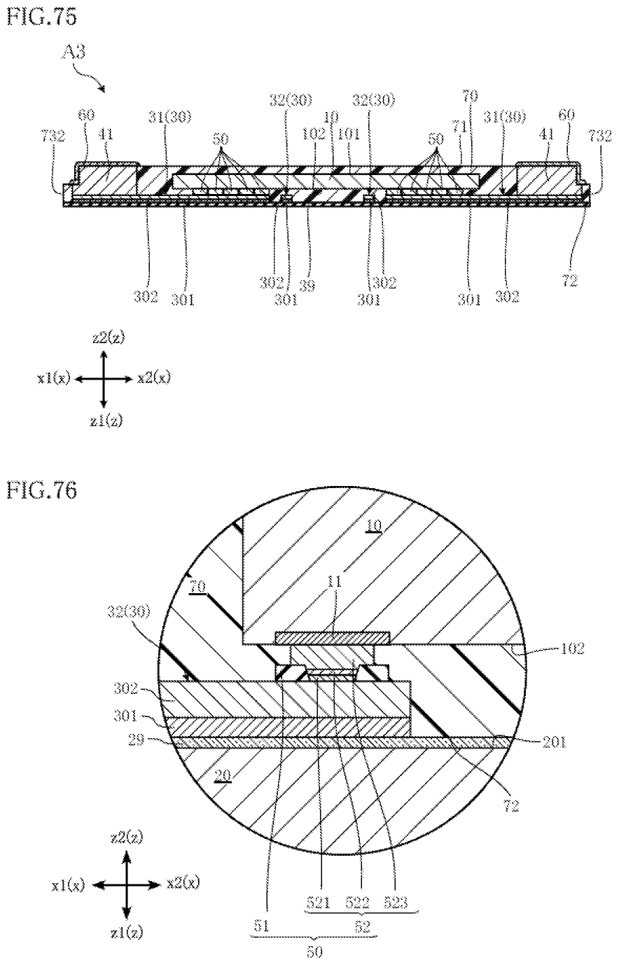

FIG. 75 illustrates a semiconductor device A3 according to a third embodiment of the second aspect. The semiconductor device A3 is without the substrate 20, unlike the semiconductor device A1. FIG. 75 is a cross-sectional view showing the semiconductor device A3, corresponding to the cross-section of the semiconductor device A1 shown in FIG. 56.

The semiconductor device A3 can be manufactured, for example, by completely grinding off the substrate 820 (removing the entirety of the substrate 820), in the substrate grinding process of the manufacturing method of the semiconductor device A1. At this point, the insulation film 829 may also be removed at a time, or be left unremoved. FIG. 75 illustrates the example where the insulation film 829 has also been removed, and therefore the semiconductor device A3 is without the insulation film 29.

As described above, the semiconductor device A3 shown in FIG. 75 is without the insulation film 29. Therefore, the wiring layers 30 are exposed from the resin member 70 (resin reverse face 72). When the wiring layers 30 are exposed from the resin member 70, an accidental short circuit may occur between a plurality of wiring layers 30. Accordingly, in the semiconductor device A3 without the insulation film 29, it is preferable to form a protective film 39, so as to cover at least the portion of the wiring layers 30 exposed from the resin reverse face 72, as shown in FIG. 75. In the example shown in FIG. 75, the protective film 39 is formed all over the resin reverse face 72, so as to stride over the plurality of wiring layers 30. The protective film 39 may be formed of, for example, an insulative material such a polyimide resin or a phenol resin.

In the semiconductor device A3 also, as in the semiconductor device A1, the side face of the semiconductor device A3 includes a stepped portion, and a part of the first columnar electrode 42 is exposed, in the recessed portion of the stepped portion. Accordingly, the semiconductor device A3 enables, like the semiconductor device A1, the bonding condition of the mount solder to be visually checked. Consequently, the semiconductor device A3 makes it easy to check the bonding condition of the mount solder.

Since the semiconductor device A3 is without the substrate 20, the semiconductor device A3 can be made even thinner, than the semiconductor device A2.

In the first to the third embodiments of the second aspect, the configuration of the bonding section 50 is not limited to the above. FIG. 76 illustrates the bonding section 50 according to a variation. FIG. 76 is a partially enlarged cross-sectional view showing the bonding section 50, corresponding to the partially enlarged cross-sectional view of FIG. 59.

The bonding section 50 according to this variation is applicable to any of the semiconductor devices A1 to A3. The plurality of bonding sections 50 according to this variation each include a protective layer 51 and a bonding layer 52, as shown in FIG. 76.

In each of the bonding sections 50, the protective layer 51 is formed on the wiring layer 30, as shown in FIG. 76. The protective layers 51 are each formed in a frame shape with an opening at the center, in plan view. The protective layers 51 each surround the bonding layer 52, in plan view. The protective layers 51 each have, for example, a rectangular annular shape in plan view. The plan-view annular shape of the protective layer 51 is not limited to the rectangular annular shape, but may be a circular annular shape, an elliptical annular shape, or a polygonal annular shape. The protective layers 51 are, for example, formed of a polyimide resin, without limitation thereto.

In each of the bonding sections 50, the bonding layer 52 serves to conductively bond the element electrode 11 of the semiconductor element 10 and the wiring layer 30 to each other. The bonding layers 52 are each formed on the wiring layer 30 (plated layer 302). The bonding layer 52 covers the surface of the opening in the protective layer 51. A part of the bonding layer 52 is filled in in the opening of the protective layer 51.

The bonding layers 52 each include, as shown in FIG. 76, a first layer 521, a second layer 522, and a third layer 523 stacked on each other. The first layer 521 is formed on the wiring layer 30 (plated layer 302), in contact with the plated layer 302. The first layer 521 is, for example, formed of a metal containing Cu. The second layer 522 is formed on the first layer 521, in contact therewith. The second layer 522 is, for example, formed of a metal containing Ni. The third layer 523 is formed on the second layer 522, in contact therewith. The third layer 523 is also in contact with the element electrode 11 of the semiconductor element 10. The third layer 523 is, for example, formed of an alloy containing Sn. Examples of such alloy include a lead-free solder such as a Sn—Sb alloy or a Sn—Ag alloy. The configuration of the bonding layer 52 is not limited to the above, provided that the element electrode 11 of the semiconductor element 10 and the wiring layer 30 can be conductively bonded to each other.

The plurality of bonding sections 50 according to this variation each include the protective layer 51, surrounding the bonding layer 52 in plan view. Such a configuration prevents a part of the bonding layer 52 (third layer 523, in the example of FIG. 76) from spreading to an undesired region, when the bonding layer 52 is molten by the heat of the reflow operation in the element mounting process. Accordingly, for example an accidental short circuit between the plurality of element electrodes 11, and between the plurality of wiring layers 30 can be prevented, and therefore a malfunction of the semiconductor device A1 to A3 can be prevented.

In the example shown in FIG. 76, the element electrode 11 is not protruding from the element reverse face 102. However, in the case where the element electrode 11 is formed so as to protrude from the element reverse face 102, unlike in the foregoing example, the protective layer 51 facilitates the element electrode 11 to self-align with the wiring layer 30.

The semiconductor device according to the second aspect of the present disclosure, and the manufacturing method thereof, are not limited to the foregoing embodiments. The specific configuration of the elements of the semiconductor device, and the specific processes in the manufacturing method of the semiconductor device may be modified as desired. The technical ideas that can be perceived from the embodiments of the second aspect and the variations thereof will be described in the following clauses.

Clause E1.

A semiconductor device including:
a semiconductor element formed with an element electrode;
a wiring layer located on one side of the semiconductor element, in a thickness direction of the semiconductor element, and electrically connected to the element electrode;
a first columnar electrode protruding from the wiring layer to the other side in the thickness direction; and
a resin member covering the semiconductor element,
in which the resin member includes a resin obverse face and a resin reverse face spaced apart from each other in the thickness direction, a first resin side face connected to the resin obverse face, and a second resin side face connected to the resin reverse face,
the first resin side face is located on an inner side of the second resin side face, as viewed in the thickness direction,
the first columnar electrode includes a first exposed side face exposed from the resin member, a first covered side face covered with the resin member, and a first top face connected to the first exposed side face and flush with the resin obverse face,
the first exposed side face is located on an inner side of the first covered side face as viewed in the thickness direction, and flush with the first resin side face,
the first covered side face and the second resin side face are each oriented in a first direction orthogonal to the thickness direction, and
the first covered side face overlaps with the second resin side face, as viewed in the first direction.

Clause E2.

The semiconductor device according to Clause E1,
in which the first columnar electrode further includes a first connecting surface connected to the first exposed side face and the first covered side face, and
the first connecting surface overlaps with the semiconductor element, as viewed in the first direction.

Clause E3.

The semiconductor device according to Clause E2,
in which the resin member further includes a resin connecting surface connected to the first resin side face and the second resin side face, and
the resin connecting surface and the first connecting surface are flush with each other.

Clause E4.

The semiconductor device according to Clause E3,
in which the resin connecting surface is larger in size in the first direction, than the first connecting surface.

Clause E5.

The semiconductor device according to any one of Clause E1 to Clause E4, further including an external electrode covering the first top face and the first exposed side face.

Clause E6.

The semiconductor device according to any one of Clause E1 to Clause E5, further including a bonding section conductively bonding the semiconductor element and the wiring layer to each other,
in which the semiconductor element includes an element reverse face oriented to the same side as is the resin reverse face,
the element electrode is formed on the element reverse face, and
the bonding section is interposed between the element electrode and the wiring layer.

Clause E7.

The semiconductor device according to any one of Clause E1 to Clause E6, further including a substrate formed of a semiconductor material,
in which the substrate is located on the one side in the thickness direction, with respect to the resin member.

Clause E8.

The semiconductor device according to Clause E7,
in which the substrate includes a substrate obverse face and a substrate reverse face spaced apart from each other in the thickness direction, a first substrate side face connected to the substrate obverse face, and a second substrate side face connected to the substrate reverse face,
the wiring layer is formed on the substrate obverse face, and
the first substrate side face is flush with the second resin side face, and located on an inner side of the second substrate side face, as viewed in the thickness direction.

Clause E9.

The semiconductor device according to Clause E8,
in which the first substrate side face is smaller in size in the thickness direction, than the second substrate side face.

Clause E10.

The semiconductor device according to any one of Clause E7 to Clause E9, further including an insulation film interposed between the substrate and the wiring layer.

Clause E11.

The semiconductor device according to any one of Clause E7 to Clause E10, in which the semiconductor material includes Si.

Clause E12.

The semiconductor device according to any one of Clause E1 to Clause E11, further including a second columnar electrode protruding from the wiring layer toward the other side in the thickness direction,
in which the second columnar electrode includes a second exposed side face exposed from the resin member, a second covered side face covered with the resin member, and a second top face connected to the second exposed side face and flush with the resin obverse face,
the first columnar electrode and the second columnar electrode are spaced apart from each other, as viewed in the thickness direction, and
the second top face is larger in plan-view area than the first top face.

Clause E13.

A manufacturing method of a semiconductor device, the method including:
a substrate preparation process including preparing a substrate having a substrate obverse face and a substrate reverse face spaced apart from each other in a thickness direction;
a wiring layer formation process including forming a wiring layer on the substrate obverse face;
a first columnar electrode formation process including forming a first columnar electrode on the wiring layer;
an element mounting process including mounting a semiconductor element;
a resin formation process including forming a resin member covering the semiconductor element, on the substrate;
a first cutting process including cutting each of the first columnar electrode and the resin member to a halfway position thereof in the thickness direction, thereby forming a first cutaway portion; and
a second cutting process including completely cutting the resin member in the thickness direction thereof, at the first cutaway portion,
in which, in the first cutting process, a first exposed side face exposed from the resin member, and a first covered side face covered with the resin member are formed on the first columnar electrode, and a first resin side face is formed in the resin member,
in the second cutting process, a second resin side face is formed in the resin member,
the first resin side face is located on an inner side of the second resin side face, as viewed in the thickness direction,
the first exposed side face is located on an inner side of the first covered side face, as viewed in the thickness direction, and flush with the first resin side face,
the first covered side face and the second resin side face are each oriented in a first direction orthogonal to the thickness direction, and
the first covered side face overlaps with the second resin side face, as viewed in the first direction.

Clause E14.

The method according to Clause E13, further including a substrate grinding process including grinding the substrate in the thickness direction, from the side of the substrate reverse face.

Clause E15.

The method according to Clause E14,
in which the substrate grinding process includes completely removing the substrate.

Clause E16.

The method according to Clause E14,
in which the second cutting process further includes cutting the substrate to a halfway position thereof in the thickness direction, thereby forming a second cutaway portion.

Clause E17.

The method according to Clause E16, further including a third cutting process including completely cutting the substrate in the thickness direction, at the second cutaway portion.

Clause E18.

The method according to any one of Clause E13 to Clause E17, further including an external electrode formation process including forming an external electrode,
in which the first columnar electrode further includes a first top face exposed from the resin member,
the first top face is connected to the first exposed side face, and oriented to the same side as is the substrate obverse face, and
the external electrode covers the first top face and the first exposed side face.

Listed hereunder are the elements related to the embodiments and/or the variations of the second aspect.
A1 to A3 semiconductor device
10 semiconductor element
101 element obverse face
102 element reverse face
11 element electrode
20 substrate
201 substrate obverse face
202 substrate reverse face
203 first substrate side face
204 second substrate side face
205 substrate connecting surface
29 insulation film
30 wiring layer
301 underlying layer
302 plated layer
31, 32 wiring section
39 protective film
41 second columnar electrode
411 second top face
412 second contact surface
413 second exposed side face
414 second covered side face
415 second connecting surface
42 first columnar electrode
421 first top face
422 first contact surface
423 first exposed side face
424 first covered side face
425 first connecting surface
50 bonding section
51 protective layer
52 bonding layer
521 first layer
522 second layer
523 third layer
60 external electrode
70 resin member
71 resin obverse face
72 resin reverse face
731 first resin side face
732 second resin side face
733 resin connecting surface
810 semiconductor element
810a element obverse face
810b element reverse face
820 substrate
820a substrate obverse face
820b substrate reverse face
820c first substrate side face
829 insulation film
830 wiring layer
830a underlying layer
830b plated layer
840 columnar electrode
840a top face
840c exposed side face
850 bonding material
860 external electrode
870 resin member
871 resin obverse face
873a first resin side face
873b second resin side face
891 first cutaway portion
892 second cutaway portion

1. A semiconductor device comprising:
a substrate having a substrate obverse face and a substrate reverse face that face to opposite sides to each other in a thickness direction;
wirings located on the substrate obverse face and including a first drive wiring and a second drive wiring;
a semiconductor element electrically connected to the first drive wiring and the second drive wiring;
a first drive conductor that is located on a same side as the semiconductor element with respect to the substrate, disposed in a region on an outer side of the semiconductor element as viewed in the thickness direction, and electrically connected to the first drive wiring;
a second drive conductor that is located on the same side as the semiconductor element with respect to the substrate, disposed in a region on an outer side of the semiconductor element as viewed in the thickness direction, and electrically connected to the second drive wiring; and
a sealing resin enclosing the wirings and the semiconductor element and covering the first drive conductor and the second drive conductor in a manner such that respective faces of the first drive conductor and the second drive conductor that are opposite to the substrate in the thickness direction are exposed from the resin,
wherein the first drive conductor and the second drive conductor are spaced apart from each other in a predetermined direction extending along the substrate obverse face, and
the first drive conductor is smaller in volume than the second drive conductor.

2. The semiconductor device according to claim 1, wherein the first drive conductor and the second drive conductor each include a top face exposed from a side of the sealing resin opposite to the substrate in the thickness direction, and
the top face of the first drive conductor is smaller in area than the top face of the second drive conductor.

3. The semiconductor device according to claim 2, wherein when a direction along which the first drive conductor and the second drive conductor is aligned is referred to as a first direction, and a direction orthogonal to the thickness direction and the first direction is referred to as a second direction,
the top faces of the first drive conductor and the second drive conductor have each a rectangular shape, as viewed in the thickness direction, that has a short-side direction corresponding to the first direction and a long-side direction corresponding to the second direction, and the top face of the first drive conductor is smaller in length in the second direction than the top face of the second drive conductor.

4. The semiconductor device according to claim 2, wherein when a direction along which the first drive conductor and the second drive conductor is aligned is referred to as a first direction, and a direction orthogonal to the thickness direction and the first direction is referred to as a second direction,
the top faces of the first drive conductor and the second drive conductor have each a rectangular shape, as viewed in the thickness direction, that has a short-side direction corresponding to the first direction and a long-side direction corresponding to the second direction, and the top face of the first drive conductor is smaller in length in the first direction than the top face of the second drive conductor.

5. The semiconductor device according to claim 1, wherein the second drive conductor is located closer to a center of the substrate obverse face than is the first drive conductor, in a direction along which the first drive conductor and the second drive conductor are aligned.

6. The semiconductor device according to claim 1, wherein when a direction along which the first drive conductor and the second drive conductor are aligned is referred to as a first direction, and a direction orthogonal to the thickness direction and the first direction is referred to as a second direction,
the semiconductor element includes a control circuit,
a plurality of control conductors are electrically connected to the control circuit,
the plurality of control conductors are arranged in the second direction with a spacing between each other, and
the second drive conductor is greater in volume than the control conductor.

7. The semiconductor device according to claim 6, wherein the first drive conductor, the second drive conductor, and the control conductors each include a top face that is opposite to the substrate in the thickness direction and exposed from the sealing resin, and
the top face of the second drive conductor is greater in area than the top face of each control conductor.

8. The semiconductor device according to claim 7, wherein the top face of the second drive conductor has a rectangular shape having a shorter side extending in the first direction and a longer side extending in the second direction as viewed in the thickness direction,
the top face of each control conductor has a rectangular shape having a side extending in the first direction and a side extending in the second direction as viewed in the thickness direction, and
a length of the top face of the second drive conductor in the second direction is greater than a length of the top face of each control conductor in the first direction and in the second direction.

9. The semiconductor device according to claim 6, wherein the plurality of control conductors are located on an outer side in the first direction with respect to the first drive conductor and the second drive conductor.

10. The semiconductor device according to claim 9, wherein the substrate has a rectangular shape having a side extending in the first direction and a side extending in the second direction as viewed in the thickness direction,
the control conductors include distal control conductors respectively located at four corners of the substrate as viewed in the thickness direction, and intermediate control conductors located between two of the distal control conductors in the second direction,
the distal control conductors and the intermediate control conductors each include a top face that is opposite to the substrate in the thickness direction and exposed from the sealing resin, and
the top face of each distal control conductor is greater in area than the top face of each intermediate control conductor.

11. The semiconductor device according to claim 10, wherein the second drive conductor is greater in volume than each distal control conductor.

12. The semiconductor device according to claim 11, wherein the second drive conductor includes a top face that is opposite to the substrate in the thickness direction and exposed from the sealing resin, and
the top face of the second drive conductor is greater in area than the top face of each distal control conductor.

13. The semiconductor device according to claim 12, wherein the top face of the second drive conductor has a rectangular shape having a shorter side extending in the first direction and a longer side extending in the second direction as viewed in the thickness direction,
the top face of each distal control conductor has a rectangular shape having a side extending in the first direction and a side extending in the second direction as viewed in the thickness direction, and
a length of the top face of the second drive conductor in the second direction is greater than a length of the top face of each distal control conductor in the first direction and the second direction.

14. The semiconductor device according to claim 6, wherein a volume of the first drive conductor is equal to or greater than a volume of each of the control conductors.

15. The semiconductor device according to claim 10, wherein the first drive conductor is smaller in volume than each distal control conductor.

16. The semiconductor device according to claim 15, wherein the first drive conductor includes a top face that is opposite to the substrate in the thickness direction and exposed from the sealing resin, and the top face of the first drive conductor is smaller in area than the top face of each distal control conductor.

17. The semiconductor device according to claim 16, wherein the top face of the first drive conductor has a rectangular shape having a shorter side extending in the first direction and a longer side extending in the second direction as viewed in the thickness direction, and
a length of the top face of the first drive conductor in the second direction is smaller than a length of the top face of each distal control conductor in at least one of the first direction and the second direction.

18. The semiconductor device according to claim 10, wherein a volume of the first drive conductor is equal to or greater than a volume of each intermediate control conductor.

19. The semiconductor device according to claim 18, wherein the first drive conductor includes a top face that is opposite to the substrate in the thickness direction and exposed from the sealing resin, and
an area of the top face of the first drive conductor is equal to or greater than an area of the top face of each intermediate control conductor.

20. The semiconductor device according to claim 10, wherein the wirings includes a control wiring connecting the control circuit and the control conductors, and
the first drive wiring and the second drive wiring are each wider than the control wiring.
